(19) United States
(12) Patent Application Publication
(10) Pub. No.: US 2018/0217497 A1
(43) Pub. Date: Aug. 2, 2018

(54) PATTERN FORMING METHOD AND ACTINIC RAY-SENSITIVE OR RADIATION-SENSITIVE RESIN COMPOSITION

(71) Applicant: FUJIFILM Corporation, Tokyo (JP)

(72) Inventors: Fumihiro YOSHINO, Haibara-gun (JP); Kenichi HARADA, Haibara-gun (JP); Shinichi SUGIYAMA, Haibara-gun (JP); Takamitsu TOMIGA, Haibara-gun (JP)

(73) Assignee: FUJIFILM Corporation, Tokyo (JP)

(21) Appl. No.: 15/939,295

(22) Filed: Mar. 29, 2018

Related U.S. Application Data
(63) Continuation of application No. PCT/JP2016/078170, filed on Sep. 26, 2016.

(30) Foreign Application Priority Data
Sep. 30, 2015 (JP) 2015-195235

(51) Int. Cl. G03F 7/039; G03F 7/16; G03F 7/20; G03F 7/32; G03F 7/38; G03F 7/004; G03F 7/40; G03F 7/038

(52) U.S. Cl. CPC G03F 7/039; G03F 7/16; G03F 7/2006; G03F 7/322; G03F 7/038; G03F 7/38; G03F 7/0045; G03F 7/40; G03F 7/168

(57) ABSTRACT

The present invention provides a pattern forming method which can be suitably applied to grayscale exposure since a deviation of the thickness among production lots is hardly generated, and an actinic ray-sensitive or radiation-sensitive resin composition. The pattern forming method of the present invention is a pattern forming method having a step A of forming a film having a thickness T on a substrate, using an actinic ray-sensitive or radiation-sensitive resin composition including a resin whose solubility in a developer changes by the action of an acid and an acid generator, a step B of exposing the film, and a step C of developing the exposed film using a developer to form a pattern, in which the film formed in the step A satisfies at least one of the following condition 1 or 2.

Condition 1: In a case where the thickness T of the film is 800 nm or more, the value of γ is less than 10,000.

Condition 2: In a case where the thickness T of the film is less than 800 nm, the value of γ is less than 5,000.

### CROSS-REFERENCE TO RELATED APPLICATIONS

This application is a Continuation of PCT International Application No. PCT/JP2016/078170 filed on Sep. 26, 2016, which claims priority under 35 U.S.C. § 119(a) to Japanese Patent Application No. 2015-195235 filed on Sep. 30, 2015. The above application is hereby expressly incorporated by reference, in its entirety, into the present application.

### BACKGROUND OF THE INVENTION

### 1. Field of the Invention

The present invention relates to a pattern forming method and an actinic ray-sensitive or radiation-sensitive resin composition. More specifically, the present invention relates to a pattern forming method which can be applied to a process for manufacturing a semiconductor such as an integrated circuit (IC), a process for manufacturing a circuit board for a liquid crystal, a thermal head, or the like, and other photofabrication processes, as well as an actinic ray-sensitive or radiation-sensitive resin composition used in the pattern forming method.

### 2. Description of the Related Art

A three-dimensional pattern forming body having a fine three-dimensional pattern region on the surface thereof has been used in various applications from the related art. As a method for forming such the three-dimensional pattern region, for example, a method of approximating the shape of a desired three-dimensional pattern region by multistage etching, or the like is known. However, since methods using multistage etching are required to carry out a plurality of times of treatments, the methods pose a problem in poor productivity.

With regard to such the problem, a method using a grayscale exposure has been proposed (for example, JP2010-044373A).

In an aspect in which grayscale exposure is carried out, disclosed is a method in which a resist film is first formed on a substrate, the resist film is then subjected to grayscale exposure to form a pattern having a three-dimensional structure (for example, a stepped structure), and dry etching is carried out to remove the resist film and etch the substrate, thereby forming a three-dimensional pattern region having a three-dimensional structure on the surface of the substrate.

### SUMMARY OF THE INVENTION

On the other hand, there has recently been required to produce the above-mentioned three-dimensional pattern forming body with good accuracy. For this, it is required to produce a resist pattern having a three-dimensional structure disposed on a substrate with good accuracy.

The present inventors have conducted studies on the methods in the related art, and thus, they have found that in a case where grayscale exposure is carried out, a variation in the thickness in a three-dimensional structure in a resist pattern formed on a substrate among production lots is easily generated, and as a result, the yield of a three-dimensional pattern forming body is reduced. More specifically, for example, in a case where a resist pattern having a stepped structure is intended to be formed on a substrate, a variation in the exposure doses from prescribed values occurs among production lots in some cases, and as a result, a deviation of the thickness among the resist patterns having a three-dimensional structure, such as different heights of the respective steps among production lots in the resist patterns thus produced is generated.

Therefore, taking these situations into consideration, the present invention has an object to provide a pattern forming method which can be suitably applied to grayscale exposure since a deviation of the thickness among production lots is hardly generated.

In addition, the present invention has another object to provide an actinic ray-sensitive or radiation-sensitive resin composition which can be applied to the pattern forming method.

The present inventors have conducted extensive studies on the objects, and as a result, they have found that by controlling the characteristics of a resist film formed using an actinic ray-sensitive or radiation-sensitive resin composition, a desired effect is obtained.

That is, the present inventors have found that the objects are accomplished by the following configurations.

(1) A pattern forming method comprising:

a step A of forming a film having a thickness T on a substrate, using an actinic ray-sensitive or radiation-sensitive resin composition including a resin whose solubility in a developer changes by the action of an acid and an acid generator;

a step B of exposing the film; and

a step C of developing the exposed film using a developer to form a pattern,

in which the film formed in the step A satisfies at least one of the following condition 1 or 2.

Condition 1: In a case where the thickness T of the film is 800 nm or more, the value of γ is less than 10,000.

Condition 2: In a case where the thickness T of the film is less than 800 nm, the value of γ is less than 5,000.

Furthermore, γ is obtained by a method for calculating γ, which will be described later.

(2) The pattern forming method as described in (1),

in which the film formed in the step A satisfies the condition 1, and

the transmittance of the film formed in the step A at a wavelength of 248 nm is 12% or less.

(3) The pattern forming method as described in (1) or (2),

in which the resin has a molar light absorption coefficient E at a wavelength of 243 nm of more than 200 L·mol⁻¹·cm⁻¹, or the actinic ray-sensitive or radiation-sensitive resin composition further includes a resin having a molar light absorption coefficient c at a wavelength of 243 nm of more than 200 L·mol⁻¹·cm⁻¹, which is other than the resin whose solubility in a developer changes by the action of an acid.

(4) The pattern forming method as described in any one of (1) to (3),

in which the actinic ray-sensitive or radiation-sensitive resin composition further includes a compound having a molar light absorption coefficient ε at a wavelength of 243 nm of more than 200 L·mol⁻¹·cm⁻¹ and a molecular weight of 2,000 or less, which is other than the acid generator.

(5) The pattern forming method as described in any one of (1) to (4),

in which the resin includes a tertiary alkyl ester group as an acid-decomposable group.

(6) The pattern forming method as described in any one of (1) to (5),

in which the acid generator includes an acid generator having a pKa of a generated acid of −2 or more.

(7) The pattern forming method as described in any one of (1) to (6),

in which the actinic ray-sensitive or radiation-sensitive resin composition further includes an acid diffusion control agent, and

the content of the acid diffusion control agent is 0.2% by mass or more with respect to the total solid content in the actinic ray-sensitive or radiation-sensitive resin composition.

(8) The pattern forming method as described in any one of (1) to (7),

in which the exposure in the step B is grayscale exposure.

(9) The pattern forming method as described in any one of (1) to (8), further comprising:

a step D of subjecting the film to a heating treatment after the step B and before the step C,

in which the temperature in the heating treatment is 115° C. or lower.

(10) The pattern forming method as described in any one of (1) to (9),

in which the exposure in the step B is carried out with KrF light.

(11) An actinic ray-sensitive or radiation-sensitive resin composition used in the pattern forming method as described in any one of (1) to (10).

According to the present invention, it is possible to provide a pattern forming method which can be suitably applied to grayscale exposure since a deviation of the thickness among production lots is hardly generated.

In addition, according to the present invention, it is also possible to provide an actinic ray-sensitive or radiation-sensitive resin composition which can be applied to the pattern forming method.

### BRIEF DESCRIPTION OF THE DRAWING

FIG. 1A is a schematic view for showing a method for calculating γ.

FIG. 1B is a schematic view for showing a method for calculating γ.

FIG. 1C is a schematic view for showing a method for calculating γ.

FIG. 2 is an example of a plot diagram created for describing a method for calculating γ.

### DESCRIPTION OF THE PREFERRED EMBODIMENTS

Hereinafter, embodiments of the present invention will be described in detail.

In citations for a group (atomic group) in the present specification, in a case where the group is denoted without specifying whether it is substituted or unsubstituted, the group includes both a group and an atomic group not having a substituent, and a group and an atomic group having a substituent. For example, an “alkyl group” which is not denoted about whether it is substituted or unsubstituted includes not only an alkyl group not having a substituent (unsubstituted alkyl group), but also an alkyl group having a substituent (substituted alkyl group).

In the present specification, “actinic rays” or “radiation” means, for example, a bright line spectrum of a mercury lamp, far ultraviolet rays represented by an excimer laser, extreme ultraviolet rays (EUV light), X-rays, electron beams (EB), or the like. In addition, in the present invention, light means actinic rays or radiation.

Furthermore, “exposure” in the present specification includes, unless otherwise specified, not only exposure by bright line spectrum of a mercury lamp, far ultraviolet rays represented by extreme ultraviolet rays (EUV light), X-rays, or the like, but also writing by particle rays such as electron beams and ion beams.

Furthermore, in the present specification, “(a value) to (a value)” means a range including the numerical values described before and after “to” as a lower limit value and an upper limit value, respectively.

In addition, in the present specification, (meth)acrylate represents acrylate and methacrylate, and (meth)acryl represents acryl and methacryl.

<<Pattern Forming Method>>

The pattern forming method of the present invention will be described.

The pattern forming method of the present invention includes at least the following steps A to C.

Step A: A step of forming a film (corresponding to a so-called resist film) having a thickness T on a substrate, using an actinic ray-sensitive or radiation-sensitive resin composition

Step B: A step of exposing the film (exposing step)

Step C: A step of developing the exposed film using a developer to form a pattern (a so-called resist pattern) (developing step)

The exposure in the step B may be liquid immersion exposure, as will be described later.

The pattern forming method of the present invention preferably includes a step D (heating step) after the step B and before the step C.

The pattern forming method of the present invention may include a plurality of times of the exposing step.

The pattern forming method of the present invention may include a plurality of times of the heating step.

Hereinafter, the procedure of each step will be described in detail.

(Step a (Film Forming Step))

The step A is a step of forming a film (hereinafter also referred to as a “resist film”) on a substrate, using an actinic ray-sensitive or radiation-sensitive resin composition.

Details of the actinic ray-sensitive or radiation-sensitive resin composition (hereinafter also simply referred to as “the composition” or “the composition of the present invention”) used in the present step will be described in detail in the paragraphs below.

The substrate used in the present step is not particularly limited, and an inorganic substrate such as silicon, SiO₂, and SiN, a coating-type inorganic substrate such as Spin on Glass (SOG), or a substrate generally used in a process for manufacturing a semiconductor such as an IC, in a process for manufacture of a circuit board for a liquid crystal, a thermal head, or the like, and in other lithographic processes of photofabrication can be used.

In addition, an antireflection film may further be formed between the resist film and the substrate, as desired. As the antireflection film, a known organic or inorganic antireflection film can be appropriately used.

A method for forming a film (resist film) using an actinic ray-sensitive or radiation-sensitive resin composition can be carried out, typically by applying the actinic ray-sensitive or radiation-sensitive resin composition onto a substrate, and examples of the application method include a rotation application method, a spray method, a roller coating method, and an immersion method, which are known in the related art, with the rotation application method being preferable.

The thickness T of the formed film is not particularly limited, but an optimal thickness is appropriately selected depending on the purposes of patterns, and is usually in the range of 10 to 15,000 nm in many cases. Among those, in a view that it is easy to form a pattern having a three-dimensional structure, it is preferable that the film is a so-called thick film, and specifically, the thickness T is preferably 800 nm or more, more preferably 1,000 to 10,000 nm, and still more preferably 2,000 to 5,000 nm.

Furthermore, the film may be a so-called thin film, depending on the purposes of the pattern. Further, the thin film as used herein is intended to mean a film having a thickness T of less than 800 nm. The range of the thickness T in a case of a thin film is not particularly limited, but is preferably 50 to 500 nm.

In addition, the thickness is an average value, which is a value obtained by measuring the thickness at arbitrary at least 5 or more points of a film, and arithmetically averaging the values.

The film formed in the present step satisfies at least one of the following condition 1 or 2.

Condition 1: In a case where the thickness T of the film is 800 nm or more, γ<10,000 (the value of γ is less than 10,000).

Condition 2: In a case where the thickness T of the film is less than 800 nm, γ<5,000 (the value of γ is less than 5,000).

The γ described in the conditions 1 and 2 is a parameter which can be calculated by a method which will be described later, and usually represents the sensitivity of a resist film to an exposure dose. In a case where the value of γ is high, the sensitivity of the resist film to the exposure dose is high, and thus, even with a slight difference in the exposure dose, the thickness of the pattern after the developing treatment is significantly different. To the contrary, in a case where the value of γ is small, the sensitivity of the resist film to the exposure dose is low, and thus, even in a case where there is a deviation of the exposure dose, a difference in the thickness of the pattern after the developing treatment is hardly generated, and therefore, the effect of the present invention is easily exhibited.

Furthermore, in a suitable aspect of the condition 1, in a view that the deviation of the thickness between the formed patterns is smaller (hereinafter also simply referred to as “in a view that the effect of the present invention is superior”), the value of γ is preferably 8,000 or less, and more preferably 5,000 or less. The lower limit is not particularly limited, but in a view of the productivity, it is preferably 100 or more, and more preferably 500 or more.

In addition, in a suitable aspect of the condition 2, in a view that the effect of the present invention is superior, the value of γ is preferably 4,000 or less, and more preferably 3,000 or less. The lower limit is not particularly limited, and in a view of the productivity, it is preferably 100 or more, and more preferably 500 or more.

Hereinafter, the method for calculating γ will be described with reference to the drawings.

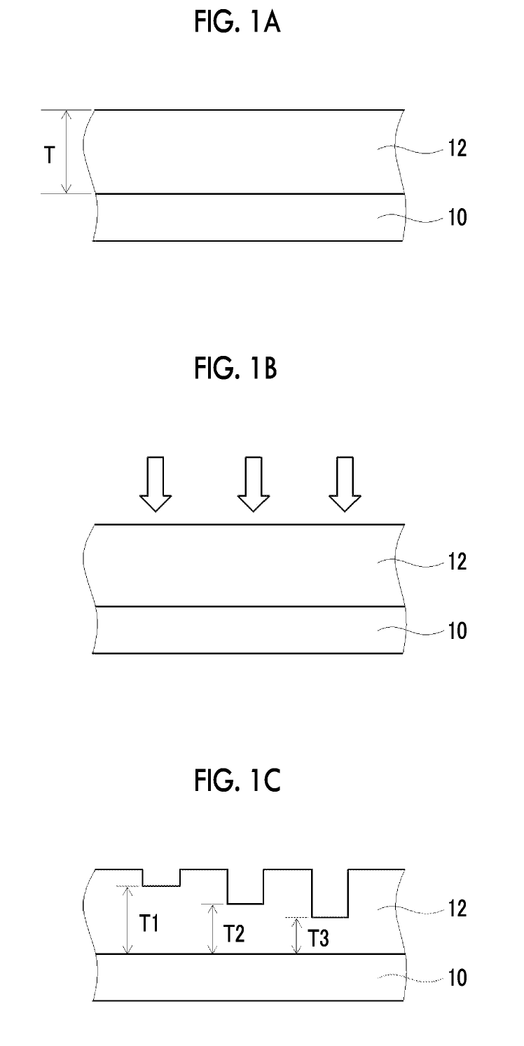

First, a film 12 having a thickness T is formed on a substrate 10, as shown in FIG. 1A. As the substrate to be used, a Si substrate (manufactured by Advanced Materials Technology Inc.) which has been subjected to a hexamethyldisilazane treatment is used.

As for a method for producing the film, a composition is applied onto a substrate by a rotation application method, and subjected to a baking (Pre Bake) treatment (heating treatment) at 140° C. for 60 seconds, thereby producing a film having a thickness T.

Next, the obtained film is subjected to exposure using a KrF excimer laser at 99 positions while an exposure dose is increased from 1 mJ/cm² at an interval of 0.8 mJ/cm². That is, the 99 positions having different film surfaces were subjected to exposure at different exposure doses, respectively. At that time, the exposure dose in each of the exposure positions is increased from 1 mJ/cm² at an interval of 0.8 mJ/cm². More specifically, as shown in FIG. 1B, exposure is carried out at exposure doses which are changed at different film positions as shown by an open white arrow. In addition, in FIG. 1B, exposure is carried out at three different positions of the film 12. In FIG. 1B, in the exposure on the leftmost side, exposure is carried out at an exposure dose of A mJ/cm²; in the exposure in the middle, exposure at an exposure dose of (A+0.8) mJ/cm² is carried out; and in the exposure on the rightmost side, exposure at an exposure dose of (A+1.6) mJ/cm² is carried out. As such, for each of the exposure positions, exposure is carried out while the exposure dose is increased at an interval of 0.8 mJ/cm².

Thereafter, the film which has been subjected to the exposure treatment is baked at 120° C. for 60 seconds (Post Exposure Bake; PEB).

Subsequently, the obtained film is subjected to a developing treatment. As for a method for the developing treatment, development is performed in an aqueous tetramethylammonium hydroxide solution (2.38% by mass: “the concentration of the tetramethylammonium hydroxide in the aqueous solution is 2.38% by mass”) for 60 seconds, rinsing is performed with pure water for 30 seconds, and then spin drying is performed. In a case where the developing treatment is carried out, the film is removed in the exposed position. The removal amount at that time varies, depending on the exposure dose. For example, FIG. 1C is a view after the film shown in FIG. 1B is subjected to a developing treatment, in which the film thickness of the leftmost exposed position is the largest, while the film thickness of the rightmost side of the exposed position is the smallest. That is, a relationship of T1>T2>T3 is satisfied. In FIG. 1C, only the film thickness at three points is described, but actually, the film thickness at the 99 exposed positions is measured.

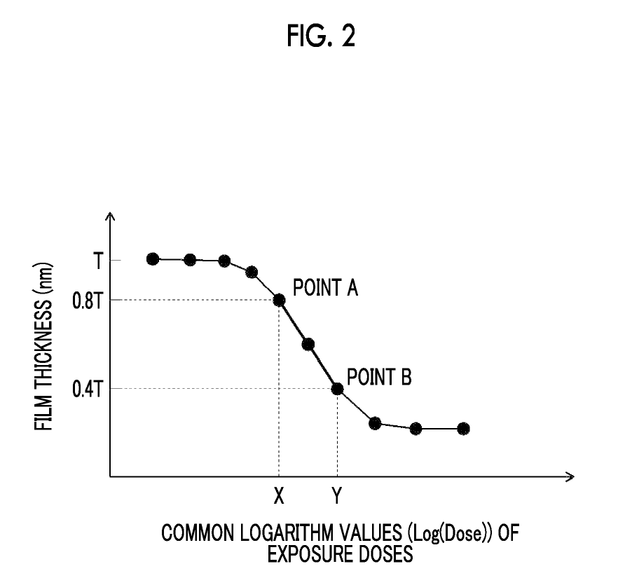

Next, a plot diagram is created, using the data of the exposure doses and the film thickness in the respective exposed positions. Specifically, the points corresponding to the film thickness and the common logarithm values of the exposure doses at the respective exposed positions are plotted in Cartesian coordinates with the film thickness displayed along the vertical axis and the common logarithm value of the exposure doses displayed along the horizontal axis. That is, a graph with the film thickness displayed along the vertical axis and the common logarithm value of the exposure doses displayed along the horizontal axis in each exposed position is created. Further, the unit of the vertical axis is nm, and the unit of the exposure dose is mJ/cm². FIG. 2 shows an example of the plot diagram. Incidentally, the respective black dots in FIG. 2 correspond to the results (the film thickness and the common logarithm values of the exposure doses) in the respective exposed positions. Further, in FIG. 2, the number of plots of black dots is shown to be less than the actual number 99 for easier description.

Subsequently, a line is created by connecting the respective plotted points in the obtained plot diagram. A point A as a point at which the value of the thickness of the vertical axis is 0.8×T (thickness accounting for 80% of T) and a point B as a point at which the value of the thickness of the vertical axis is 0.4×T (thickness accounting for 40% of T), on the obtained line, are selected, and an absolute value of the slope of a straight line connecting the points A and B is calculated and defined as γ.

For example, in a case where the thickness T is 2,000 nm, 0.8 T and 0.4 T correspond to 1,600 nm and 800 nm, respectively. Here, in a case where the value on the horizontal axis of the point having a thickness on the vertical axis of 1,600 nm is taken as X and the value on the horizontal axis of the point having a thickness on the vertical axis of 800 nm is taken as Y as shown in FIG. 2, the slope of the two points is calculated as (800−1,600)/(Y−X), and an absolute value thereof is taken as γ.

A method for controlling γ as mentioned above is not particularly limited, but γ can be controlled by the following method.

(I) The transmittance of the film is set to a predetermined value or less.

(II) The types or used amounts of the materials (for example, a resin, an acid generator, an acid diffusion control agent, and a light absorbent) included in the actinic ray-sensitive or radiation-sensitive resin composition are adjusted.

(III) The method at a time of forming the pattern is adjusted.

With regard to (I), it is possible to reduce the value of γ by reducing the transmittance of a film, it is possible to suppress the decomposition of an acid generator included in the film, and thus, reduce the sensitivity of the film. Further, examples of a method for reducing the transmittance include a method of using a light absorbent, as described in detail in the later paragraphs.

Furthermore, with regard to (II), it is possible to control the extent of decomposition, for example, by adjusting the type of an acid-decomposable group included in a resin used. More specifically, it is possible to reduce the value of γ by using a tertiary alkyl ester group as the acid-decomposable group to make acid decomposition difficult. Incidentally, it is also possible to reduce the value of γ by using an acid generator having a pKa of a generated acid of more than a predetermined value as the acid generator to weaken the strength of the generated acid. Further, it is also possible to reduce the value of γ by increasing the used amount of an acid diffusion control agent to be used to prevent the diffusion of an acid. In addition, it is possible to adjust the value of γ using a predetermined type of a light absorbent.

Moreover, with regard to (III), it is also possible to reduce the value of γ, for example, by setting a temperature for a heating step (step D: post-exposure bake) provided between a step B and a step C, which will be described later (PEB; Post Exposure Bake) provided between a step B and a step C, which will be described later to a predetermined value or less, to suppress the diffusion of the acid.

Incidentally, in a case of adjusting the value of γ, an optimal method is selected according to the thickness of the film. For example, in a case where the thickness of the film is high (a case of a thick film having a thickness T of 800 nm or more), a method of adjusting the transmittance of the film described in (I), a method using the predetermined resin described in (II) (a resin having a predetermined acid-decomposable group), or the like is suitably adopted and used.

In addition, in a case where the thickness of the film is low (a case of a thin film having a thickness T of less than 800 nm), a method of using the predetermined acid generator described in (II), a method of using the acid diffusion control agent described in (II) in a predetermined amount or more, a method of carrying out post-exposure heating described in (III) at a predetermined temperature or lower, or the like is suitably adopted and used.

The transmittance of the film formed in the step A is not particularly limited, but in a case where the thickness of the film is 800 nm or more (a case under the condition 1 above), the transmittance of the film at a wavelength of 248 nm is preferably 12% or less. Above all, in a view that the effect of the present invention is superior, the transmittance is more preferably 8% or less. The lower limit is not particularly limited, but is 1% or more in many cases.

As for a method for measuring the transmittance, a composition prepared is applied onto a quartz glass substrate by rotation application, and subjected to pre-baking at 140° C. for 60 seconds to form a resist film having a thickness T, and the transmittance of the film at a wavelength of 248 nm is measured using a light absorption photometer (UV-2500PC, manufactured by Shimadzu Corp.).

It is also preferable that the method includes a preheating step (PB; Prebake) before an exposing step which will be described later, after forming a film.

The heating is carried out at a heating temperature of preferably 70° C. to 130° C., and more preferably 80° C. to 120° C.

The heating time is preferably 30 to 300 seconds, more preferably 30 to 180 seconds, and still more preferably 30 to 90 seconds.

The heating may be carried out using a means equipped in ordinary exposure and development machines, or may also be carried out using a hot plate or the like.

(Step B (Exposing Step))

The step B is a step of exposing the film.

The light source wavelength used in the exposure device used in the present step is not particularly limited, and examples thereof include infrared rays, visible light, ultraviolet rays, far ultraviolet rays, extreme ultraviolet rays, X-rays, and electron beams, for example, far ultraviolet rays at a wavelength of preferably 250 nm or less, more preferably 220 nm or less, and still more preferably 1 to 200 nm, specifically a KrF excimer laser (248 nm), an ArF excimer laser (193 nm), an F₂ excimer laser (157 nm), X-rays, extreme ultraviolet (EUV) (13 nm), electron beams, and the like, with the KrF excimer laser, the ArF excimer laser, EUV, or the electron beams being preferable, and the KrF excimer laser or the ArF excimer laser being more preferable. That is, as the exposure light, KrF light is preferably used.

As the exposure, grayscale exposure is preferably carried out.

Grayscale exposure is to subject a resist film to an exposure treatment through a mask having a predetermined dot formed such that a desired shape may be obtained and predetermined light transmittance is obtained. That is, it is an exposure treatment which can provide gradation in the height of the obtained pattern (resist pattern) by irradiating the mask having fine apertures with light.

Moreover, a liquid immersion exposure method can be applied to the step of carrying out the exposure of the present invention. It is possible to combine the liquid immersion exposure method with super-resolution technology such as a phase shift method and a modified illumination method.

In a case of carrying out the liquid immersion exposure, a step of washing the surface of the film with a water-based chemical may be carried out (1) before the step of forming the film on the substrate and then exposing the film and/or (2) before the step of heating the film after the step of subjecting the film to exposure through an immersion liquid.

The immersion liquid is preferably a liquid which is transparent to exposure wavelength and possibly has a minimum temperature coefficient of a refractive index so as to minimize the distortion of an optical image projected on the film. In particular, in a case where the exposure light source is ArF excimer laser (wavelength; 193 nm), water is preferable in terms of easy availability and easy handling, in addition to the above-mentioned viewpoints.

In a case of using water, an additive (liquid) that decreases the surface tension of water while increasing the interfacial activity may be added at a slight proportion. It is preferable that this additive does not dissolve the resist film on a wafer, and has a negligible effect on the optical coat at the undersurface of a lens element.

Such an additive is preferably an aliphatic alcohol having a refractive index almost equal to that of water, and specific examples thereof may include methyl alcohol, ethyl alcohol, and isopropyl alcohol. By adding an alcohol having a refractive index almost equal to that of water, even in a case where the alcohol component in water is evaporated and the content concentration thereof is changed, it is possible to obtain an advantage in that the change in the refractive index of the liquid as a whole can be made very small.

Meanwhile, in a case where a substance opaque in 193 nm rays or an impurity having a refractive index greatly different from that of water is incorporated therein, the incorporation would cause a distortion of an optical image projected on the resist film, and thus, it is preferable to use distilled water as the water. In addition, pure water having been filtered through an ion exchange filter or the like may also be used.

The electrical resistance of water to be used as an immersion liquid is desirably 18.3 MQcm or more, and an organic matter concentration (TOC) thereof is desirably 20 ppb or less, and the water is desirably subjected to a deaeration treatment.

Furthermore, it is possible to enhance the lithography performance by increasing the refractive index of the immersion liquid. From such a viewpoint, an additive for increasing the refractive index may be added to the water, or heavy water (D₂O) may be used instead of water.

A receding contact angle of the resist film is preferably 70° or more at a temperature of 23±3° C. and a humidity of 45±5%, and this is suitable to a case of performing exposure through a liquid immersion medium. Further, the receding contact angle is more preferably 75° or more, and still more preferably 75° to 850.

In a case where the receding contact angle is extremely small, it cannot be suitably used in a case of performing exposure through a liquid immersion medium, and further, an effect of reducing watermark defect cannot be sufficiently exhibited. In order to realize a preferable receding contact angle, it is preferable to incorporate a hydrophobic resin which will be described later into the composition. Alternatively, a film (hereinafter also referred to as a “topcoat”) sparingly soluble in an immersion liquid, which is formed with the hydrophobic resin on the upper layer of the resist film, may be provided on the upper layer of a resist film including the hydrophobic resin. The functions required for the topcoat are coating suitability on the upper layer part of the resist film, and sparing solubility in an immersion liquid. It is preferable that the topcoat is not mixed with the resist film and can be uniformly applied onto the upper layer of the resist film.

Specific examples of materials constituting the topcoat include a hydrocarbon polymer, an acrylic acid ester polymer, a polymethacrylic acid, a polyacrylic acid, a polyvinyl ether, a silicon-containing polymer, and a fluorine-containing polymer. From the viewpoint that an optical lens is contaminated in a case where impurities are eluted from the topcoat to the immersion liquid, it is preferable that the amounts of residual monomer components of the polymer included in the topcoat are small. The topcoat may include a basic compound.

For the release of the topcoat, a developer may be used, or a release agent may separately be used. As the release agent, a solvent that rarely penetrates the film is preferable. In a view that the releasing step can be performed simultaneously with the developing step of the film, it is preferable that the topcoat is released by a developer including an organic solvent.

In a case where there is no difference in the refractive index between the topcoat and the immersion liquid. In this case, the resolving power is improved. In a case where water is used as the immersion liquid, the topcoat preferably has a refractive index close to that of the immersion liquid. From the viewpoint that the refractive index is close to that of the immersion liquid, the topcoat preferably has a fluorine atom. Further, a thin film is preferable from the viewpoints of transparency and the refractive index.

It is preferable that the topcoat is not mixed with the film and the immersion liquid. From this viewpoint, in a case where the immersion liquid is water, it is preferable that a solvent used for the topcoat is sparingly soluble in a solvent used for the composition of the present invention and is a water-insoluble medium. Further, in a case where the immersion liquid is an organic solvent, the topcoat may be water-soluble or water-insoluble.

Formation of the topcoat is not limited to a case of the liquid immersion exposure, and may also be carried out in a case of dry exposure (exposure not through an immersion liquid). By forming the topcoat, for example, generation of out-gases can be suppressed.

Hereinafter, the topcoat composition used for formation of the topcoat will be described.

The solvent used in the topcoat composition is preferably an organic solvent, and more preferably an alcohol-based solvent.

In a case where the solvent is the organic solvent, a solvent that does not dissolve the resist film is preferable. As the available solvent, an alcohol-based solvent, a fluorine-based solvent, or a hydrocarbon-based solvent are preferable, and a non-fluorine alcohol-based solvent is more preferable. As the alcohol-based solvent, a primary alcohol is preferable, and a primary alcohol having 4 to 8 carbon atoms is more preferable, from the viewpoint of coatability. As the primary alcohol having 4 to 8 carbon atoms, linear, branched, and cyclic alcohols can be used, but preferred examples thereof include 1-butanol, 1-hexanol, 1-pentanol, 3-methyl-1-butanol, 2-ethylbutanol, and perfluorobutyl tetrahydrofuran.

In addition, as the resin for the topcoat composition, the resin having an acidic group described in JP2009-134177A and JP2009-91798A can be preferably used.

The weight-average molecular weight of the resin is not particularly limited, but is preferably 2,000 to 1,000,000, more preferably 5,000 to 500,000, and still more preferably 10,000 to 100,000. Here, the weight-average molecular weight of the resin represents a molecular weight in terms of polystyrene, measured by gel permeation chromatography (GPC) (carrier: tetrahydrofuran (THF) or N-methyl-2-pyrrolidone (NMP)).

The pH of the topcoat composition is not particularly limited, but is preferably 0 to 10, more preferably 0 to 8, and particularly preferably 1 to 7.

The topcoat composition may contain additives such as a photoacid generator and a nitrogen-containing basic compound. Examples of the topcoat composition containing the nitrogen-containing basic compound include those in US2013/0244438A.

The concentration of the resin in the topcoat composition is preferably 0.1% to 10% by mass, more preferably 0.2% to 5% by mass, and still more preferably 0.3% to 3% by mass. The topcoat composition includes components other than the resin, and the proportion of the resin occupied in the solid content of the topcoat composition is preferably 80% to 100% by mass, more preferably 90% to 100% by mass, and still more preferably 95% to 100% by mass.

The concentration of the solid content of the topcoat composition is preferably 0.1% to 10% by mass, more preferably 0.2% to 6% by mass, and still more preferably 0.3% to 5% by mass. By setting the concentration of the solid content within the range, the topcoat composition can be uniformly applied onto the resist film.

In the pattern forming method of the present invention, the resist film can be formed on a substrate, using the composition, and a topcoat can also be formed on the resist film, using the topcoat composition. The film thickness of the resist film is preferably 10 to 100 nm, and the film thickness of the topcoat is preferably 10 to 200 nm, more preferably 20 to 100 nm, and still more preferably 40 to 80 nm.

A method for forming the topcoat is not particularly limited, but the topcoat can be formed by applying and drying the topcoat composition by the same means as the method for forming the resist film.

The resist film having the topcoat thereon is irradiated with actinic rays or radiation, usually through a mask, preferably baked (heated), and developed, whereby a good pattern can be obtained.

In the liquid immersion exposure step, it is necessary for the immersion liquid to move on a wafer following the movement of an exposure head which scans the wafer at a high speed to form an exposed pattern. Therefore, the contact angle of the immersion liquid for the resist film in a dynamic state is important, and the resist is required to have a performance of allowing the immersion liquid to follow the high-speed scanning of an exposure head with no remaining of a liquid droplet.

(Step C (Developing Step))

The step C is a step of developing the exposed film using a developer to form a pattern.

The type of the developer used in the present step is not particularly limited, but examples thereof include a developer containing an alkali developer or an organic solvent (the developer is hereinafter also referred to an organic developer), with the alkali developer being preferable.

As the alkali developer, for example, aqueous alkali solutions of inorganic alkalis such as sodium hydroxide, potassium hydroxide, sodium carbonate, sodium silicate, sodium metasilicate, and aqueous ammonia, primary amines such as ethylamine and n-propylamine, secondary amines such as diethylamine and di-n-butylamine, tertiary amines such as triethylamine and methyldiethylamine, alcohol amines such as dimethylethanolamine and triethanolamine, quaternary ammonium salts such as tetraalkylammonium hydroxides such as tetramethylammonium hydroxide, tetraethylammonium hydroxide, tetrapropylammonium hydroxide, tetrabutylammonium hydroxide, tetrapentylammonium hydroxide, tetrahexylammonium hydroxide, tetraoctylammonium hydroxide, ethyltrimethylammonium hydroxide, butyltrimethylammonium hydroxide, methyltriamylammonium hydroxide, and dibutyldipentylammonium hydroxide, trimethylphenylammonium hydroxide, trimethylbenzylammonium hydroxide, and triethylbenzylammonium hydroxide, cyclic amines such as pyrrole and piperidine, or the like can be used. Further, alcohols and a surfactant can also be added to the aqueous alkali solution in an appropriate amount before use. The alkali concentration of the alkali developer is usually 0.1% to 20% by mass. The pH of the alkali developer is usually 10.0 to 15.0. It is possible to appropriately adjust and use the alkali concentration and the pH of the alkali developer. The alkali developer may also be used after adding a surfactant or an organic solvent thereto.

As the rinsing liquid in the rinsing treatment carried out after the alkali development, pure water is used, and the rinsing liquid can also be used after adding an appropriate amount of a surfactant thereto.

In addition, after the developing treatment or the rinsing treatment, a treatment of removing the developer or rinsing liquid adhering to the pattern by a supercritical fluid can be carried out.

As the organic developer, a polar solvent such as a ketone-based solvent, an ester-based solvent, an alcohol-based solvent, an amide-based solvent, or an ether-based solvent, and a hydrocarbon-based solvent can be used, and specific examples thereof include the solvents described in paragraph <0507> of JP2013-218223A, and isoamyl acetate, butyl butanoate, methyl 2-hydroxyisobutyrate, isobutyl isobutyrate, and butyl propionate.

The above-mentioned solvents can be used by mixing a plurality of the solvents or by mixing the solvents with solvents other than the solvents or water. However, in order to sufficiently exhibit the effects of the present invention, the moisture content in the entire developer is preferably less than 10% by mass, but a developer having substantially no water is more preferable.

That is, the amount of the organic solvent to be used with respect to the organic developer is preferably from 90% by mass to 100% by mass, and preferably from 95% by mass to 100% by mass, with respect to the total amount of the developer.

In particular, the organic developer is preferably a developer containing at least one organic solvent selected from the group consisting of a ketone-based solvent, an ester-based solvent, an alcohol-based solvent, an amide-based solvent, and an ether-based solvent.

The vapor pressure of the organic developer is preferably 5 kPa or less, more preferably 3 kPa or less, and particularly preferably 2 kPa or less, at 20° C. By setting the vapor pressure of the organic developer to 5 kPa or less, the evaporation of the developer on the substrate or in a developing cup is suppressed, the temperature uniformity in the wafer surface is improved, and as a result, the dimensional uniformity within a wafer surface is improved.

It is possible to add an appropriate amount of a surfactant to the organic developer, as desired. In addition, the surfactants may be used in combination of two or more kinds thereof.

The surfactant is not particularly limited, but it is possible to use, for example, ionic or non-ionic fluorine-based and/or silicon-based surfactants, or the like. Examples of the fluorine- and/or silicon-based surfactant include the surfactants described in JP1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540A), JP1995-230165A (JP-H07-230165A), JP1996-62834A (JP-H08-62834A), JP1997-54432A (JP-H09-54432A), JP1997-5988A (JP-H09-5988A), U.S. Pat. No. 5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511A, and U.S. Pat. No. 5,824,451A, and non-ionic surfactants are preferable. The non-ionic surfactant is not particularly limited, but it is more preferable to use a fluorine-based surfactant or a silicon-based surfactant.

The amount of the surfactant to be used is usually 0.001% to 5% by mass, preferably 0.005% to 2% by mass, and more preferably 0.01% to 0.5% by mass, with respect to the total amount of the developer.

The organic developer may include a basic compound. Specific and preferred examples of the basic compound which can be included in the organic developer used in the present invention are the same ones as for the basic compound which can be included in the composition, as an acid diffusion control agent which will be described later.

Examples of the developing method include a method in which a substrate is immersed in a tank filled with a developer for a certain period of time (a dip method), a method in which development is performed by heaping a developer up onto the surface of a substrate by surface tension, and then standing it for a certain period of time (a puddle method), a method in which a developer is sprayed on the surface of a substrate (a spray method), and a method in which a developer is continuously discharged onto a substrate spun at a constant rate while scanning a developer discharging nozzle at a constant rate (a dynamic dispense method).

In a case where the various developing methods include a step of discharging a developer toward a resist film from a development nozzle of a developing device, the discharge pressure of the developer discharged (the flow rate per unit area of the developer discharged) is preferably 2 mL/sec/mm² or less, more preferably 1.5 mL/sec/mm² or less, and still more preferably 1 mL/sec/mm² or less. The flow rate has no particular lower limit, but is preferably 0.2 mL/sec/mm² or more in consideration of throughput.

By setting the discharge pressure of the discharged developer to the above-mentioned range, pattern defects resulting from the resist scum after development can be significantly reduced.

Details on the mechanism are not clear, but it is thought that it is due to the pressure imposed on the resist film by the developer being decreased by setting the discharge pressure to the above-described range so that the resist film and/or the resist pattern is suppressed from being inadvertently cut or collapsing.

In addition, the discharge pressure (mL/sec/mm²) of the developer is the value at the outlet of the development nozzle in the developing device.

Examples of the method for adjusting the discharge pressure of the developer include a method of adjusting the discharge pressure by a pump, and a method of supplying a developer from a pressurized tank and adjusting the pressure to change the discharge pressure.

In addition, after the step of performing development, using a developer including an organic solvent, a step of stopping the development while replacing the solvent with another solvent may be carried out.

In the pattern forming method of the present invention, a step of performing development by using a developer including an organic solvent (organic solvent developing step) and a step of carrying out development by using an aqueous alkali solution (alkali developing step) may be used in combination. Thus, a finer pattern can be formed.

In the present invention, an area with a low exposure intensity is removed in the organic solvent developing step, and by further carrying out the alkali developing step, an area with a high exposure intensity is also removed. By virtue of a multiple development process in which development is carried out in a plurality of times in such a manner, a pattern can be formed by keeping only a region with an intermediate exposure intensity from not being dissolved, so that a finer pattern than usual can be formed (the same mechanism as in <0077> of JP2008-292975A).

In the pattern forming method of the present invention, the order of the alkali developing step and the organic solvent developing step is not particularly limited, but it is more preferable that the alkali development is carried out before the organic solvent developing step.

It is preferable that a step of performing washing using a rinsing liquid is carried out after the step of performing development using a developer including an organic solvent.

The rinsing liquid used in the rinsing step after the step of performing development using a developer including an organic solvent is not particularly limited as long as the rinsing liquid does not dissolve the resist pattern, and a solution including a common organic solvent can be used. As the rinsing liquid, a rinsing liquid containing at least one organic solvent selected from the group consisting of a hydrocarbon-based solvent, a ketone-based solvent, an ester-based solvent, an alcohol-based solvent, an amide-based solvent, and an ether-based solvent is preferably used.

Specific examples of the hydrocarbon-based solvent, the ketone-based solvent, the ester-based solvent, the alcohol-based solvent, the amide-based solvent, and the ether-based solvent include the same solvents as those described for the developer including an organic solvent.

After the developing step using a developer including an organic solvent, it is more preferable to carry out a step of performing washing using a rinsing liquid containing at least one organic solvent selected from the group consisting of a ketone-based solvent, an ester-based solvent, an alcohol-based solvent, an amide-based solvent, and a hydrocarbon-based solvent, it is still more preferable to carry out a step of performing washing using a rinsing liquid containing an alcohol-based solvent or an ester-based solvent, it is particularly preferable to carry out a step of performing washing using a rinsing liquid containing a monohydric alcohol, and it is the most preferable to carry out a step of performing washing using a rinsing liquid containing a monohydric alcohol having 5 or more carbon atoms.

Here, examples of the monohydric alcohol used in the rinsing step include linear, branched, or cyclic monohydric alcohols, and specifically, 1-butanol, 2-butanol, 3-methyl-1-butanol, tert-butyl alcohol, 1-pentanol, 2-pentanol, 1-hexanol, 4-methyl-2-pentanol, 1-heptanol, 1-octanol, 2-hexanol, cyclopentanol, 2-heptanol, 2-octanol, 3-hexanol, 3-heptanol, 3-octanol, and 4-octanol, with a monohydric alcohol having 5 or more carbon atoms, such as 1-hexanol, 2-hexanol, 4-methyl-2-pentanol, 1-pentanol, 3-methyl-1-butanol, being preferable.

The rinsing liquid containing the hydrocarbon-based solvent is preferably a hydrocarbon compound having 6 to 30 carbon atoms, more preferably a hydrocarbon compound having 8 to 30 carbon atoms, still more preferably a hydrocarbon compound having 7 to 30 carbon atoms, and particularly preferably a hydrocarbon compound having 10 to 30 carbon atoms. By using a rinsing liquid including decane and/or undecane among these, pattern collapse is suppressed.

In a case where an ester-based solvent is used as the rinsing liquid, a glycol ether-based solvent may be used, in addition to the ester-based solvent (one kind or two or more kinds). Specific examples of such a case include use of an ester-based solvent (preferably butyl acetate) as a main component and a glycol ether-based solvent (preferably propylene glycol monomethyl ether (PGME)) as a side component. Thus, residue defects are suppressed.

The respective components in plural numbers may be mixed, or the components may be mixed with an organic solvent other than the above solvents, and used.

The moisture content of the rinsing liquid is preferably 10% by mass or less, more preferably 5% by mass or less, and still more preferably 3% by mass or less. By setting the moisture content to 10% by mass or less, good development characteristics can be obtained.

The vapor pressure at 20° C. of the rinsing liquid which is used after the step of carrying out development using a developer including an organic solvent is preferably 0.05 to 5 kPa, more preferably 0.1 to 5 kPa, and still more preferably 0.12 to 3 kPa. By setting the vapor pressure of the rinsing liquid to 0.05 to 5 kPa, the temperature uniformity within a wafer surface is improved, and further, the dimensional uniformity within a wafer surface is enhanced by suppression of swelling due to the permeation of the rinsing liquid.

An appropriate amount of a surfactant may be added to the rinsing liquid.

In the rinsing step, a washing treatment is performed using a rinsing liquid. A method for the washing treatment is not particularly limited, and examples thereof include a method in which a rinsing liquid is continuously discharged on a substrate spun at a constant rate (a rotation application method), a method in which a substrate is immersed in a tank filled with a rinsing liquid for a certain period of time (a dip method), and a method in which a rinsing liquid is sprayed on a substrate surface (a spray method). Among these, a method in which a washing treatment is carried out using a rotation application method, and a substrate is rotated at a rotation speed of 2,000 rpm to 4,000 rpm after washing, thereby removing the rinsing liquid from the substrate, is preferable.

Furthermore, it is preferable that a heating step (Post Bake) is carried out after the rinsing step. The residual developer and the rinsing liquid between and inside the patterns are removed by the baking. The heating step after the rinsing step is carried out at usually 40° C. to 160° C., and preferably at 70° C. to 95° C., and usually for 10 seconds to 3 minutes, and preferably for 30 seconds to 90 seconds.

(Step (D))

Moreover, it is also preferable that a step of subjecting a film to a heating treatment (step D) is provided after the step B and before the step C.

The temperature for the heating step is not particularly limited, but is 160° C. or lower in many cases, and in a view that the effect of the present invention is superior, the temperature is preferably 115° C. or lower, more preferably lower than 115° C., and still more preferably 110° C. or lower. The lower limit is not particularly limited, but is 50° C. or higher in many cases.

The heating time is preferably 30 to 300 seconds, more preferably 30 to 180 seconds, and still more preferably 30 to 90 seconds.

The heating may be carried out using a means equipped in ordinary exposure and development machines, or may also be carried out using a hot plate or the like.

The baking accelerates the reaction in the exposed areas, and thus, the sensitivity and the pattern profile are enhanced.

<Actinic Ray-Sensitive or Radiation-Sensitive Resin Composition>

Hereinafter, the respective components which may be included in the actinic ray-sensitive or radiation-sensitive resin composition will be described in detail. Usually, the actinic ray-sensitive or radiation-sensitive resin composition include a resin (A) (resin whose solubility in a developer changes by the action of an acid), an acid generator (compound capable of generating an acid upon irradiation with actinic rays or radiation), a solvent, and the like.

<Resin Whose Solubility in Developer is Changed by Action of Acid (Hereinafter Also Referred to as “Resin (A)”)>

The resin contained in the composition of the present invention is a resin whose solubility in a developer changes by the action of an acid (for example: a resin whose solubility in an alkali developer changes by the action of an acid), and is preferably, for example, a resin whose solubility in an alkali developer increases by the action of an acid or whose solubility in a developer having an organic solvent as a main component decreases by the action of an acid, and is also preferably a resin having a group (hereinafter also referred to as an “acid-decomposable group”) that is decomposed by the action of an acid in the main chain or a side chain, or both a main chain and the side chain of the resin to generate an alkali-soluble group. The resin (A) preferably has a group capable of decomposing by the action of an acid to generate a polar group.

The resin (A) is preferably insoluble or sparingly soluble in an alkali developer.

In one of suitable aspects of the resin (A), the resin (A) preferably has a molar light absorption coefficient & at a wavelength of 243 nm of more than 200 L·mol⁻¹·cm⁻¹. In a case where the molar light absorption coefficient E of the resin (A) is within the range, the value of γ is reduced, and the effects of the present invention are more excellent.

Incidentally, a suitable range of the molar light absorption coefficient ε is preferably 5,000 L·mol⁻¹·cm⁻¹ or more, and more preferably 10,000 L·mol⁻¹·cm⁻¹ or more. The upper limit is not particularly limited, but is 50,000 L·mol⁻¹·cm⁻¹ or more in many cases.

As for a method for measuring the molar light absorption coefficient ε, 0.1 g of the resin (A) is weighed and completely dissolved in 1,000 mL of acetonitrile, the absorbance of the solution is measured using a spectrophotometer (UV-2500PC, manufactured by Shimadzu Corporation), and a molar light absorption coefficient ε is calculated by the following equation. Further, the optical path length of a cell used in this measurement is 1 cm.

A=ε·C·l Equation:

(A: absorbance, C: concentration (mol/L), l: optical path length (cm))

The acid-decomposable group preferably has a structure in which an alkali-soluble group is protected with a group capable of leaving by the decomposition by the action of an acid.

Examples of the alkali-soluble group include a phenolic hydroxyl group, a carboxyl group, a fluorinated alcohol group, a sulfonic acid group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group.

Preferred examples of the alkali-soluble group include a carboxyl group, a fluorinated alcohol group (preferably a hexafluoroisopropanol group), and a sulfonic acid group.

The group which is preferable as the acid-decomposable group is a group in which a hydrogen atom of the alkali-soluble group is substituted with a group capable of leaving by an acid.

Examples of the group capable of leaving by an acid include —C(R₃₆)(R₃₇)(R₃₈), —C(R₃₆)(R₃₇)(OR₃₉), and —C(R₀₁)(R₀₂)(OR₃₉).

In the formulae, R₃₆ to R₃₉ each independently represent an alkyl group, a cycloalkyl group, an aryl group, an aralkyl group, or an alkenyl group. R₃₆ and R₃₇ may be bonded to each other to form a ring.

R₀₁ and R₀₂ each independently represent a hydrogen atom, an alkyl group, a cycloalkyl group, an aryl group, an aralkyl group, or an alkenyl group.

The acid-decomposable group is preferably a cumyl ester group, an enol ester group, an acetal group, an acetal ester group, a tertiary alkyl ester group, or the like, and more preferably a tertiary alkyl ester group.

As the repeating unit having an acid-decomposable group, which can be contained in the resin (A), a repeating unit represented by General Formula (AI) is preferable.

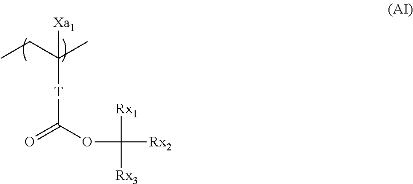

In General Formula (AI),

Xa₁ represents a hydrogen atom, or an alkyl group which may have a substituent.

T represents a single bond or a divalent linking group.

Rx₁ to Rx₃ each independently represent an (linear or branched) alkyl group or a (monocyclic or polycyclic) cycloalkyl group.

Two of Rx₁ to Rx₃ may be bonded to each other to form a (monocyclic or polycyclic) cycloalkyl group.

Examples of the alkyl group which may have a substituent, represented by Xa₁, include a methyl group or a group represented by —CH₂—R₁₁. R₁₁ represents a halogen atom (a fluorine atom or the like), a hydroxyl group, or a monovalent organic group, and examples thereof include an alkyl group having 5 or less carbon atoms, and an acyl group having 5 or less carbon atoms, preferably an alkyl group having 3 or less carbon atoms, and more preferably a methyl group. In one aspect, Xa₁ is preferably a hydrogen atom, a methyl group, a trifluoromethyl group, a hydroxymethyl group, or the like.

Examples of the divalent linking group of T include an alkylene group, a —COO-Rt- group, and an —O-Rt- group. In the formulae, Rt represents an alkylene group or a cycloalkylene group.

T is preferably a single bond or a —COO-Rt- group. Rt is preferably an alkylene group having 1 to 5 carbon atoms, and more preferably a —CH₂— group, a —(CH₂)₂— group, or a —(CH₂)₃— group.

As the alkyl group of Rx₁ to Rx₃, an alkyl group having 1 to 4 carbon atoms, such as a methyl group, an ethyl group, an n-propyl group, an isopropyl group, an n-butyl group, an isobutyl group, and a t-butyl group is preferable.

As the cycloalkyl group of Rx₁ to Rx₃, a monocyclic cycloalkyl group such as a cyclopentyl group and a cyclohexyl group, and a polycyclic cycloalkyl group such as a norbornyl group, a tetracyclodecanyl group, a tetracyclododecanyl group, and an adamantyl group are preferable.

As the cycloalkyl group formed by the mutual bonding of two of Rx₁ to Rx₃, a monocyclic cycloalkyl group such as a cyclopentyl group and a cyclohexyl group, and a polycyclic cycloalkyl group such as a norbornyl group, a tetracyclodecanyl group, a tetracyclododecanyl group, and an adamantyl group are preferable, and a monocyclic cycloalkyl group having 5 or 6 carbon atoms is particularly preferable.

In the cycloalkyl group formed by the mutual bonding of two of Rx₁ to Rx₃, for example, one of the methylene groups constituting the ring may be substituted with a heteroatom such as an oxygen atom, or with a group having a heteroatom, such as a carbonyl group.

An aspect of the repeating unit represented by General Formula (AI), for example, in which Rx₁ is a methyl group or an ethyl group, and Rx₂ and Rx₃ are bonded to each other to form the above-mentioned cycloalkyl group, is preferable.

Each of the groups may have a substituent, and examples of the substituent include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms), with those having 8 or less carbon atoms being preferable.

The total content of the repeating unit having an acid-decomposable group is preferably 20% to 90% by mole, more preferably 25% to 85% by mole, and still more preferably 30% to 80% by mole, with respect to all the repeating units in the resin (A).

Specific preferred examples of the repeating unit having an acid-decomposable group are set forth below, but the present invention is not limited thereto.

In the specific examples, Rx and Xa₁ each represent a hydrogen atom, CH₃, CF₃, or CH₂OH. Rxa and Rxb each represent an alkyl group having 1 to 4 carbon atoms. Z represents a substituent containing a polar group, and in a case where Z's are present in plural numbers, they are each independent. p represents 0 or a positive integer. Examples of the substituent containing a polar group, represented by Z, include a linear or branched alkyl group, and a cycloalkyl group, each having a hydroxyl group, a cyano group, an amino group, an alkylamido group, or a sulfonamido group, and preferably an alkyl group having a hydroxyl group. As the branched alkyl group, an isopropyl group is particularly preferable.

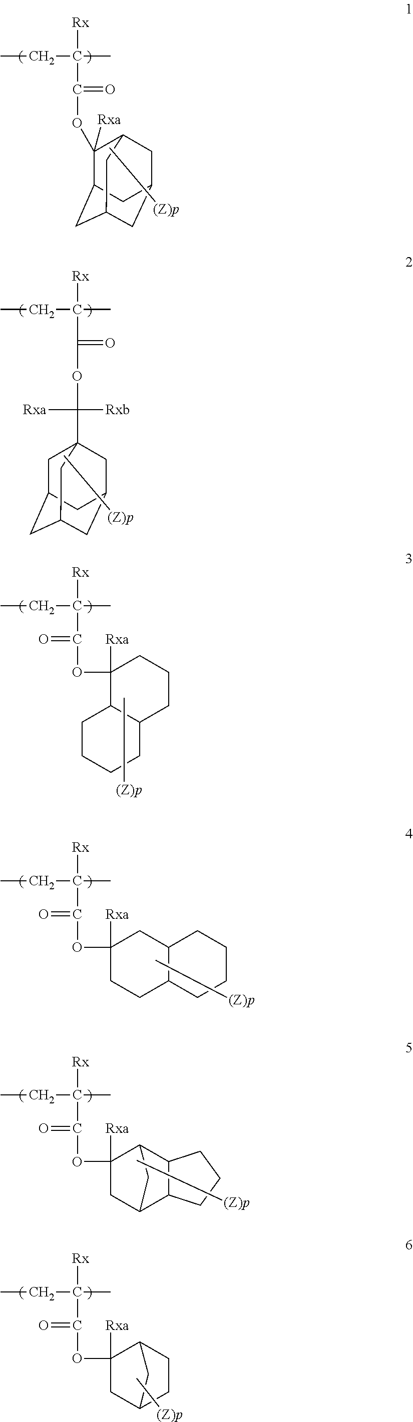

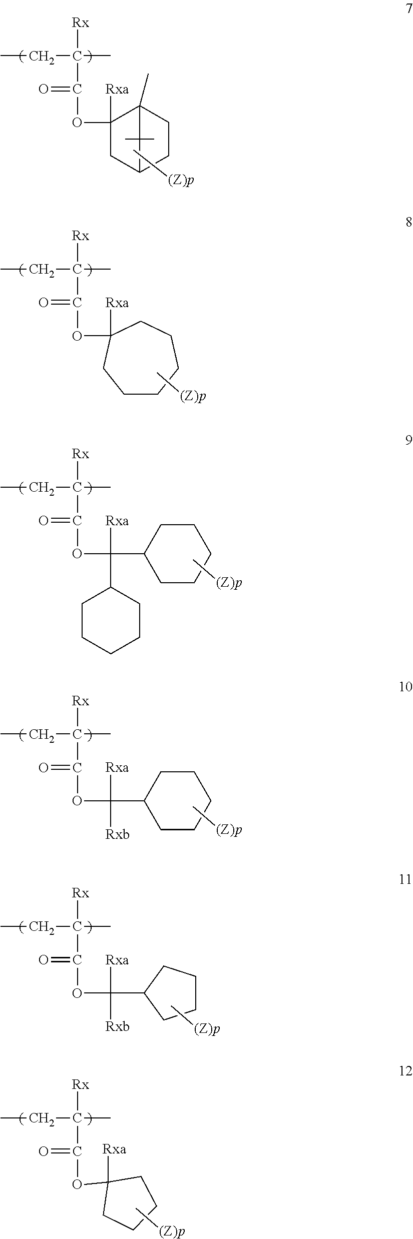

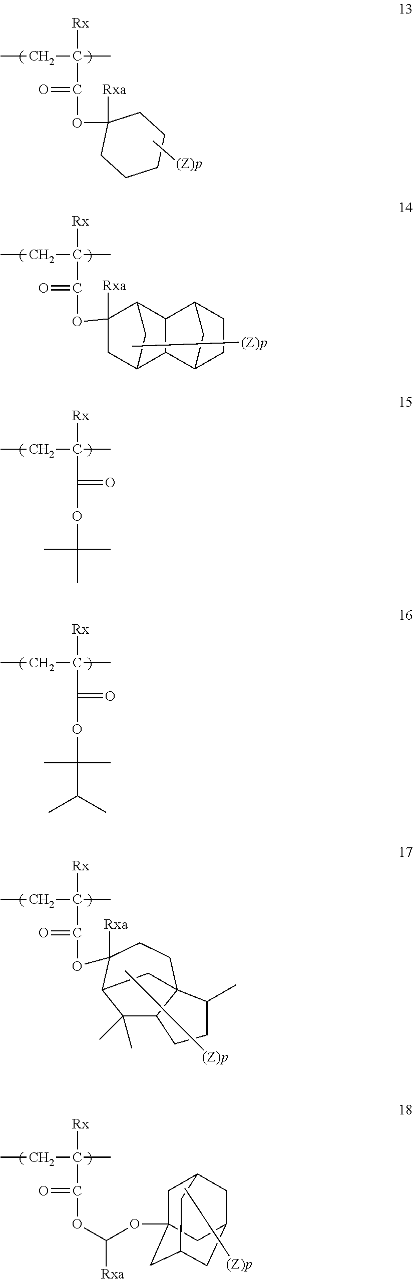

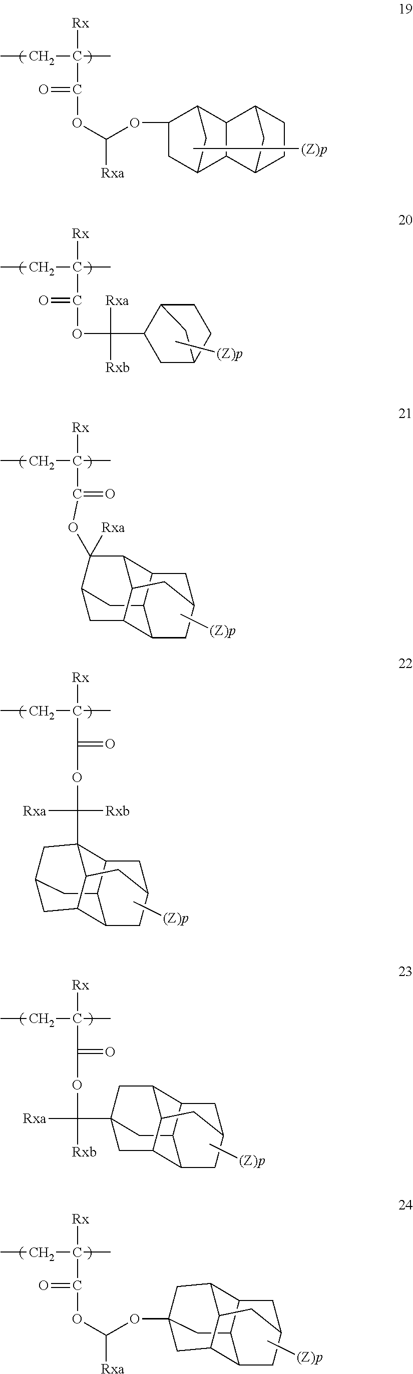

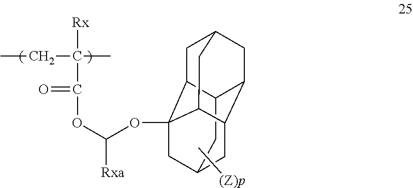

It is preferable that the resin (A) contains, for example, a repeating unit represented by General Formula (3), as the repeating unit represented by General Formula (AI).

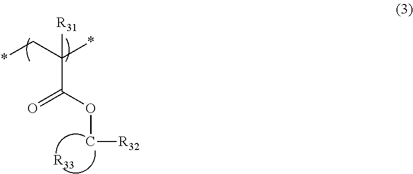

In General Formula (3),

R₃₁ represents a hydrogen atom or an alkyl group.

R₃₂ represents an alkyl group or a cycloalkyl group, and specific examples thereof include a methyl group, an ethyl group, an n-propyl group, an isopropyl group, an n-butyl group, an isobutyl group, a sec-butyl group, a tert-butyl group, and a cyclohexyl group.

R₃₃ represents an atomic group required for forming a monocyclic alicyclic hydrocarbon structure together with a carbon atom to which R₃₂ is bonded. In the alicyclic hydrocarbon structure, a part of the carbon atoms constituting the ring may be substituted with a heteroatom or a group having a heteroatom.

The alkyl group of R₃₁ may have a substituent, and examples of the substituent include a fluorine atom and a hydroxyl group. R₃₁ preferably represents a hydrogen atom, a methyl group, a trifluoromethyl group, or a hydroxymethyl group.

R₃₂ is preferably a methyl group, an ethyl group, an n-propyl group, an isopropyl group, a tert-butyl group, or a cyclohexyl group, and more preferably a methyl group, an ethyl group, an isopropyl group, or a tert-butyl group.

The monocyclic alicyclic hydrocarbon structure formed of R₃₃ together with a carbon atom is preferably a 3- to 8-membered ring, and more preferably a 5- or 6-membered ring.

In the monocyclic alicyclic hydrocarbon structure formed of R₃₃ together with a carbon atom, examples of the heteroatom which can constitute a ring include an oxygen atom and a sulfur atom, and examples of the group having a heteroatom include a carbonyl group. However, it is preferable that the group having a heteroatom is not an ester group (ester bond).

It is preferable that the monocyclic alicyclic hydrocarbon structure formed of R₃₃ together with a carbon atom is formed of only carbon atoms and hydrogen atoms.

The resin (A) preferably contains a repeating unit having a lactone structure or sultone (cyclic sulfonic acid ester) structure.

As the lactone group or sultone group, any group having a lactone structure or sultone structure can be used, and is preferably a 5- to 7-membered ring lactone structure or sultone structure, with a 5- to 7-membered ring lactone structure or sultone structure to which another ring structure is fused so as to form a bicyclo structure or spiro structure being preferable. The resin still more preferably has a repeating unit having a lactone structure or sultone structure represented by any one of General Formulae (LC1-1) to (LC1-17), General Formula (SL1-1), and General Formula (SL1-2). Further, the lactone structure or sultone structure may be directly bonded to the main chain. A preferred lactone structure or sultone structure is General Formula (LC1-1), General Formula (LC1-4), General Formula (LC1-5), or General Formula (LC1-8), with General Formula (LC1-4) being more preferable. By using a specific lactone structure or sultone structure, line width roughness (LWR) and development defects are improved.

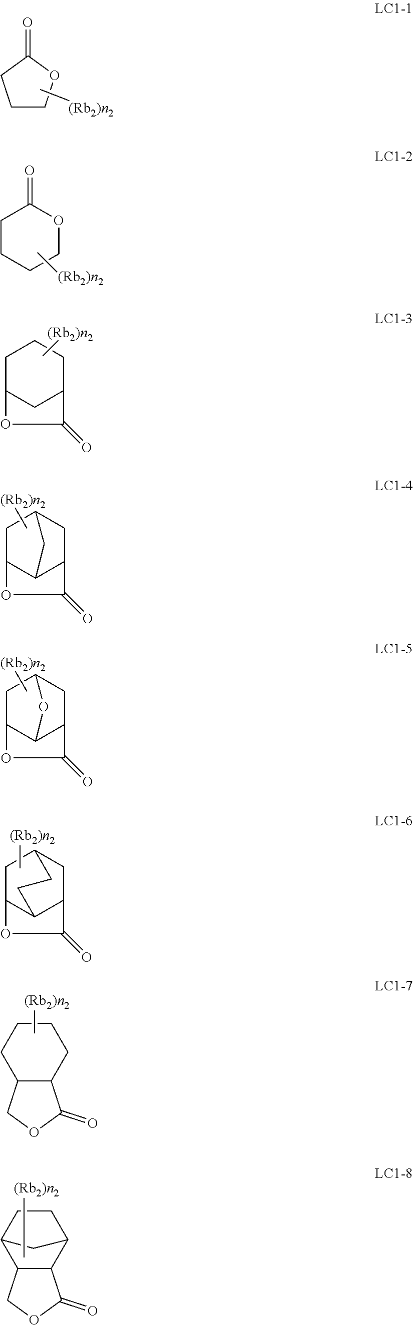

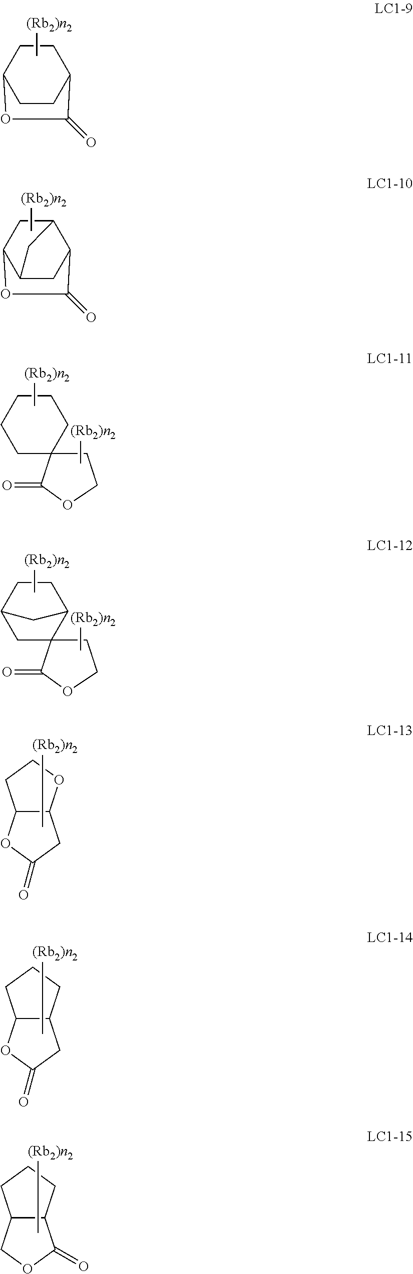

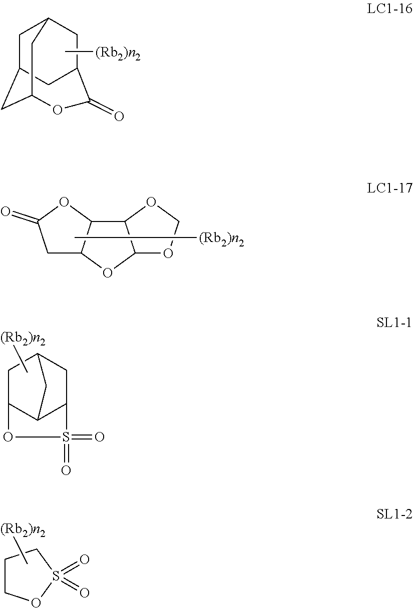

The repeating unit having a lactone group or sultone group usually has an optical isomer, and any optical isomer may be used. Further, one kind of optical isomer may be used singly or a plurality of optical isomers may be mixed and used. In a case of mainly using one kind of optical isomer, the optical purity (ee) thereof is preferably 90% or more, and more preferably 95% or more.

The resin (A) preferably has a repeating unit having a hydroxyl group or a cyano group. Thus, adhesiveness to a substrate, and affinity for a developer are enhanced. The repeating unit having a hydroxyl group or a cyano group is preferably a repeating unit having an alicyclic hydrocarbon structure substituted with a hydroxyl group or a cyano group, and preferably has no acid-decomposable group. In the alicyclic hydrocarbon structure substituted with a hydroxyl group or a cyano group, as the alicyclic hydrocarbon structure, an adamantyl group, a diadamantyl group, and a norbornane group are preferable. As the alicyclic hydrocarbon structure substituted with a hydroxyl group or a cyano group, partial structures represented by General Formulae (VIIa) to (VIId) are preferable.

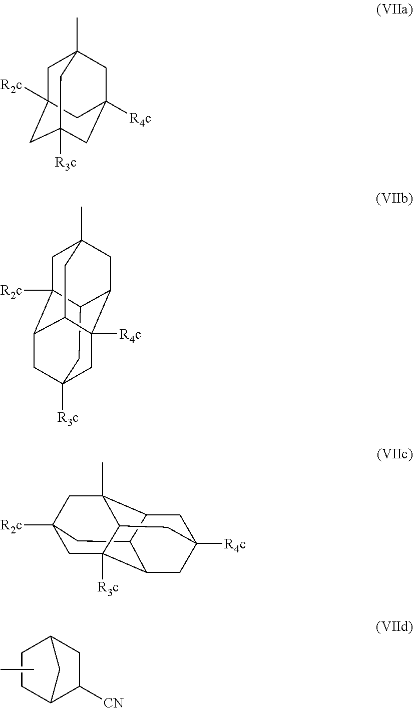

In General Formulae (VIIa) to (VIIc),

R₂c to R₄c each independently represent a hydrogen atom, a hydroxyl group, or a cyano group. Here, at least one of R₂c, . . . , or R₄c represents a hydroxyl group or a cyano group. Preferably one or two of R₂c to R₄c are a hydroxyl group while the remainder is a hydrogen atom. In General Formula (VIIa), it is more preferable that two of R₂c to R₄c are a hydroxyl group and the remainder is a hydrogen atom.

In addition to the repeating structural units, the resin (A) used in the composition of the present invention can have a variety of repeating structural units for the purpose of adjusting dry-etching resistance, suitability for a standard developer, adhesiveness to a substrate, and a resist profile, and in addition, resolving power, heat resistance, sensitivity, and the like, which are characteristics generally required for the resist. Examples of such repeating structural units include, but are not limited to, repeating structural units corresponding to the following monomers.

Thus, it becomes possible to perform fine adjustments to performance required for the resin used in the composition of the present invention, in particular, (1) solubility with respect to a coating solvent, (2) film forming properties (glass transition point), (3) alkali developability, (4) film reduction (selection of hydrophilic, hydrophobic, or alkali-soluble groups), (5) adhesiveness of an unexposed area to a substrate, (6) dry-etching resistance, and the like.

Examples of such a monomer include a compound having one addition-polymerizable unsaturated bond selected from acrylic esters, methacrylic esters, acrylamides, methacrylamides, allyl compounds, vinyl ethers, vinyl esters, and the like.

In addition to these, an addition-polymerizable unsaturated compound that is copolymerizable with the monomers corresponding to various repeating structural units as described above may be copolymerized.

In the resin (A) used in the composition of the present invention, the molar ratio of each repeating structural unit content is appropriately set in order to adjust dry-etching resistance, suitability for a standard developer, adhesiveness to a substrate, and a resist profile of the resist, and in addition, resolving power, heat resistance, sensitivity, and the like, each of which is performance generally required for the resist.

In a case where the composition of the present invention is for ArF exposure, it is preferable that the resin (A) used in the composition of the present invention does not substantially have an aromatic group in terms of transparency to ArF light. More specifically, the proportion of repeating units having an aromatic group in all the repeating units of the resin (A) is preferably 5% by mole or less, and more preferably 3% by mole or less, and ideally, the proportion is more preferably 0% by mole of all the repeating units, that is, the resin (A) does not have a repeating unit having an aromatic group. Further, it is preferable that the resin (A) has a monocyclic or polycyclic alicyclic hydrocarbon structure.

In a case of irradiating the composition of the present invention with KrF excimer laser light, electron beams, X-rays, or high-energy beams at a wavelength of 50 nm or less (for example, EUV), it is preferable that the resin (A) contains a hydroxystyrene repeating unit. The resin (A) is more preferably a copolymer of hydroxystyrene with hydroxystyrene protected with a group capable of leaving by the action of an acid, or a copolymer of hydroxystyrene with tertiary alkyl (meth)acrylate ester.

Specific examples of such a resin include a resin having a repeating unit represented by General Formula (A).

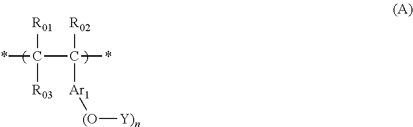

In the formula, R₀₁, R₀₂, and R₀₃ each independently represent, for example, a hydrogen atom, an alkyl group, a cycloalkyl group, a halogen atom, a cyano group, or an alkoxycarbonyl group. An represents, for example, an aromatic ring group. Further, R₀₃ and Ar₁ are each an alkylene group, or both of them may be bonded to each other, together with a —C—C— chain, to form a 5- or 6-membered ring.

n Y's each independently represent a hydrogen atom or a group capable of leaving by the action of an acid, provided that at least one of Y's represents a group capable of leaving by the action of an acid.

n represents an integer of 1 to 4, and is preferably 1 or 2, and more preferably 1.

The alkyl group as each of R₀₁ to R₀₃ is, for example, an alkyl group having 20 or less carbon atoms, preferably a methyl group, an ethyl group, a propyl group, an isopropyl group, an n-butyl group, a sec-butyl group, a hexyl group, a 2-ethylhexyl group, an octyl group, or a dodecyl group. More preferably, these alkyl groups are alkyl groups having 8 or less carbon atoms. Further, these alkyl groups may have a substituent.

The alkyl group included in the alkoxycarbonyl group is preferably the same as the alkyl group in R₀₁ to R₀₃.

The cycloalkyl group may be a monocyclic cycloalkyl group or a polycyclic cycloalkyl group. Preferred examples thereof include a monocyclic cycloalkyl group having 3 to 8 carbon atoms, such as a cyclopropyl group, a cyclopentyl group, and a cyclohexyl group. Further, these cycloalkyl groups may have a substituent.

Examples of the halogen atom include a fluorine atom, a chlorine atom, a bromine atom, and an iodine atom, with the fluorine atom being more preferable.

In a case where R₀₃ represents an alkylene group, preferred examples of the alkylene group include ones having 1 to 8 carbon atoms, such as a methylene group, an ethylene group, a propylene group, a butylene group, a hexylene group, and an octylene group.

The aromatic ring group as Ar₁ is preferably one having 6 to 14 carbon atoms, and examples thereof include a benzene ring, a toluene ring, and a naphthalene ring. Further, these aromatic ring groups may have a substituent.

Examples of the group Y capable of leaving by the action of an acid include groups represented by —C(R₃₆)(R₃₇)(R₃₈), —C(═O)—O—C(R₃₆)(R₃₇)(R₃₈), —C(R₀₁)(R₀₂)(OR₃₉), —C(R₀₁)(R₀₂)—C(═O)—O—C(R₃₆)(R₃₇)(R₃₈), or —CH(R₃₆)(Ar).

In the formulae, R₃₆ to R₃₉ each independently represent an alkyl group, a cycloalkyl group, an aryl group, an aralkyl group, or an alkenyl group. R₃₆ and R₃₇ may be bonded to each other to form a ring structure.

R₀₁ and R₀₂ each independently represent a hydrogen atom, an alkyl group, a cycloalkyl group, an aryl group, an aralkyl group, or an alkenyl group.

Ar represents an aryl group.

As the alkyl group as R₃₆ to R₃₉, R₀₁, or R₀₂, an alkyl group having 1 to 8 carbon atoms is preferable, and examples thereof include a methyl group, an ethyl group, a propyl group, an n-butyl group, a sec-butyl group, a hexyl group, and an octyl group.

A cycloalkyl group as R₃₆ to R₃₉, R₀₁, or R₀₂ may be a monocyclic cycloalkyl group or a polycyclic cycloalkyl group. As the monocyclic cycloalkyl group, a cycloalkyl group having 3 to 8 carbon atoms is preferable, and examples thereof include a cyclopropyl group, a cyclobutyl group, a cyclopentyl group, a cyclohexyl group, and a cyclooctyl group. As the polycyclic cycloalkyl group, a cycloalkyl group having 6 to 20 carbon atoms is preferable, and examples thereof include an adamantyl group, a norbornyl group, an isobornyl group, a camphonyl group, a dicyclopentyl group, an α-pinanyl group, a tricyclodecanyl group, a tetracyclododecyl group, and an androstanyl group. Further, some of the carbon atoms in the cycloalkyl group may be substituted with heteroatoms such as an oxygen atom.

An aryl group as R₃₆ to R₃₉, R₀₁, or R₀₂, or Ar is preferably an aryl group having 6 to 10 carbon atoms and examples thereof include a phenyl group, a naphthyl group, and an anthryl group.

An aralkyl group as R₃₆ to R₃₉, R₀₁, or R₀₂ is preferably an aralkyl group with 7 to 12 carbon atoms and for example, a benzyl group, a phenethyl group, and a naphthylmethyl group are preferable.

An alkenyl group as R₃₆ to R₃₉, R₀₁, or R₀₂ is preferably an alkenyl group with 2 to 8 carbon atoms and examples thereof include a vinyl group, an allyl group, a butenyl group, and a cyclohexenyl group.

A ring which can be formed by the mutual bonding of R₃₆ and R₃₇ may be monocyclic or polycyclic. The monocyclic ring is preferably a cycloalkane structure having 3 to 8 carbon atoms, and examples thereof include a cyclopropane structure, a cyclobutane structure, a cyclopentane structure, a cyclohexane structure, a cycloheptane structure, and a cyclooctane structure. The polycyclic ring is preferably a cycloalkane structure having 6 to 20 carbon atoms, and examples thereof include an adamantane structure, a norbornane structure, a dicyclopentane structure, a tricyclodecane structure, and a tetracyclododecane structure. Further, a part of carbon atoms in the ring structure may be substituted with the heteroatom such as an oxygen atom.

Each of the groups may have a substituent. Examples of the substituent include an alkyl group, a cycloalkyl group, an aryl group, an amino group, an amido group, an ureido group, an urethane group, a hydroxyl group, a carboxyl group, a halogen atom, an alkoxy group, a thioether group, an acyl group, an acyloxy group, an alkoxycarbonyl group, a cyano group, and a nitro group. Theses substituents preferably have 8 or less carbon atoms.

Examples of the group Y capable of leaving by the action of an acid in General Formula (A) include groups represented by Formulae (Y1) to (Y4).

—C(Rx₁)(Rx₂)(Rx₃) Formula (Y1):

—C(═O)O(Rx₁)(Rx₂)(Rx₃) Formula (Y2):

—C(R₃₆)(R₃₇)(OR₃₈) Formula (Y3):

—C(Rn)(H)(Ar) Formula (Y4):

In Formulae (Y1) and (Y2), Rx₁ to Rx₃ each independently represent an (linear or branched) alkyl group or a (monocyclic or polycyclic) cycloalkyl group. Here, in a case where all of Rx₁ to Rx₃ are (linear or branched) alkyl group, at least two of Rx₁, . . . , or Rx₃ are preferably methyl groups.

The repeating unit represented by General Formula (A) is more preferably a repeating unit in which Rx₁ to Rx₃ each independently represent a linear or branched alkyl group, and still more preferably a repeating unit in which Rx₁ to Rx₃ each independently represent a linear alkyl group.

Two of Rx₁ to Rx₃ may be bonded to each other to form a (monocyclic or polycyclic) cycloalkyl group.

The alkyl group of each of Rx₁ to Rx₃ is preferably an alkyl group having 1 to 4 carbon atoms, such as a methyl group, an ethyl group, an n-propyl group, an isopropyl group, an n-butyl group, an isobutyl group, and a t-butyl group.

The cycloalkyl group of each of Rx₁ to Rx₃ is preferably a monocyclic cycloalkyl group such as a cyclopentyl group and a cyclohexyl group, and a polycyclic cycloalkyl group such as a norbornyl group, a tetracyclodecanyl group, a tetracyclododecanyl group, and an adamantyl group.

The cycloalkyl group formed by mutual bonding of two of Rx₁ to Rx₃ is preferably a monocyclic cycloalkyl group such as a cyclopentyl group and a cyclohexyl group, and a polycyclic cycloalkyl group such as a norbornyl group, a tetracyclodecanyl group, a tetracyclododecanyl group, and an adamantyl group. The monocyclic cycloalkyl group having 5 or 6 carbon atoms is particularly preferable.

In the cycloalkyl group formed by mutual bonding of two of Rx₁ to Rx₃, for example, one of methylene groups constituting the ring may be substituted with a heteroatom such as an oxygen atom, or a group having a heteroatom, such as a carbonyl group.

An aspect of the group represented by General Formula (Y1) or (Y2), for example, in which Rx₁ is a methyl group or an ethyl group, and Rx₂ and Rx₃ are bonded to each other to form the above-mentioned cycloalkyl group, is preferable.

In Formula (Y3), R₃₆ to R₃₈ each independently represent a hydrogen atom or a monovalent organic group. R₃₇ and R₃₈ may be bonded to each other to form a ring. Examples of the monovalent organic group include an alkyl group, a cycloalkyl group, an aryl group, an aralkyl group, and an alkenyl group. It is also preferable that R₃₆ is a hydrogen atom.

As preferred Formula (Y3), a structure represented by General Formula (Y3-1) is more preferable.

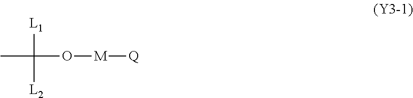

Here, L₁ and L₂ each independently represent a hydrogen atom, an alkyl group, a cycloalkyl group, an aryl group, or a group obtained by combining an alkylene group with an aryl group.

M represents a single bond or a divalent linking group.

Q represents an alkyl group, a cycloalkyl group which may include a heteroatom, an aryl group which may include a heteroatom, an amino group, an ammonium group, a mercapto group, a cyano group, or an aldehyde group.

It is preferable that at least one of L₁ or L₂ is a hydrogen atom, and at least one of L₁ or L₂ is an alkyl group, a cycloalkyl group, an aryl group, or a group obtained by combining an alkylene group with an aryl group.

At least two of Q, M, and L₁ may be bonded to each other to form a ring (preferably a 5- or 6-membered ring).

For the improvement of pattern collapse performance, L₂ preferably is a secondary or tertiary alkyl group, and more preferably a tertiary alkyl group. Examples of the secondary alkyl group include an isopropyl group, a cyclohexyl group, and a norbornyl group, and examples of the tertiary alkyl group include a tert-butyl group and an adamantane group. In these aspects, since Tg or activation energy is high, suppression of fogging can be achieved, in addition to secured film hardness.

In Formula (Y4), Ar represents an aromatic ring group. Rn represents an alkyl group, a cycloalkyl group, or an aryl group. Rn and Ar may be bonded to each other to form a non-aromatic ring. Ar is more preferably an aryl group.

Further, it is preferable that the resin (A) does not contain a fluorine atom and a silicon atom, from the viewpoint of compatibility with a hydrophobic resin which will be described later.

The resin (A) used in the composition of the present invention is preferably a resin in which all the repeating units are constituted with (meth)acrylate-based repeating units. In this case, any of a resin in which all of the repeating units are methacrylate-based repeating units, a resin in which all of the repeating units are acrylate-based repeating units, a resin in which all of the repeating units are methacrylate-based repeating units and acrylate-based repeating units can be used, but it is preferable that the acrylate-based repeating units account for 50% by mole or less of all of the repeating units. Further, a copolymerization polymer including 20% to 50% by mole of (meth)acrylate-based repeating units having an acid-decomposable group, 20% to 50% by mole of (meth)acrylate-based repeating units having a lactone group, 5% to 30% by mole of (meth)acrylate-based repeating units having an alicyclic hydrocarbon structure substituted with a hydroxyl group or a cyano group, and 0% to 20% by mole of other (meth)acrylate-based repeating units is also preferable.

The resin (A) can be synthesized in accordance with an ordinary method (for example, radical polymerization). Examples of the general synthesis method include a bulk polymerization method in which polymerization is carried out by dissolving monomer species and an initiator in a solvent and heating the solution, a dropwise addition polymerization method in which a solution of monomer species and an initiator is added dropwise to a heating solvent for 1 hour to 10 hours, with the dropwise addition polymerization method being preferable. Examples of the reaction solvent include ether-based solvents such as tetrahydrofuran, 1,4-dioxane, and diisopropyl ether, ketone-based solvents such as a methyl ethyl ketone and methyl isobutyl ketone, ester-based solvents such as ethyl acetate, amide-based solvents such as dimethyl formamide and dimethyl acetamide, and a solvent which dissolves the composition of the present invention, such as propylene glycol monomethyl ether acetate, propylene glycol monomethyl ether, and cyclohexanone, which will be described later. It is more preferable to perform polymerization using the same solvent as the solvent used in the composition of the present invention. Thus, generation of the particles during storage can be suppressed.

It is preferable that the polymerization reaction is carried out in an inert gas atmosphere such as nitrogen and argon. As the polymerization initiator, commercially available radical initiators (an azo-based initiator, a peroxide, or the like) are used to initiate the polymerization. As the radical initiator, an azo-based initiator is preferable, and the azo-based initiator having an ester group, a cyano group, or a carboxyl group is preferable. Preferred examples of the initiator include azobisisobutyronitrile, azobisdimethylvaleronitrile, dimethyl 2,2′-azobis(2-methyl propionate), or the like. The initiator is added or added in portionwise, as desired, and a desired polymer is recovered after the reaction is completed, the reaction mixture is poured into a solvent, and then a method such as powder or solid recovery is used. The concentration of the reactant is 5% to 50% by mass, and preferably 10% to 30% by mass. The reaction temperature is normally 10° C. to 150° C., preferably 30° C. to 120° C., and more preferably 60° C. to 100° C.

The weight-average molecular weight of the resin (A) of the present invention is preferably 1,000 to 200,000, more preferably 2,000 to 20,000, still more preferably 3,000 to 15,000, and particularly preferably 3,000 to 11,000. By setting the weight-average molecular weight to 1,000 to 200,000, it is possible to prevent the deterioration of heat resistance or dry-etching resistance, and also prevent the deterioration of film forming properties due to deterioration of developability or increased viscosity.

With regard to the resin (A) and the compound (C), the weight-average molecular weight (Mw), the number-average molecular weight (Mn), and the dispersity (Mw/Mn) represent values in terms of polystyrene by means of GPC measurement. The weight-average molecular weight and the number-average molecular weight can be calculated, using HLC-8120 (manufactured by Tosoh Corporation), TSK gel Multipore HXL-M (manufactured by Tosoh Corporation, 7.8 mmIDx30.0 cm) as a column, and tetrahydrofuran (THF) as an eluant.

The dispersity (molecular weight distribution) is usually in the range of 1.0 to 3.0, and a dispersity in the range of preferably 1.0 to 2.6, more preferably 1.0 to 2.0, and still more preferably 1.1 to 2.0 is used. The smaller the molecular weight distribution is, the better the resolution and the resist shape are, the smoother the side wall of the resist pattern is, and the better roughness is.

The content of the resin (A) in the total composition is preferably 30% to 99% by mass, and more preferably 50% to 95% by mass, with respect to the total solid contents.

In addition, the resin (A) may be used singly or in combination of two or more kinds thereof.

<Acid Generator (Compound (B) Capable of Generating Acid Upon Irradiation with Actinic Rays or Radiation)>

The acid generator contained in the composition of the present invention is not particularly limited as long as it is a compound capable of generating an acid upon irradiation with actinic rays or radiation (hereinafter also referred to as a “compound (B)”, an “acid generator”, or an “acid generator (B)”).

The compound (B) is preferably a compound capable of generating an organic acid upon irradiation with actinic rays or radiation.

The compound (B) may be in a form of a low-molecular-weight compound or a form incorporated into a part of a polymer. Further, a combination of the form of a low-molecular-weight compound and the form incorporated into a part of a polymer may also be used.

In a case where the compound (B) is in the form of a low-molecular-weight compound, the molecular weight is preferably 3,000 or less, more preferably 2,000 or less, and still more preferably 1,000 or less.

In a case where the compound (B) is in the form incorporated into a part of a polymer, it may be incorporated into a part of the resin (A) as described above or into a resin other than the resin (A). Specific examples of a case where the compound (B) is in the form incorporated into a part of a polymer include those described in, for example, paragraphs <0191> to <0209> of JP2013-54196A.

The acid generator which is appropriately selected from a photoinitiator for cationic photopolymerization, a photoinitiator for radical photopolymerization, a photodecoloring agent for dyes, a photodiscoloring agent, a known compound capable of generating an acid upon irradiation with actinic rays or radiation, which is used for a microresist or the like, and a mixture thereof, can be used.

Examples of the acid generator include a diazonium salt, a phosphonium salt, a sulfonium salt, an iodonium salt, imidosulfonate, oxime sulfonate, diazodisulfone, disulfone, and o-nitrobenzyl sulfonate.

As the acid generator, an acid generator having a pKa of a generated acid of −2 or more is preferable. Among those, in a view of a smaller deviation of the thickness among the formed patterns, pKa is preferably −1.5 or more, and more preferably −1 or more. Further, the upper limit of pKa is not particularly limited, but is preferably 1 or less.

The pKa (acid strength) is one of indices for quantitatively expressing the strength of an acid, and has the same definition as an acidity constant. The acid strength (pKa) refers to, upon contemplation of a dissociation reaction in which a hydrogen ion is released from an acid, the equilibrium constant (Ka) of the reaction expressed by the negative common logarithm pKa thereof. As the value of pKa is smaller, the acid is the stronger. In the present invention, the acid strength (pKa) is calculated by a calculation using an analysis software package ACD/pKa DB V8.0 manufactured by Advanced Chemistry Development (ACD).

Examples of the preferred compounds among the acid generators include a compound represented by General Formula (ZI), (ZII), or (ZIII).

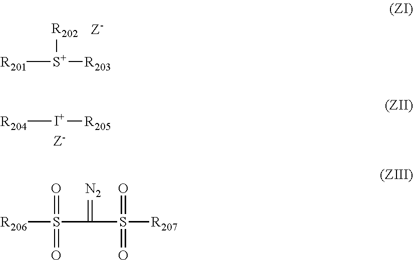

In General Formula (ZI),

R₂₀₁, R₂₀₂, and R₂₀₃ each independently represent an organic group.

The number of carbon atoms of the organic group as R₂₀₁, R₂₀₂, and R₂₀₃ is generally 1 to 30, and preferably 1 to 20.

Furthermore, two of R₂₀₁ to R₂₀₃ may be bonded to each other to form a ring structure, and the ring may include an oxygen atom, a sulfur atom, an ester bond, an amide bond, or a carbonyl group, and examples of the group formed by the bonding of two of R₂₀₁ to R₂₀₃ include an alkylene group (for example, a butylene group and a pentylene group).

Z⁻ represents a non-nucleophilic anion.

Examples of the non-nucleophilic anion as Z⁻ include a sulfonate anion, a carboxylate anion, a sulfonylimide anion, a bis(alkylsulfonyl)imide anion, and a tris(alkylsulfonyl)methyl anion.

The non-nucleophilic anion is an anion having a noticeably low ability for causing a nucleophilic reaction, and is an anion which can suppress temporal decomposition caused by an intra-molecular nucleophilic reaction. Thus, the temporal stability of the composition is improved.

Examples of the sulfonate anion include an aliphatic sulfonate anion, an aromatic sulfonate anion, and a camphorsulfonate anion.

Examples of the carboxylate anion include an aliphatic carboxylate anion, an aromatic carboxylate anion, and an aralkyl carboxylate anion.

The aliphatic site in the aliphatic sulfonate anion and the aliphatic carboxylate anion may be either an alkyl group or a cycloalkyl group, but preferred examples thereof include an alkyl group having 1 to 30 carbon atoms and a cycloalkyl group having 3 to 30 carbon atoms. Examples of the aromatic group in the aromatic sulfonate anion and the aromatic carboxylate anion is preferably an aryl group having 6 to 14 carbon atoms, and examples thereof include a phenyl group, a tolyl group, and a naphthyl group.

The alkyl group, the cycloalkyl group, and the aryl group in the aliphatic sulfonate anion and the aromatic sulfonate anion may have a substituent.

Other examples of the non-nucleophilic anions include fluorinated phosphorus (for example, PF₆⁻), fluorinated boron (for example, BF₄⁻), and fluorinated antimony (for example, SbF₆⁻).

The non-nucleophilic anion of Z⁻ is preferably an aliphatic sulfonate anion substituted with a fluorine atom at least at the α-position of sulfonic acid, an aromatic sulfonate anion substituted with a fluorine atom or a fluorine atom-containing group, a bis(alkylsulfonyl)imide anion in which the alkyl group is substituted with a fluorine atom, or a tris(alkylsulfonyl)methide anion in which the alkyl group is substituted with a fluorine atom. The non-nucleophilic anion is more preferably a perfluoroaliphatic sulfonate anion having 4 to 8 carbon atoms or a benzenesulfonate anion having a fluorine atom, and still more preferably a nonafluorobutanesulfonate anion, a perfluorooctanesulfonate anion, a pentafluorobenzenesulfonate anion, or a 3,5-bis(trifluoromethyl)benzenesulfonate anion.

The non-nucleophilic anion of Z⁻ is preferably represented by General Formula (2). In this case, the volume of the generated acid is increased, and thus, diffusion of an acid is suppressed.

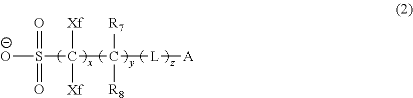

In General Formula (2),

Xf's each independently represent a fluorine atom or an alkyl group substituted with at least one fluorine atom.

R₇ and R₈ each independently represent a hydrogen atom, a fluorine atom, an alkyl group, or an alkyl group substituted with at least one fluorine atom, and in a case where a plurality of R₇'s and R₈'s are present, they may be the same as or different from each other.

L represents a divalent linking group, and in a case where a plurality of L's are present, they may be the same as or different from each other.

A represents an organic group including a cyclic structure.

x represents an integer of 1 to 20, y represents an integer of 0 to 10, and z represents an integer of 0 to 10.

The anion of General Formula (2) will be described in more detail.

As described above, Xf is a fluorine atom or an alkyl group substituted with at least one fluorine atom, and the alkyl group in the alkyl group substituted with a fluorine atom is preferably an alkyl group having 1 to 10 carbon atoms, and more preferably an alkyl group having 1 to 4 carbon atoms. Further, the alkyl group substituted with a fluorine atom of Xf is preferably a perfluoroalkyl group.

Xf is preferably a fluorine atom or a perfluoroalkyl group having 1 to 4 carbon atoms. Specific examples of Xf include a fluorine atom, CF₃, C₂F₅, C₃F₇, C₄F₉, C₅F₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉, with the fluorine atom and CF₃ being preferred. In particular, it is preferable that both Xf's are fluorine atoms.

As described above, R₆ and R₇ each represent a hydrogen atom, a fluorine atom, an alkyl group, or an alkyl group substituted with at least one fluorine atom. An alkyl group having 1 to 4 carbon atoms is preferable, and a perfluoroalkyl group having 1 to 4 carbon atoms is more preferable. Specific examples of the alkyl group substituted with at least one fluorine atom of R₆ and R₇ include CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉, and among these, CF₃ is preferable.

L represents a divalent linking group, and examples thereof include —COO—, —OCO—, —CO—, —O—, —S—, —SO—, —SO₂—, —N(Ri)- (in the formula, Ri represents a hydrogen atom or alkyl), an alkylene group (preferably an alkyl group having 1 to 6 carbon atoms, more preferably an alkyl group having 1 to 4 carbon atoms, particularly preferably a methyl group or an ethyl group, and most preferably a methyl group), a cycloalkylene group (preferably having 3 to 10 carbon atoms), an alkenylene group (preferably having 2 to 6 carbon atoms), and a divalent linking group obtained by combining a plurality of the groups. L is preferably —COO—, —OCO—, —CO—, —SO₂—, —CON(Ri)-, —SO₂N(Ri)-, —CON(Ri)-alkylene group-, —N(Ri)CO-alkylene group-, —COO-alkylene group-, or —OCO-alkylene group-, and more preferably —SO₂—, —COO—, —OCO—, —COO-alkylene group-, or —OCO-alkylene group-. The alkylene group in —CON(Ri)-alkylene group-, —N(Ri)CO-alkylene group-, —COO-alkylene group-, and —OCO-alkylene group- is preferably an alkylene group having 1 to 20 carbon atoms, and more preferably an alkylene group having 1 to 10 carbon atoms. In a case where a plurality of L's are present, they may be the same as or different from each other.

Specific examples of the alkyl group for Ri, and preferred examples thereof include the same ones as the specific examples and the preferred examples mentioned above as each of R₁ to R₄ in General Formula (1).

The organic group including the cyclic structure of A is not particularly limited as long as it has a cyclic structure, and examples of the organic group include an alicyclic group, an aryl group, a heterocyclic group (including the group having aromaticity or not having aromaticity, and including, for example, a tetrahydropyran ring, a lactone ring structure, and a sultone ring structure).

The alicyclic group may be monocyclic or polycyclic, and is preferably a monocyclic cycloalkyl group such as a cyclopentyl group, a cyclohexyl group, and a cyclooctyl group, or polycyclic cycloalkyl group such as a norbornyl group, a norbornenyl group, a tricyclodecanyl group (for example, a tricyclo[5.2.1.0^{(2,6)}]decanyl group), a tetracyclodecanyl group, a tetracyclododecanyl group, and an adamantyl group, with the adamantyl group being preferable. Further, a nitrogen atom-containing alicyclic group such as a piperidine group, a decahydroquinoline group, and a decahydroisoquinoline group is also preferable. Among those, an alicyclic group with a bulky structure having 7 or more carbon atoms, such as a norbornyl group, a tricyclodecanyl group, a tetracyclodecanyl group, a tetracyclododecanyl group, an adamantyl group, a decahydroquinoline group, and a decahydroisoquinoline group is preferable from the viewpoints of suppressing diffusivity into a film in the post-exposure baking (PEB) step. Among those, an adamantyl group and a decahydroisoquinoline group are particularly preferable.

Examples of the aryl group include a benzene ring, a naphthalene ring, a phenanthrene ring, and an anthracene ring. Among those, naphthalene with low absorbance is preferable from the viewpoint of light absorbance at 193 nm.

Examples of the heterocyclic group include a furan ring, a thiophene ring, a benzofuran ring, a benzothiophene ring, a dibenzofuran ring, a dibenzothiophene ring, and a pyridine ring. Among those, a furan ring, a thiophene ring, and a pyridine ring are preferable. Other preferred examples of the heterocyclic group include structures shown below (in the formula, X represents a methylene group or an oxygen atom, and R represents a monovalent organic group).

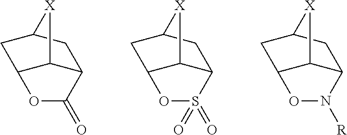

The cyclic organic group may have a substituent, and examples of the substituent include an alkyl group (may be linear, branched, or cyclic; preferably having 1 to 12 carbon atoms), an aryl group (preferably having 6 to 14 carbon atoms), a hydroxyl group, an alkoxy group, an ester group, an amido group, a urethane group, a ureido group, a thioether group, a sulfonamido group, and a sulfonic acid ester group.

Incidentally, the carbon constituting the cyclic organic group (the carbon contributing to ring formation) may be a carbonyl carbon.

x is preferably 1 to 8, more preferably 1 to 4, and particularly preferably 1. y is preferably 0 to 4, more preferably 0 or 1, and still more preferably 1. z is preferably 0 to 8, more preferably 0 to 4, and still more preferably 1.

In the anion in General Formula (2), as a combination of partial structures other than A, SO₃⁻—CF₂—CH₂—OCO—, SO₃⁻—CF₂—CHF—CH₂—OCO—, SO₃⁻—CF₂—COO—, SO₃⁻—CF₂—CF₂—CH₂—, or SO₃⁻—CF₂—CH(CF₃)—OCO— is preferable.

Furthermore, in another embodiment of the present invention, the non-nucleophilic anion of Z⁻ may be a disulfonylimide acid anion.

As the disulfonylimide acid anion, a bis(alkylsulfonyl)imide anion is preferable.

The alkyl group in the bis(alkylsulfonyl)imide anion is preferably an alkyl group having 1 to 5 carbon atoms.

Two alkyl groups in the bis(alkylsulfonyl)imide anion may be linked to each other to form an alkylene group (preferably having 2 to 4 carbon atoms), and the alkylene group may be bonded to an imido group and two sulfonyl groups to form a ring. As the ring structure formed by the bis(alkylsulfonyl)imide anion, a 5- to 7-membered ring is preferable, and a 6-membered ring is more preferable.

Examples of a substituent which may be contained in these alkyl groups and an alkylene group formed by linking two alkyl groups include a halogen atom, an alkyl group substituted with a halogen atom, an alkoxy group, an alkylthio group, an alkyloxysulfonyl group, an aryloxysulfonyl group, and a cycloalkylaryloxysulfonyl group, and a fluorine atom and an alkyl group substituted with a fluorine atom are preferable.

The non-nucleophilic anion of Z⁻ preferably has a fluorine content represented by (a total mass of all the fluorine atoms contained in the anion)/(a total mass of all the atoms contained in the anion) of 0.25 or less, more preferably has the fluorine content of 0.20 or less, and still more preferably has the fluorine content of 0.15 or less.

Examples of the organic group represented by R₂₀₁, R₂₀₂, and R₂₀₃ include corresponding groups in the compounds (ZI-1), (ZI-2), (ZI-3), and (ZI-4) which will be described later.

Incidentally, the compound may be a compound having a plurality of structures represented by General Formula (ZI). For example, the compound may be a compound having a structure in which at least one of R₂₀₁, . . . , or R₂₀₃ in a compound represented by General Formula (ZI) is bonded to at least one of R₂₀₁, . . . , or R₂₀₃ in another compound represented by General Formula (ZI) through a single bond or a linking group.

More preferred examples of the components (ZI) include the compounds (ZI-1), (ZI-2), (ZI-3), and (ZI-4) which will be described below.

First, the compound (ZI-1) will be described.

The compound (ZI-1) is an arylsulfonium compound in which at least one of R₂₀₁, . . . , or R₂₀₃ in General Formula (ZI) is an aryl group, that is, a compound having arylsulfonium as the cation.

In the arylsulfonium compound, all of R₂₀₁ to R₂₀₃ may be an aryl group, or a part of R₂₀₁ to R₂₀₃ may be an aryl group, with the remainder being an alkyl group or a cycloalkyl group.

Examples of the arylsulfonium compound include a triarylsulfonium compound, a diarylalkylsulfonium compound, an aryldialkylsulfonium compound, a diarylcycloalkylsulfonium compound, and an aryldicycloalkylsulfonium compound.

The aryl group in the arylsulfonium compound is preferably a phenyl group or a naphthyl group, and more preferably a phenyl group. The aryl group may be an aryl group having a heterocyclic structure containing an oxygen atom, a nitrogen atom, a sulfur atom, or the like. Examples of the heterocyclic structure include a pyrrole residue, a furan residue, a thiophene residue, an indole residue, a benzofuran residue, and a benzothiophene residue. In a case where the arylsulfonium compound has two or more aryl groups, these two or more aryl groups may be the same as or different from each other.

The alkyl group or the cycloalkyl group which may be contained, if desired, in the arylsulfonium compound, is preferably a linear or branched alkyl group having 1 to 15 carbon atoms or a cycloalkyl group having 3 to 15 carbon atoms, and examples thereof include a methyl group, an ethyl group, a propyl group, an n-butyl group, a sec-butyl group, a t-butyl group, a cyclopropyl group, a cyclobutyl group, and a cyclohexyl group.

The aryl group, the alkyl group, and the cycloalkyl group of R₂₀₁ to R₂₀₃ may have, as the substituent, an alkyl group (for example, an alkyl group having 1 to 15 carbon atoms), a cycloalkyl group (for example, a cycloalkyl group having 3 to 15 carbon atoms), an aryl group (for example, an aryl group having 6 to 14 carbon atoms), an alkoxy group (for example, an alkoxy group having 1 to 15 carbon atoms), a halogen atom, a hydroxyl group, or a phenylthio group.

Next, the compound (ZI-2) will be described.

The compound (ZI-2) is a compound in which R₂₀₁ to R₂₀₃ in Formula (ZI) each independently represent an organic group not having an aromatic ring. The aromatic ring as used herein encompasses an aromatic ring containing a heteroatom.

The organic group not having an aromatic ring as each of R₂₀₁ to R₂₀₃ has generally 1 to 30 carbon atoms, and preferably 1 to 20 carbon atoms.

R₂₀₁ to R₂₀₃ are each independently preferably an alkyl group, a cycloalkyl group, an allyl group, or a vinyl group, more preferably a linear or branched 2-oxoalkyl group, a 2-oxocycloalkyl group, or an alkoxycarbonylmethyl group, and still more preferably a linear or branched 2-oxoalkyl group.

As the alkyl group and the cycloalkyl group of each of R₂₀₁ to R₂₀₃, a linear or branched alkyl group having 1 to 10 carbon atoms (for example, a methyl group, an ethyl group, a propyl group, a butyl group, and a pentyl group), or a cycloalkyl group having 3 to 10 carbon atoms (a cyclopentyl group, a cyclohexyl group, and a norbornyl group) is preferable.

R₂₀₁ to R₂₀₃ may further be substituted with a halogen atom, an alkoxy group (for example, an alkoxy group having 1 to 5 carbon atoms), a hydroxyl group, a cyano group, and a nitro group.

Next, the compound (ZI-3) will be described.

The compound (ZI-3) is a compound represented by General Formula (ZI-3), which has a phenacylsulfonium salt structure.

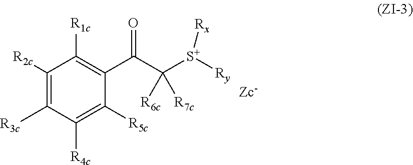

In General Formula (ZI-3),

R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group,

R_{6c} and R_{7c} each independently represent a hydrogen atom, an alkyl group, a cycloalkyl group, a halogen atom, a cyano group, or an aryl group, and

Rₓ and R_{y} each independently represent an alkyl group, a cycloalkyl group, a 2-oxoalkyl group, a 2-oxocycloalkyl group, an alkoxycarbonylalkyl group, an allyl group, or a vinyl group.

Any two or more of R_{1c} to R_{5c}, R_{5c} and R_{6c}, R_{6c} and R_{7c}, R_{5c} and Rₓ, or Rₓ and R_{y} may be respectively bonded to each other to form a ring structure, and this ring structure may contain an oxygen atom, a sulfur atom, a ketone group, an ester bond, or an amide bond.

Examples of the ring structure include an aromatic or non-aromatic hydrocarbon ring, an aromatic or non-aromatic heterocyclic ring, and a polycyclic fused ring formed by combination of two or more of these rings. Examples of the ring structure include 3- to 10-membered rings, with 4- to 8-membered rings being preferable, and 5- or 6-membered rings being more preferable.

Examples of the group formed by the mutual bonding of any two or more of R_{1c} to R_{5c}, R_{6c} and R_{7c}, or Rₓ and R_{y} include a butylene group, and a pentylene group.

The group formed by the mutual bonding of R_{5c} and R_{6c}, or R_{5c} and Rₓ is preferably a single bond or an alkylene group, and examples of the alkylene group include a methylene group and an ethylene group.

Zc⁻ represents a non-nucleophilic anion, and examples thereof include the same ones as the non-nucleophilic anions of Z⁻ in General Formula (ZI).

Specific examples of the alkoxy group in the alkoxycarbonyl group as each of R_{1c} to R_{5c} are the same as the specific examples of the alkoxy group as each of R_{1c} to R_{5c}.

Specific examples of the alkyl group in the alkylcarbonyloxy group and the alkylthio group as each of R_{1c} to R_{5c} are the same as the specific examples of the alkyl group as each of R_{1c} to R_{5c}.

Specific examples of the cycloalkyl group in the cycloalkylcarbonyloxy group as each of R_{1c} to R_{5c} are the same as the specific examples of the cycloalkyl group as each of R_{1c} to R_{5c}.

Specific examples of the aryl group in the aryloxy group and the arylthio group as each of R_{1c} to R_{5c} are the same as the specific examples of the aryl group as each of R_{1c} to R_{5c}.

Examples of the cation in the compound (ZI-2) or (ZI-3) in the present invention include the cations described after paragraph <0036> in the specification of US2012/0076996A1.

Next, the compound (ZI-4) will be described.

The compound (ZI-4) is represented by General Formula (ZI-4).

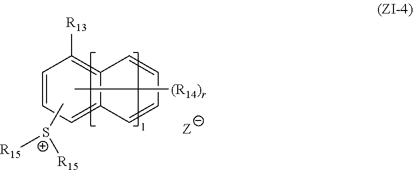

In General Formula (ZI-4),

R₁₃ represents a hydrogen atom, a fluorine atom, a hydroxyl group, an alkyl group, a cycloalkyl group, an alkoxy group, an alkoxycarbonyl group, or a group having a cycloalkyl group, and these groups may have a substituent.

In a case where R₁₄'s are present in plural numbers, they each independently represent a hydroxyl group, an alkyl group, a cycloalkyl group, an alkoxy group, an alkoxycarbonyl group, an alkylcarbonyl group, an alkylsulfonyl group, a cycloalkylsulfonyl group, or a group having a cycloalkyl group, and these groups may have a substituent,

R₁₅'s each independently represent an alkyl group, a cycloalkyl group, or a naphthyl group, these groups may have a substituent, two R₁₅'s may be bonded to each other to form a ring, and in a case where two R₁₅'s are bonded to each other to form a ring, the ring skeleton may contain a heteroatom such as an oxygen atom and a nitrogen atom; and in an aspect, two R₁₅'s are alkylene groups, and are preferably bonded to each other to form a ring structure,

l represents an integer of 0 to 2,

r represents an integer of 0 to 8, and

Z⁻ represents a non-nucleophilic anion, and examples thereof include the same non-nucleophilic anions as Z⁻ in General Formula (ZI).

In General Formula (ZI-4), the alkyl groups of each of R₁₃, R₁₄, and R₁₅ are linear or branched, and preferably have 1 to 10 carbon atoms, and preferred examples thereof include a methyl group, an ethyl group, an n-butyl group, and a t-butyl group.

Examples of the cation of the compound represented by General Formula (ZI-4) in the present invention include the cations described in paragraphs <0121>, <0123>, and <0124> of JP2010-256842A, paragraphs <0127>, <0129>, and <0130> of JP2011-76056A, and the like.

Next, General Formulae (ZII) and (ZIII) will be described.

In General Formulae (ZII) and (ZIII), R₂₀₄ to R₂₀₇ each independently represent an aryl group, an alkyl group, or a cycloalkyl group.

The aryl group of R₂₀₄ to R₂₀₇ is preferably a phenyl group or a naphthyl group, and more preferably a phenyl group. The aryl group of R₂₀₄ to R₂₀₇ may be an aryl group having a heterocyclic structure containing an oxygen atom, a nitrogen atom, a sulfur atom, or the like. Examples of the skeleton of the aryl group having a heterocyclic structure include pyrrole, furan, thiophene, indole, benzofuran, and benzothiophene.

Examples of the alkyl group and the cycloalkyl group with respect to R₂₀₄ to R₂₀₇ include a linear or branched alkyl group having 1 to 10 carbon atoms (for example, a methyl group, an ethyl group, a propyl group, a butyl group, and a pentyl group) and a cycloalkyl group having 3 to 10 carbon atoms (for example, a cyclopentyl group, a cyclohexyl group, and a norbornyl group).

The aryl group, the alkyl group, and the cycloalkyl group of R₂₀₄ to R₂₀₇ may have a substituent, and examples of the substituent which may be contained in the aryl group, the alkyl group, and the cycloalkyl group of each of R₂₀₄ to R₂₀₇ include an alkyl group (for example, an alkyl group having 1 to 15 carbon atoms), a cycloalkyl group (for example, a cycloalkyl group having 3 to 15 carbon atoms), an aryl group (for example, an aryl group having 6 to 15 carbon atoms), an alkoxy group (for example, an alkoxy group having 1 to 15 carbon atoms), a halogen atom, a hydroxyl group, and a phenylthio group.

Z⁻ represents a non-nucleophilic anion, and examples thereof include the same ones as the non-nucleophilic anions of Z⁻ in General Formula (ZI).

Other examples of the acid generator include compounds represented by General Formulae (ZIV), (ZV), and (ZVI).

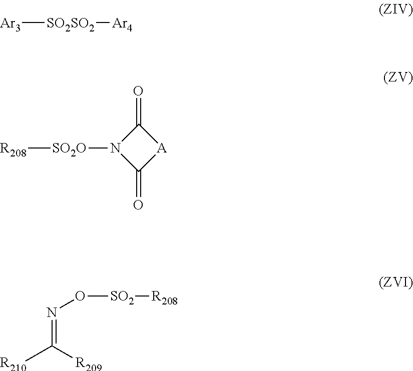

In General Formulae (ZIV) to (ZVI),

Ar₃ and Ar₄ each independently represent an aryl group.

R₂₀₈, R₂₀₉, and R₂₁₀ each independently represent an alkyl group, a cycloalkyl group, or an aryl group.

A represents an alkylene group, an alkenylene group, or an arylene group.

Specific examples of the aryl group of each of Ar₃, Ar₄, R₂₀₈, R₂₀₉, and R₂₁₀ include the same ones as the specific examples of the aryl group of each of R₂₀₁, R₂₀₂, and R₂₀₃ in General Formula (ZI-1).

Specific examples of the alkyl group and the cycloalkyl group of R₂₀₈, R₂₀₉, and R₂₁₀ include the same ones as the specific examples of the alkyl group and the cycloalkyl group of each of R₂₀₁, R₂₀₂, and R₂₀₃ in General Formula (ZI-2).

Examples of the alkylene group of A include an alkylene group having 1 to 12 carbon atoms (for example, a methylene group, an ethylene group, a propylene group, an isopropylene group, a butylene group, and an isobutylene group); examples of the alkenylene group of A include an alkenylene group having 2 to 12 carbon atoms (for example, an ethenylene group, a propenylene group, and a butenylene group); and examples of the arylene group of A include an arylene group having 6 to 10 carbon atoms (for example, a phenylene group, a tolylene group, and a naphthylene group).

Furthermore, another aspect of the acid generator may include a compound capable of generating an acid represented by General Formula (III) or (IV) upon irradiation with actinic rays or radiation.

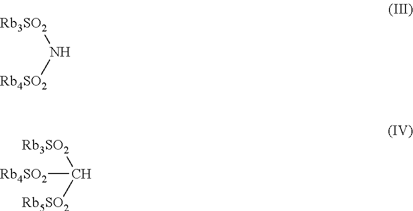

In General Formulae (III) and (IV),

Rb₃ to Rb₅ each independently represent an alkyl group, a cycloalkyl group, or an aryl group. Rb₃ and Rb₄ may be bonded to each other to form a ring structure.

In General Formulae (III) and (IV), Rb₃ to Rb₅ are each more preferably an alkyl group substituted with a fluorine atom or a fluoroalkyl group at the first position, or an aryl group (preferably a phenyl group) substituted with a fluorine atom or a fluoroalkyl group. In a case where the fluorine atom or the fluoroalkyl group is contained, the acidity of an acid generated upon irradiation with light is increased, and thus, the sensitivity is improved. In a case where Rb₃ to Rb₅ each have 5 or more carbon atoms, it is preferable that all of the hydrogen atoms of at least one carbon atom is not substituted with fluorine atoms, and it is more preferable that the number of hydrogen atoms is larger than that of fluorine atoms. In a case where a perfluoroalkyl group having 5 or more carbon atoms is not contained, the toxicity to ecology is reduced.

Rb₃ to Rb₅ are each preferably a perfluoroalkyl group having 1 to 4 carbon atoms, and more preferably a perfluoroalkyl group having 1 to 3 carbon atoms.

Examples of a group formed by the mutual bonding of Rb₃ and Rb₄ include an alkylene group and an arylene group.

The group formed by the mutual bonding of Rb₃ and Rb₄ is preferably a perfluoroalkylene group having 2 to 4 carbon atoms, and more preferably a perfluoropropylene group. In a case where Rb₃ and Rb₄ are bonded to form a ring structure, the acidity is improved and the sensitivity of the composition is also improved, as compared with a case of not forming the ring structure.

A particularly preferred aspect of Rb₃ to Rb₅ may include a group represented by the following general formula.

Rc₇-Ax-Rc₆-

In the general formula,

Rc₆ represents a perfluoroalkylene group, and is more preferably a perfluoroalkylene group having 2 to 4 carbon atoms.

Ax represents a single bond or a divalent linking group (preferably —O—, —CO₂—, —S—, —SO₃—, or —SO₂N(Rd₁)-). Rd₁ represents a hydrogen atom or an alkyl group, or may be bonded to Rc₇ to form a ring structure.

Rc₇ represents a hydrogen atom, a fluorine atom, an alkyl group, a cycloalkyl group, or an aryl group. It is preferable that the alkyl group, the cycloalkyl group, or the aryl group as Rc₇ does not have a fluorine atom as the substituent.

Specific examples of the acid represented by General Formula (III) are set forth below, but the present invention is not limited thereto.

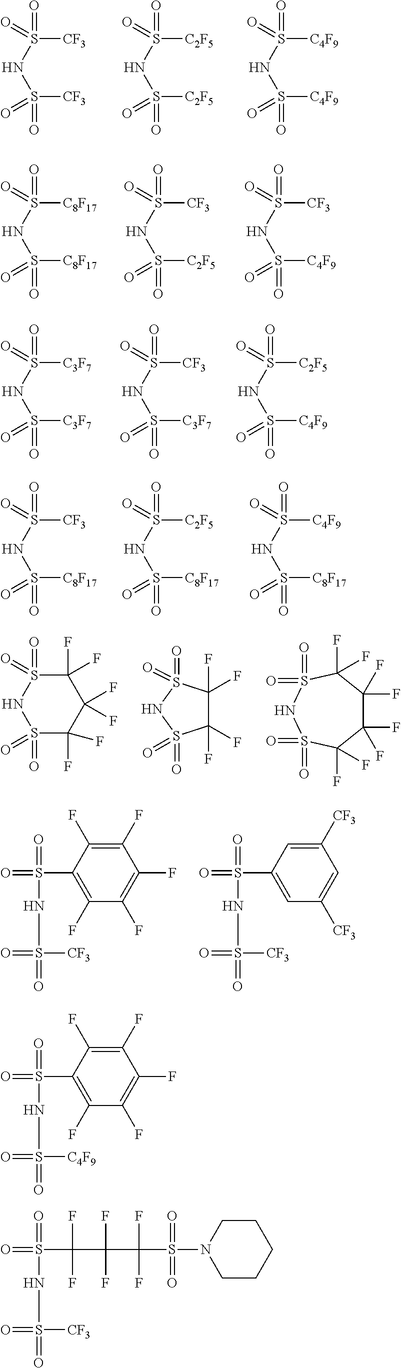

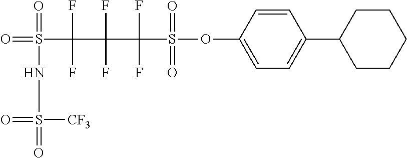

Specific examples of the acid represented by General Formula (IV) are set forth below, but the present invention is not limited thereto.

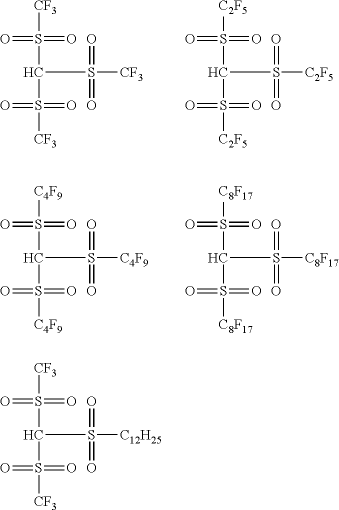

Examples of the compound which generates an acid represented by General Formula (III) or (IV) upon irradiation with actinic rays or radiation include a diazonium salt, a phosphonium salt, a sulfonium salt, an iodonium salt, imidosulfonate, oxime sulfonate, and o-nitrobenzyl sulfonate.

In addition, compounds obtained by introducing into the polymer main chain or side chain thereof, these groups or compounds which generates an acid represented by General Formula (III) or (IV) upon irradiation with actinic rays or radiation, for example, the compounds described in U.S. Pat. No. 3,849,137A, DE3914407B, JP1988-26653A (JP-S63-26653A), JP1980-164824A (JP-S55-164824A), JP1987-69263A (JP-S62-69263A), JP1988-146038A (JP-S63-146038A), JP1988-163452A (JP-S63-163452A), JP1987-153853A (JP-S62-153853A), JP1988-146029A (JP-S63-146029A), and the like can be used.

Furthermore, the compounds capable of generating an acid by light, which are described in U.S. Pat. No. 3,779,778A, EP126712B, and the like can also be used.

Examples of preferred compounds among the compounds capable of generating an acid represented by General Formula (III) or (IV) upon irradiation with actinic rays or radiation include a compound represented by General Formula (ZIa) or (ZIIa).

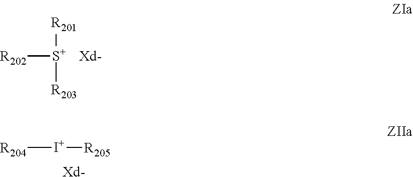

In General Formula (ZIa),

R₂₀₁, R₂₀₂, and R₂₀₃ each independently represent an organic group.

Xd− represents an anion of the acid represented by General Formula (III) or (IV).

Specific examples of the organic group as R₂₀₁, R₂₀₂, and R₂₀₃ in General Formula (ZIa) include groups corresponding to compounds (ZI-1a), (ZI-2a), and (ZI-3a) which will be described later.

Two of R₂₀₁ to R₂₀₃ may be bonded to each other to form a ring structure, and may include an oxygen atom, a sulfur atom, an ester bond, an amide bond, or a carbonyl group within the ring. Examples of the ring formed by the mutual bonding of two of R₂₀₁ to R₂₀₃ include alkylene groups (for example, a butylene group and a pentylene group).

Further, the organic group may also be a compound having a plurality of structures represented by General Formula (ZIa). For example, the organic group may be a compound having a structure in which at least one of R₂₀₁, . . . , or R₂₀₃ of a compound represented by General Formula (ZIa) is bonded to at least one of R₂₀₁, . . . , or R₂₀₃ of another compound represented by General Formula (ZIa).

More preferred examples of the component (ZIa) include compounds (ZI-1a), (ZI-2a) and (ZI-3a) described below.

The compound (ZI-1a) is an arylsulfonium compound having an aryl group as at least one of R₂₀₁, . . . , or R₂₀₃ in General Formula (ZIa), that is, a compound having an arylsulfonium as a cation.

In the arylsulfonium compound, all of R₂₀₁ to R₂₀₃ may be an aryl group or some of R₂₀₁ to R₂₀₃ may be an aryl group with the remaining being an alkyl group or a cycloalkyl group.

Examples of the arylsulfonium compound include a triarylsulfonium compound, a diarylalkylsulfonium compound, an aryldialkylsulfonium compound, a diarylcycloalkylsulfonium compound, and an aryldicycloalkylsulfonium compound.

The aryl group of the arylsulfonium compound is preferably an aryl group such as a phenyl group and a naphthyl group, or a heteroaryl group such as an indole residue and a pyrrole residue, and more preferably a phenyl group or an indole residue. In a case where the arylsulfonium compound has two or more aryl groups, these two or more aryl groups may be the same as or different from each other.

The alkyl group which is contained in the arylsulfonium compound, as necessary, is preferably a linear or branched alkyl group having 1 to 15 carbon atoms, and examples thereof include a methyl group, an ethyl group, a propyl group, an n-butyl group, a sec-butyl group, and a t-butyl group.

The cycloalkyl group which is contained in the arylsulfonium compound, as necessary, is preferably a cycloalkyl group having 3 to 15 carbon atoms, and examples thereof include a cyclopropyl group, a cyclobutyl group, and a cyclohexyl group.

The aryl group, the alkyl group, and the cycloalkyl group of each of R₂₀₁ to R₂₀₃ may have an alkyl group (for example, an alkyl group having 1 to 15 carbon atoms), a cycloalkyl group (for example, a cycloalkyl group having 3 to 15 carbon atoms), an aryl group (for example, an aryl group having 6 to 14 carbon atoms), an alkoxy group (for example, an alkoxy group having 1 to 15 carbon atoms), a halogen atom, a hydroxyl group, or a phenylthio group as a substituent. Preferred examples of the substituent include a linear, branched alkyl group having 1 to 12 carbon atoms, a cycloalkyl group having 3 to 12 carbon atoms, and a linear, branched, or cyclic alkoxy group having 1 to 12 carbon atoms, and more preferably an alkyl group having 1 to 4 carbon atoms and an alkoxy group having 1 to 4 carbon atoms. The substituent may be substituted to any one of three R₂₀₁ to R₂₀₃ or may be substituted to three all of them. Further, in a case where R₂₀₁ to R₂₀₃ are each an aryl group, the substituent is preferably substituted at the p-position of the aryl group.

As the arylsulfonium cation, a triphenylsulfonium cation which may be substituted, a naphthyltetrahydrothiophenium cation which may be substituted, or a phenyltetrahydrothiophenium cation which may be substituted is preferable.

The compound (ZI-2a) will be described next.

The compound (ZI-2a) is a compound of General Formula (ZIa) in which R₂₀₁ to R₂₀₃ each independently represent an organic group containing no aromatic ring. Here, the aromatic ring also encompasses an aromatic ring containing a heteroatom.

The organic group, as each of R₂₀₁ to R₂₀₃, containing no aromatic ring has generally 1 to 30 carbon atoms, and preferably 1 to 20 carbon atoms.

R₂₀₁ to R₂₀₃ each independently preferably represent an alkyl group, a cycloalkyl group, an allyl group, or a vinyl group, more preferably a linear, branched, or cyclic 2-oxoalkyl group, or an alkoxycarbonylmethyl group, and still more preferably a linear or branched 2-oxoalkyl group.

The alkyl group as each of R₂₀₁ to R₂₀₃ may be linear, branched, or cyclic, and preferred examples thereof include a linear or branched alkyl group having 1 to 10 carbon atoms (such as a methyl group, an ethyl group, a propyl group, a butyl group, and a pentyl group). The alkyl group as each of R₂₀₁ to R₂₀₃ is preferably a linear or branched 2-oxoalkyl group, or an alkoxycarbonylmethyl group.

The cycloalkyl group as each of R₂₀₁ to R₂₀₃ is preferably a cycloalkyl group having 3 to 10 carbon atoms (a cyclopentyl group, a cyclohexyl group, or a norbornyl group). The cycloalkyl group as each of R₂₀₁ to R₂₀₃ is more preferably a cyclic 2-oxoalkyl group.

Preferred examples of the linear, branched, or cyclic 2-oxoalkyl group in each of R₂₀₁ to R₂₀₃ include a group having >C═O at the 2-position of the cycloalkyl group.

Preferred examples of the alkoxy group in the alkoxycarbonylmethyl group as each of R₂₀₁ to R₂₀₃ include an alkoxy group having 1 to 5 carbon atoms (such as a methoxy group, an ethoxy group, a propoxy group, a butoxy group, and a pentoxy group).

R₂₀₁ to R₂₀₃ may further be substituted with a halogen atom, an alkoxy group (for example, an alkoxy group having 1 to 5 carbon atoms), a hydroxyl group, a cyano group, or a nitro group.

The compound (ZI-3a) is a compound represented by General Formula (ZI-3a), and is a compound having a phenacylsulfonium salt structure.

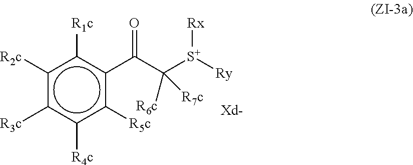

In General Formula (ZI-3a),

R_{1c} to R_{5c} each independently represent a hydrogen atom, an alkyl group, a cycloalkyl group, an alkoxy group, or a halogen atom.

R_{6c} and R_{7c} each independently represent a hydrogen atom, an alkyl group, or a cycloalkyl group.

Rx and Ry each independently represent an alkyl group, a cycloalkyl group, an allyl group, or a vinyl group.

Any two or more of R_{1c} to R_{5c}, or Rx and Ry may be bonded to each other to form a ring structure, and the ring structure may include an oxygen atom, a sulfur atom, an ester bond, or an amide bond. Examples of the group formed by the mutual bonding of any two or more of R_{1c} to R_{5c}, or Rx and Ry include a butylene group and a pentylene group.

Xd⁻ represents an anion of an acid represented by General Formula (III) or (IV), and is the same as Xd− in General Formula (Zia).

The alkyl group as each of R_{1c} to R_{7c} may be linear or branched, and examples thereof include an alkyl group having 1 to 20 carbon atoms, and preferable a linear or branched alkyl group having 1 to 12 carbon atoms (such as a methyl group, an ethyl group, a linear or branched propyl group, a linear or branched butyl group, and a linear or branched pentyl group)

Examples of the cycloalkyl group as each of R_{1c} to R_{7c} include a cycloalkyl group having 3 to 20 carbon atoms, preferably cycloalkyl group having 3 to 8 carbon atoms (for example, a cyclopentyl group and a cyclohexyl group).

The alkoxy group as each of R_{1c} to R_{5c} may be linear, branched, or cyclic, and examples thereof include an alkoxy group having 1 to 10 carbon atoms, and preferably a linear or branched alkoxy group having 1 to 5 carbon atoms (such as a methoxy group, an ethoxy group, a linear or branched propoxy group, a linear or branched butoxy group, and a linear or branched pentoxy group), and a cyclic alkoxy group having 3 to 8 carbon atoms (such as a cyclopentyloxy group and a cyclohexyloxy group).

Preferably, any one of R_{1c} to R_{5c} is a linear, branched, or cyclic alkyl group, or a linear, branched, or cyclic alkoxy group. More preferably, the sum of carbon atoms of R_{1c} to R_{5c} is 2 to 15. Thus, the solubility in a solvent is improved, and generation of particles during storage is suppressed.

Examples of the alkyl group as each of Rx and Ry include the same ones as the alkyl group as each of R_{1c} to R_{7c}. The alkyl group as each of Rx and Ry is more preferably a linear or branched 2-oxoalkyl group, or an alkoxycarbonylmethyl group.

Examples of the cycloalkyl group as each of Rx and Ry include the same ones as the cycloalkyl group as each of R_{1c} to R_{7c}. The cycloalkyl group as each of Rx and Ry is more preferably a cyclic 2-oxoalkyl group.

Examples of the linear, branched, or cyclic 2-oxoalkyl group include the alkyl group as each of R_{1c} to R_{7c}, and a group having >C═O at the 2-position of a cycloalkyl group.

Examples of the alkoxy group of the alkoxycarbonylmethyl group are similar to those of the alkoxy group as each of R_{1c} to R_{5c}.

Rx and Ry are each preferably an alkyl group having 4 or more carbon atoms, more preferably an alkyl group having 6 or more carbon atoms, and still more preferably an alkyl group having 8 or more carbon atoms.

In General Formula (ZIIa),

R₂₀₄ to R₂₀₅ each independently represent an aryl group, an alkyl group, or a cycloalkyl group.

The aryl group as each of R₂₀₄ to R₂₀₅ is preferably a phenyl group or a naphthyl group, and more preferably a phenyl group.

The alkyl group as each of R₂₀₄ to R₂₀₅ is preferably linear or branched, and preferred examples thereof include a linear or branched alkyl group having 1 to 10 carbon atoms (for example, a methyl group, an ethyl group, a propyl group, a butyl group, and a pentyl group).

Preferred examples of the cycloalkyl group as each of R₂₀₄ to R₂₀₅ include a cycloalkyl group having 3 to 10 carbon atoms (a cyclopentyl group, a cyclohexyl group, and a norbornyl group).

Examples of the substituent which may be contained in each of R₂₀₄ to R₂₀₇ include an alkyl group (for example, an alkyl group having 1 to 15 carbon atoms), a cycloalkyl group (for example, a cycloalkyl group having 3 to 15 carbon atoms), an aryl group (for example, an aryl group having 6 to 15 carbon atoms), an alkoxy group (for example, an alkoxy group having 1 to 15 carbon atoms), a halogen atom, a hydroxyl group, and a phenylthio group.

The compound capable of generating an acid represented by General Formula (III) or (IV) upon irradiation with actinic rays or radiation is more preferably a sulfonium salt compound or iodonium salt compound having an anion of an acid represented by General Formula (III) or (IV), still more preferably a compound represented by General Formula (ZIa), and particularly preferably a compound represented by (ZI-1a) to (ZI-3a).

Among the components (A), particularly preferred examples thereof are set forth below, but the present invention is not limited thereto.

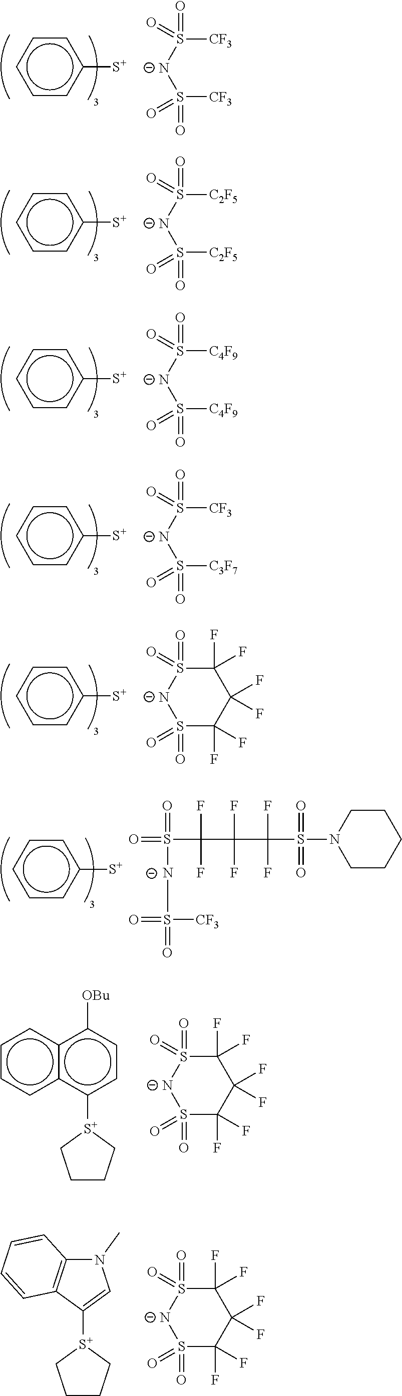

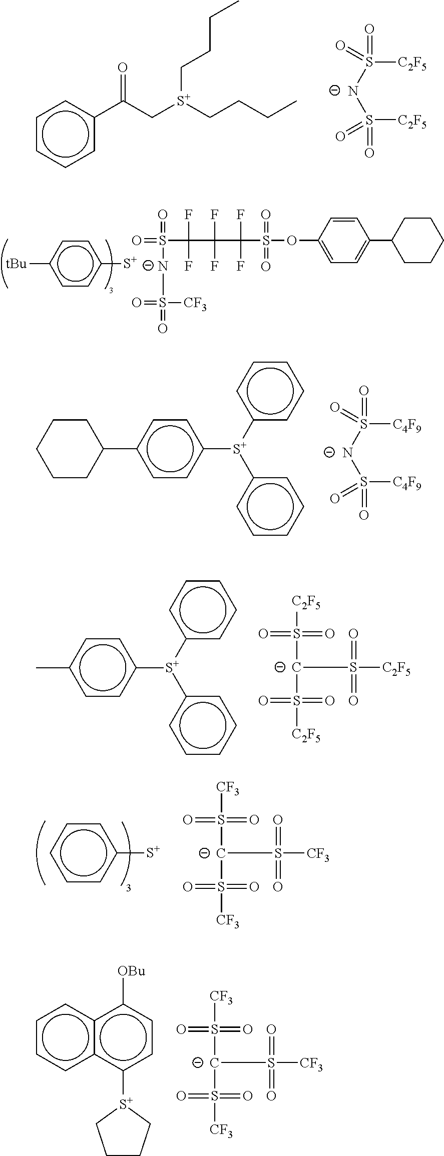

Among the acid generators, preferred examples thereof include the compounds exemplified in <0143> of US2012/0207978A1.

The acid generator can be synthesized by a known method, and can be synthesized in accordance with, for example, the method described in JP2007-161707A.

The acid generators may be used singly or in combination of two or more kinds thereof.

The content (the total content in a case where two or more kinds of the compound (B) are present) of the acid generator in the composition is preferably 0.1% to 30% by mass, more preferably 0.5% to 25% by mass, still more preferably 0.5% to 20% by mass, and particularly preferably 0.5% to 15% by mass, with respect to the total solid content of the composition.

Incidentally, in a case where the acid generator is represented by General Formula (ZI-3) or (ZI-4) (the total content in a case where the acid generators are present in plural numbers), the content thereof is preferably 0.1% to 35% by mass, more preferably 0.5% to 30% by mass, still more preferably 0.5% to 30% by mass, and particularly preferably 0.5% to 25% by mass, with respect to the total solid content of the composition.

Specific examples of the acid generator are set forth below, but the present invention is not limited thereto.

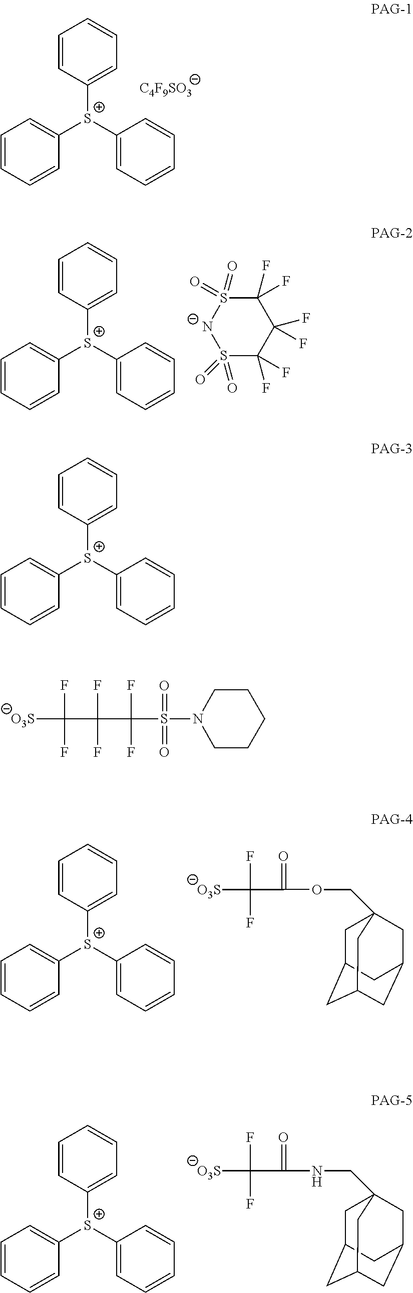

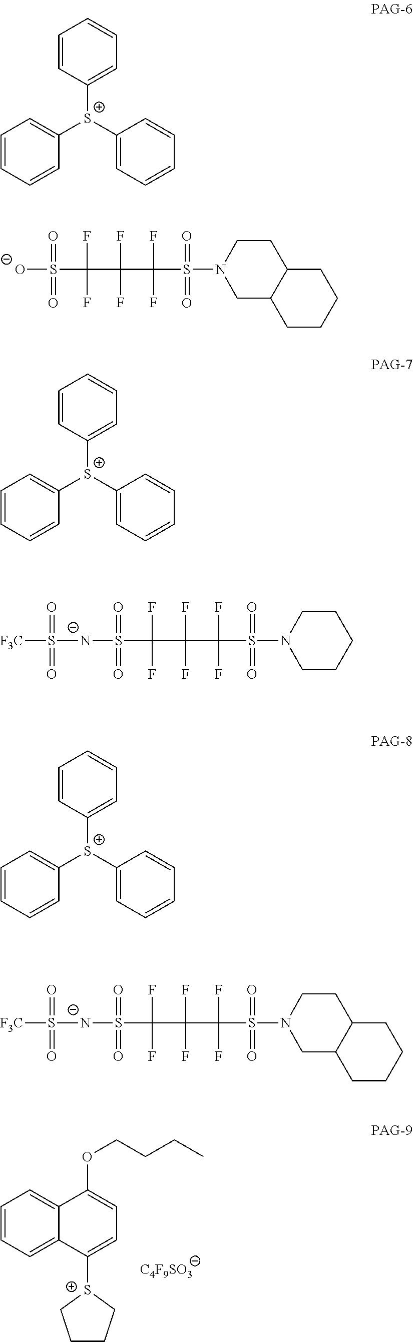

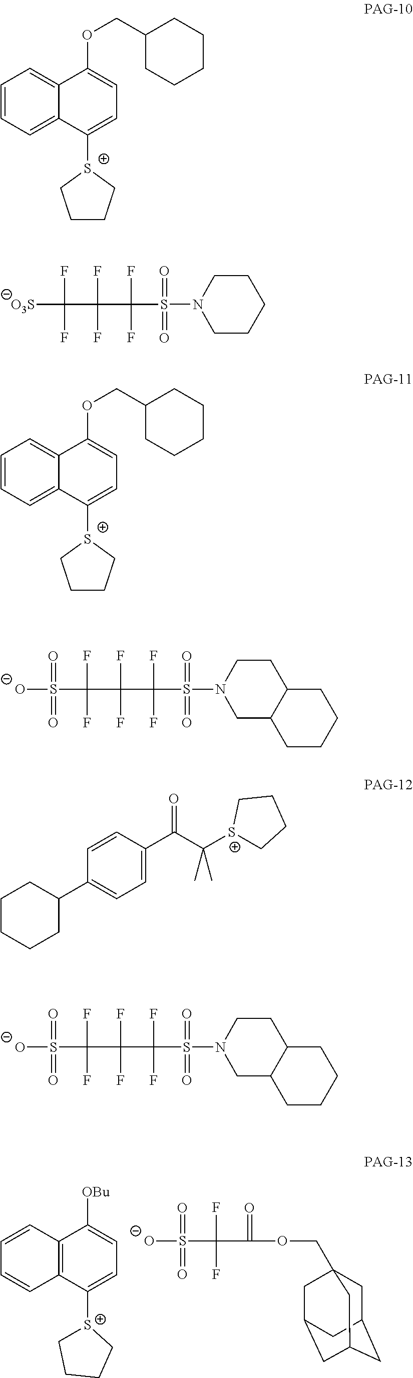

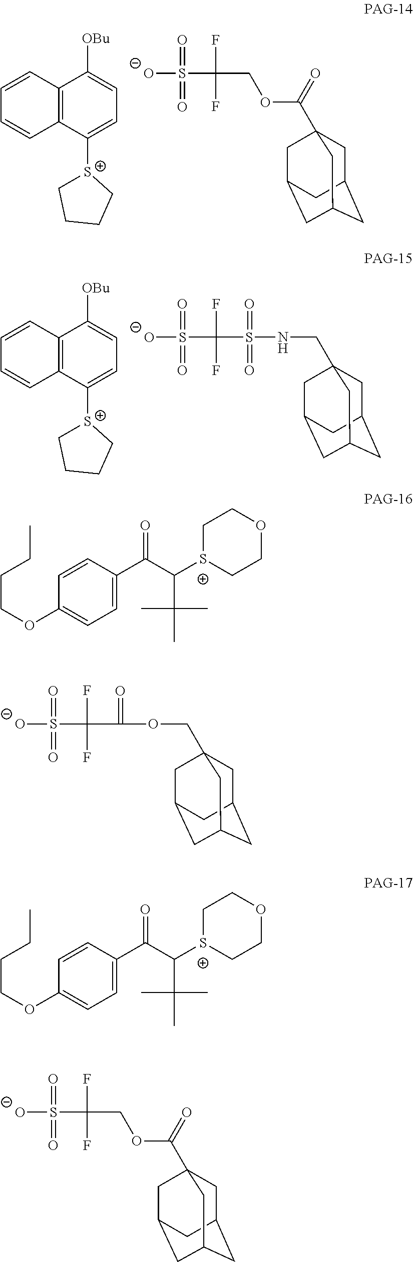

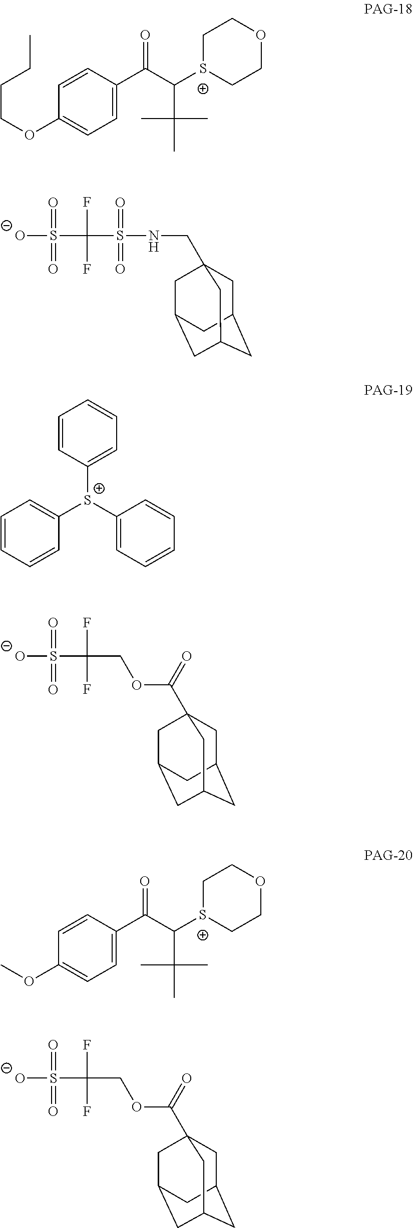 [SMILES: CCCCOc1ccc(C(=O)C([S+]2CCOCC2)C(C)(C)C)cc1 ; O=S(=O)([O-])C(F)(F)S(=O)(=O)NCC12CC3CC(CC(C3)C1)C2 ; c1ccc([S+](c2ccccc2)c2ccccc2)cc1 ; O=C(OCC(F)(F)S(=O)(=O)[O-])C12CC3CC(CC(C3)C1)C2 ; COc1ccc(C(=O)C([S+]2CCOCC2)C(C)(C)C)cc1 ; O=C(OCC(F)(F)S(=O)(=O)[O-])C12CC3CC(CC(C3)C1)C2]

<Hydrophobic Resin>

The composition of the present invention may contain a hydrophobic resin. Further, the hydrophobic resin is preferably different from the resin (A).

Although the hydrophobic resin is preferably designed to be unevenly distributed on an interface as described above, it does not necessarily have to have a hydrophilic group in its molecule as different from the surfactant, and does not need to contribute to uniform mixing of polar/nonpolar materials.

Examples of the effect of addition of the hydrophobic resin include control of the static/dynamic contact angle of the resist film surface with respect to water, improvement of the immersion liquid tracking properties, and suppression of out gas.

The hydrophobic resin preferably has at least one of a “fluorine atom”, a “silicon atom”, or a “CH₃ partial structure which is contained in a side chain moiety of a resin” from the viewpoint of uneven distribution on the film surface layer, and more preferably has two or more kinds.

In a case where hydrophobic resin includes a fluorine atom and/or a silicon atom, the fluorine atom and/or the silicon atom in the hydrophobic resin may be contained in the main chain or the side chain of the resin.

In a case where the hydrophobic resin includes a fluorine atom, it is preferably a resin having an alkyl group having a fluorine atom, a cycloalkyl group having a fluorine atom, or an aryl group having a fluorine atom, as a partial structure having a fluorine atom.

The alkyl group having a fluorine atom (preferably having 1 to 10 carbon atoms, and more preferably having 1 to 4 carbon atoms) is a linear or branched alkyl group in which at least one hydrogen atom is substituted with a fluorine atom, and may further have a substituent other than a fluorine atom.

The cycloalkyl group having a fluorine atom is a monocyclic or polycyclic cycloalkyl group in which at least one hydrogen atom is substituted with a fluorine atom, and may further have a substituent other than a fluorine atom.

The aryl group having a fluorine atom is an aryl group such as a phenyl group and a naphthyl group, in which at least one hydrogen atom is substituted with a fluorine atom, and may further have a substituent other than a fluorine atom.

Preferred examples of the alkyl group having a fluorine atom, the cycloalkyl group having a fluorine atom, and the aryl group having a fluorine atom include groups represented by General Formulae (F₂) to (F₄), but the present invention is not limited thereto.

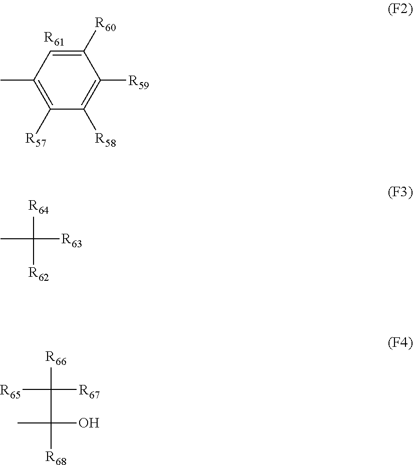

In General Formulae (F₂) to (F₄),

R₅₇ to R₆₈ each independently represent a hydrogen atom, a fluorine atom, or an (linear or branched) alkyl group, a provided that at least one of R₅₇, . . . , or R₆₁, at least one of R₆₂, . . . , or R₆₄, and at least one of R₆₅, . . . , or R₆₈ each independently represent a fluorine atom or an alkyl group (preferably having 1 to 4 carbon atoms) in which at least one hydrogen atom is substituted with a fluorine atom.

It is preferable that all of R₅₇ to R₆₁, and R₆₅ to R₆₇ are fluorine atoms. R₆₂, R₆₃, and R₆₈ are each preferably an alkyl group (preferably having 1 to 4 carbon atoms) in which at least one hydrogen atom is substituted with a fluorine atom, and more preferably a perfluoroalkyl group having 1 to 4 carbon atoms. R₆₂ and R₆₃ may be linked to each other to form a ring.

Specific examples of the group represented by General Formula (F₂) include a p-fluorophenyl group, a pentafluorophenyl group, and a 3,5-di(trifluoromethyl)phenyl group.

Specific examples of the group represented by General Formula (F₃) include those described in [0500] of US2012/0251948A1.

Specific examples of the group represented by General Formula (F₄) include —C(CF₃)₂OH, —C(C₂F₅)₂OH, —C(CF₃)(CH₃)OH, and —CH(CF₃)OH, with —C(CF₃)₂OH being preferable.

The partial structure including a fluorine atom may be directly bonded to a main chain, or bonded to a main chain via a group selected from the group consisting of an alkylene group, a phenylene group, an ether bond, a thioether bond, a carbonyl group, an ester bond, an amide bond, a urethane bond, and a ureylene bond, or a group formed by combining two or more of these groups.

The hydrophobic resin may contain a silicon atom. The hydrophobic resin is preferably a resin having an alkylsilyl structure (preferably a trialkylsilyl group) or a cyclic siloxane structure as the partial structure having a silicon atom.

Examples of the alkylsilyl structure or the cyclic siloxane structure include the partial structures described in paragraphs <0304> to <0307> of JP2013-178370A.

Examples of the repeating unit having a fluorine atom or a silicon atom include those exemplified in [0519] of US2012/0251948A1.

Moreover, it is also preferable that the hydrophobic resin includes a CH₃ partial structure in the side chain moiety as described above.

Here, the CH₃ partial structure contained in the side chain moiety in the hydrophobic resin includes a CH₃ partial structure contained in an ethyl group, a propyl group, and the like.

On the other hand, a methyl group bonded directly to the main chain of the hydrophobic resin (for example, an α-methyl group in the repeating unit having a methacrylic acid structure) makes only a small contribution of uneven distribution to the surface of the hydrophobic resin due to the effect of the main chain, and it is therefore not included in the CH₃ partial structure.

More specifically, in a case where the hydrophobic resin includes a repeating unit derived from a monomer having a polymerizable site with a carbon-carbon double bond, such as a repeating unit represented by General Formula (M), and in addition, R₁₁ to R₁₄ are each CH₃ “itself”, such the CH₃ is not included in the CH₃ partial structure contained in the side chain moiety in the present invention.

On the other hand, a CH₃ partial structure which is present via a certain atom from a C—C main chain corresponds to the CH₃ partial structure in the present invention. For example, in a case where R₁₁ is an ethyl group (CH₂CH₃), the hydrophobic resin has “one” CH₃ partial structure in the present invention.

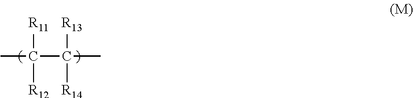

In General Formula (M),

R₁₁ to R₁₄ each independently represent a side chain moiety.

Examples of R₁₁ to R₁₄ at the side chain moiety include a hydrogen atom and a monovalent organic group.

Examples of the monovalent organic group for R₁₁ to R₁₄ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, and an arylaminocarbonyl group, and these groups may further have a substituent.

The hydrophobic resin is preferably a resin including a repeating unit having the CH₃ partial structure in the side chain moiety thereof. Further, the hydrophobic resin more preferably has, as such a repeating unit, at least one repeating unit (x) selected from a repeating unit represented by General Formula (II) or a repeating unit represented by General Formula (III).

Hereinafter, the repeating unit represented by General Formula (II) will be described in detail.

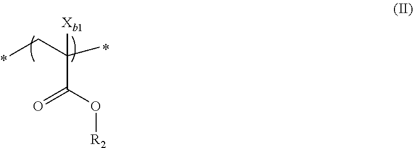

In General Formula (II), X_{b1} represents a hydrogen atom, an alkyl group, a cyano group, or a halogen atom, and R₂ represents an organic group which has one or more CH₃ partial structures and is stable against an acid. Here, more specifically, the organic group which is stable against an acid is preferably an organic group having no “acid-decomposable group” described for the resin (A).

The alkyl group of X_{b1} is preferably an alkyl group having 1 to 4 carbon atoms, and examples thereof include a methyl group, an ethyl group, a propyl group, a hydroxymethyl group, and a trifluoromethyl group, with the methyl group being preferable.

X_{b1} is preferably a hydrogen atom or a methyl group.

Examples of R₂ include an alkyl group, a cycloalkyl group, an alkenyl group, a cycloalkenyl group, an aryl group, and an aralkyl group, each of which has one or more CH₃ partial structures. Each of the cycloalkyl group, the alkenyl group, the cycloalkenyl group, the aryl group and the aralkyl group may further have an alkyl group as a substituent.

R₂ is preferably an alkyl group or an alkyl-substituted cycloalkyl group, each of which has one or more CH₃ partial structures.

The number of the CH₃ partial structures contained in the organic group which has one or more CH₃ partial structures and is stable against an acid as R₂ is preferably 2 to 10, and more preferably 2 to 8.

Specific preferred examples of the repeating unit represented by General Formula (II) are shown below, but the present invention is not limited thereto.

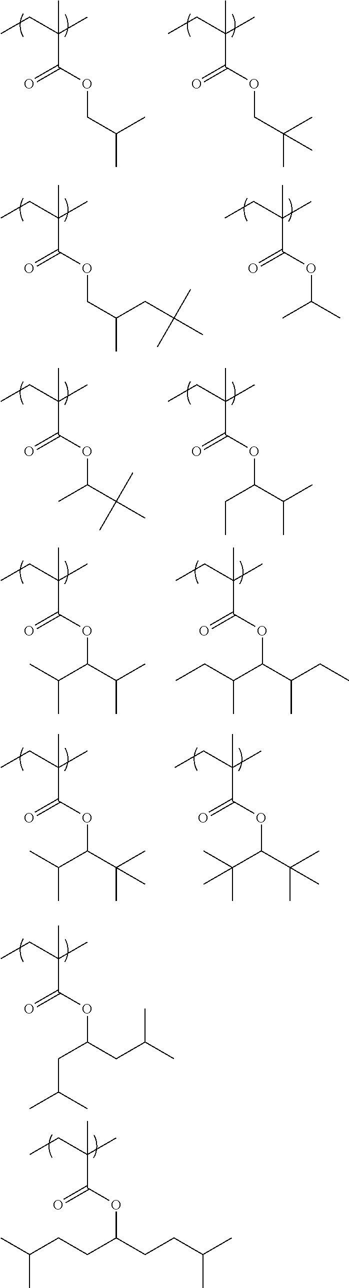

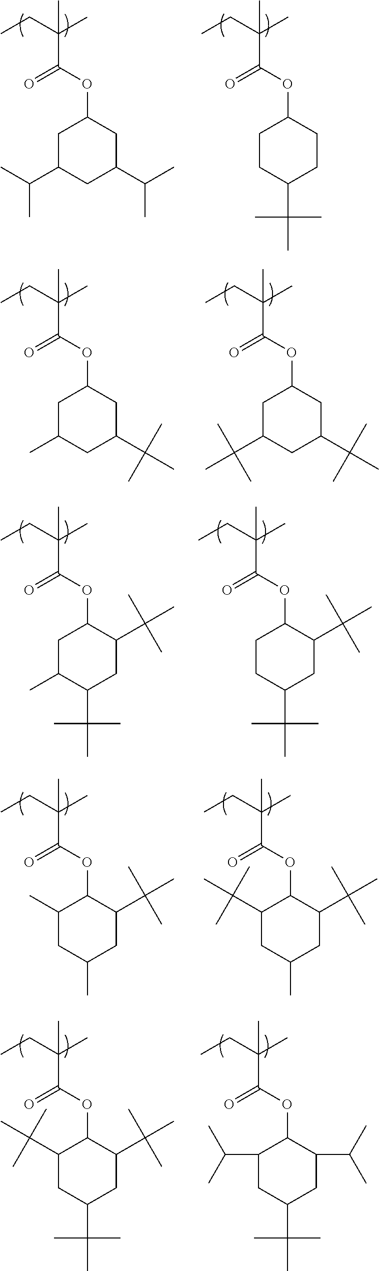

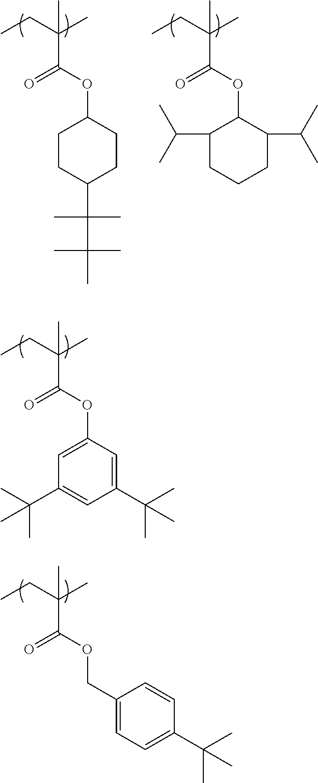

The repeating unit represented by General Formula (II) is preferably a repeating unit which is stable against an acid (acid-indecomposable), and specifically, it is preferably a repeating unit not having a group capable of decomposing by the action of an acid to generate a polar group.

Hereinafter, the repeating unit represented by General Formula (III) will be described in detail.

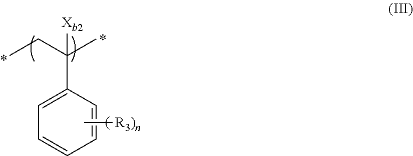

In General Formula (III), X_{b2} represents a hydrogen atom, an alkyl group, a cyano group, or a halogen atom, R₃ represents an organic group which has one or more CH₃ partial structures and is stable against an acid, and n represents an integer of 1 to 5.

The alkyl group of X_{b2} is preferably an alkyl group having 1 to 4 carbon atoms, and examples thereof include a methyl group, an ethyl group, a propyl group, a hydroxymethyl group, and a trifluoromethyl group, but a hydrogen atom is preferable.

X_{b2} is preferably a hydrogen atom.

Since R₃ is an organic group stable against an acid, more specifically, R₃ is preferably an organic group not having the “acid-decomposable group” described for the resin (A).

Examples of R₃ include an alkyl group having one or more CH₃ partial structures.

The number of the CH₃ partial structures contained in the organic group which has one or more CH₃ partial structures and is stable against an acid as R₃ is preferably 1 to 10, more preferably 1 to 8, and still more preferably 1 to 4.

n represents an integer of 1 to 5, more preferably 1 to 3, and still more preferably 1 or 2.

Specific preferred examples of the repeating unit represented by General Formula (III) are shown below, but the present invention is not limited thereto.

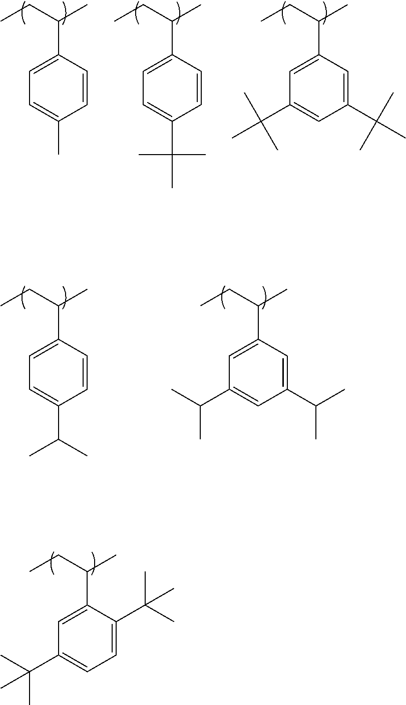

The repeating unit represented by General Formula (III) is preferably a repeating unit which is stable against an acid (acid-indecomposable), and specifically, the repeating unit is preferably a repeating unit having no group capable of decomposing by the action of an acid to generate a polar group.

In a case where the hydrophobic resin includes a CH₃ partial structure in the side chain moiety thereof, and in particular, it has neither a fluorine atom nor a silicon atom, the content of at least one repeating unit (x) of the repeating unit represented by General Formula (II) or the repeating unit represented by General Formula (III) is preferably 90% by mole or more, and more preferably 95% by mole or more, with respect to all the repeating units of the hydrophobic resin. Further, the content is usually 100% by mole or less with respect to all the repeating units of the hydrophobic resin.

By incorporating at least one repeating unit (x) of the repeating unit represented by General Formula (II) or the repeating unit represented by General Formula (III) in a proportion of 90% by mole or more with respect to all the repeating units of the hydrophobic resin into the hydrophobic resin, the surface free energy of the hydrophobic resin is increased. As a result, it is difficult for the hydrophobic resin to be unevenly distributed on the surface of the resist film and the static/dynamic contact angle of the resist film with respect to water can be securely increased, thereby enhancing the immersion liquid tracking properties.

In a case where the hydrophobic resin has a fluorine atom, the content of the fluorine atom is preferably 5% to 80% by mass, and more preferably 10% to 80% by mass, with respect to the weight-average molecular weight of the hydrophobic resin. Further, the content of the repeating unit including a fluorine atom is preferably 10% to 100% by mass, and more preferably 30% to 100% by mass, with respect to all the repeating units included in the hydrophobic resin.

In a case where the hydrophobic resin has a silicon atom, the content of the silicon atoms is preferably 2% to 50% by mass, and more preferably 2% to 30% by mass, with respect to the weight-average molecular weight of the hydrophobic resin. Further, the content of the repeating unit including a silicon atom is preferably 10% to 100% by mass, and more preferably 20% to 100% by mass, with respect to all the repeating units included in the hydrophobic resin.

On the other hand, in particular, in a case where the hydrophobic resin includes a CH₃ partial structure in the side chain moiety thereof, it is also preferable that the hydrophobic resin has a form substantially not having any one of fluorine atoms and silicon atoms. In this case, specifically, the content of the repeating unit having a fluorine atom or a silicon atom is preferably 5% by mole or less, more preferably 3% by mole or less, and still more preferably 1% by mole or less, with respect to all the repeating units in the hydrophobic resin, and ideally, the content is 0% by mole, that is, the hydrophobic resin does not contain a fluorine atom and a silicon atom. In addition, it is preferable that the hydrophobic resin is substantially composed only of repeating units which are composed only of atoms selected from a carbon atom, an oxygen atom, a hydrogen atom, a nitrogen atom, and a sulfur atom. More specifically, the proportion of the repeating units which are composed only of atoms selected from a carbon atom, an oxygen atom, a hydrogen atom, a nitrogen atom, and a sulfur atom is preferably 95% by mole or more, more preferably 97% by mole or more, still more preferably 99% by mole or more, and ideally 100% by mole, in all the repeating units in the hydrophobic resin.

The weight-average molecular weight of the hydrophobic resin in terms of standard polystyrene is preferably 1,000 to 100,000, more preferably 1,000 to 50,000, and still more preferably 2,000 to 15,000.

Furthermore, the hydrophobic resin may be used singly or in combination of a plurality of kinds thereof.

The content of the hydrophobic resin in the composition is preferably 0.01% to 10% by mass, more preferably 0.05% to 8% by mass, and still more preferably 0.1% to 7% by mass, with respect to the total solid contents of the composition of the present invention.

It is natural that the hydrophobic resin contains a small amount of impurities such as metals, but the amount of remaining monomers and oligomer components in the hydrophobic resin is preferably 0.01% to 5% by mass, more preferably 0.01% to 3% by mass, and still more preferably 0.05% to 1% by mass. Thus, a composition having no temporal change in foreign substances in a liquid, sensitivity, and the like is obtained. Further, the molecular weight distribution (Mw/Mn, which is also referred to as a dispersity) is preferably in a range of 1 to 5, more preferably in a range of 1 to 3, and still more preferably in a range of 1 to 2, in views of a resolution, a resist shape, side walls of a resist pattern, roughness, and the like.

As the hydrophobic resin, various commercial products can also be used, or the resin can be synthesized by an ordinary method (for example, radical polymerization). Examples of the general synthesis method include a bulk polymerization method in which polymerization is carried out by dissolving monomer species and an initiator in a solvent and heating the solution, a dropwise addition polymerization method in which a solution of monomer species and an initiator is added dropwise to a heating solvent for 1 to 10 hours, with the dropwise addition polymerization method being preferable.

A reaction solvent, a polymerization initiator, reaction conditions (a temperature, a concentration, and the like), and a purification method after the reaction are the same as those described for the resin (A), but in the synthesis of the hydrophobic resin, the concentration of the reactant is preferably 30% to 50% by mass.

<Acid Diffusion Control Agent (D)>

The composition of the present invention preferably contains an acid diffusion control agent (D). The acid diffusion control agent (D) acts as a quencher that inhibits a reaction of the acid-decomposable resin in the unexposed area by excessive generated acids by trapping the acids generated from an acid generator or the like upon exposure. As the acid diffusion control agent (D), a basic compound, a low-molecular-weight compound which has a nitrogen atom and a group capable of leaving by the action of an acid, a basic compound whose basicity is reduced or lost upon irradiation with actinic rays or radiation, or an onium salt which becomes a relatively weak acid relative to the acid generator can be used.

The content of the acid diffusion control agent is not particularly limited, but in a view that the effect of the present invention is superior, the content is preferably 0.01% by mass or more, and more preferably 0.2% by mass or more, with respect to the total solid content in the actinic ray-sensitive or radiation-sensitive resin composition. The upper limit is not particularly limited, but is 2.0% by mass or less in many cases.

Furthermore, the acid diffusion control agent may be used singly or in combination of two or more kinds thereof.

Preferred examples of the basic compound include compounds having structures represented by Formulae (A) to (E).

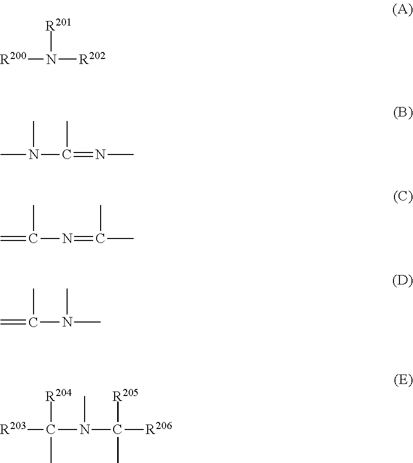

In General Formulae (A) and (E),

R₂₀₀, R₂₀₁, and R₂₀₂ may be the same as or different from each other, and each represent a hydrogen atom, an alkyl group (preferably having 1 to 20 carbon atoms), a cycloalkyl group (preferably having 3 to 20 carbon atoms), or an aryl group (having 6 to 20 carbon atoms), and R₂₀₁ and R₂₀₂ may be bonded to each other to form a ring.

R₂₀₃, R₂₀₄, R₂₀₅, and R₂₀₆ may be the same as or different from each other, and each represent an alkyl group having 1 to 20 carbon atoms.

With regard to the alkyl group, the alkyl group having a substituent is preferably an aminoalkyl group having 1 to 20 carbon atoms, a hydroxyalkyl group having 1 to 20 carbon atoms, or a cyanoalkyl group having 1 to 20 carbon atoms.

The alkyl groups in General Formulae (A) and (E) are more preferably unsubstituted.

Preferred examples of the compound include guanidine, aminopyrrolidine, pyrazole, pyrazoline, piperazine, aminomorpholine, aminoalkylmorpholine, and piperidine. More preferred examples of the compound include a compound having an imidazole structure, a diazabicyclo structure, an onium hydroxide structure, an onium carboxylate structure, a trialkylamine structure, an aniline structure, or a pyridine structure; an alkylamine derivative having a hydroxyl group and/or an ether bond; and an aniline derivative having a hydroxyl group and/or an ether bond.

Specific preferred examples of the compound include the compounds exemplified in paragraph <0379> in the specification of US2012/0219913A1.

Preferred examples of the basic compound include an amine compound having a phenoxy group, an ammonium salt compound having a phenoxy group, an amine compound containing a sulfonic ester group, and an ammonium salt compound having a sulfonic ester group.

As the amine compound, a primary, secondary, or tertiary amine compound can be used, and an amine compound in which at least one alkyl group is bonded to a nitrogen atom is preferable. The amine compound is more preferably a tertiary amine compound. Any amine compound is available as long as at least one alkyl group (preferably having 1 to 20 carbon atoms) is bonded to a nitrogen atom, and a cycloalkyl group (preferably having 3 to 20 carbon atoms) or an aryl group (preferably having 6 to 12 carbon atoms) may be bonded to the nitrogen atom, in addition to the alkyl group. The amine compound preferably has an oxygen atom in the alkyl chain to form an oxyalkylene group. The number of the oxyalkylene groups within the molecule is 1 or more, preferably 3 to 9, and more preferably from 4 to 6. Among the oxyalkylene groups, an oxyethylene group (—CH₂CH₂O—) or an oxypropylene group (—CH(CH₃)CH₂O— or —CH₂CH₂CH₂O—) is preferable, and an oxyethylene group is more preferable.

As the ammonium salt compound, a primary, secondary, tertiary, or quaternary ammonium salt compound can be used, and an ammonium salt compound in which at least one alkyl group is bonded to a nitrogen atom is preferable. Any ammonium salt compound is available as long as at least one alkyl group (preferably having 1 to 20 carbon atoms) is bonded to a nitrogen atom, and a cycloalkyl group (preferably having 3 to 20 carbon atoms) or an aryl group (preferably having 6 to 12 carbon atoms) may be bonded to the nitrogen atom, in addition to the alkyl group. The ammonium salt compound preferably has an oxygen atom in the alkyl chain to form an oxyalkylene group. The number of the oxyalkylene groups within the molecule is 1 or more, preferably 3 to 9, and more preferably 4 to 6. Among the oxyalkylene groups, an oxyethylene group (—CH₂CH₂O—) or an oxypropylene group (—CH(CH₃)CH₂O— or —CH₂CH₂CH₂O—) is preferable, and an oxyethylene group is more preferable.

Examples of the anion of the ammonium salt compound include a halogen atom, sulfonate, borate, and phosphate, and among these, the halogen atom and sulfonate are preferable.

Furthermore, the following compounds are also preferable as the basic compound.

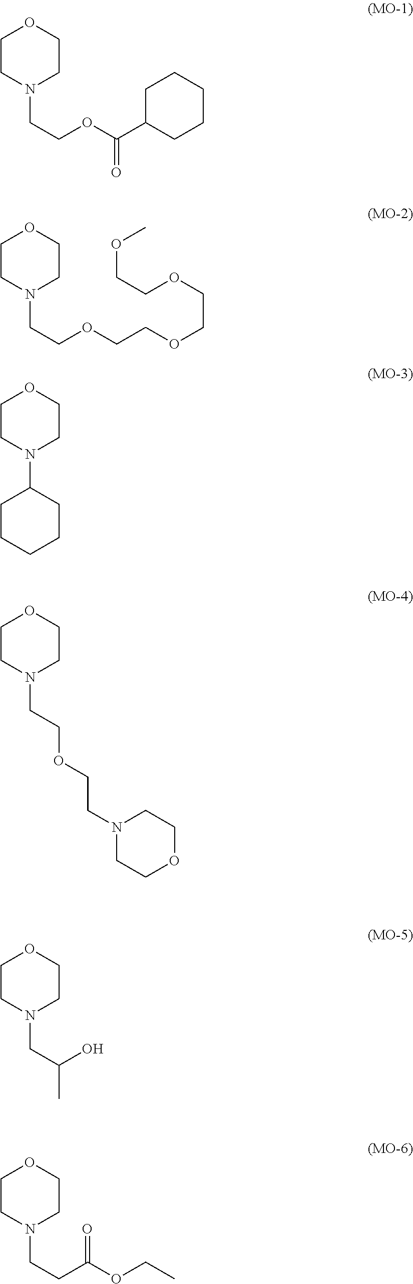

In addition to the compounds as described above, as the basic compound, the compounds described in [0180] to [0225] of JP2011-22560A, [0218] to [0219] of JP2012-137735A, and [0416] to [0438] of WO2011/158687A1, and the like can also be used.

These basic compounds may be used singly or in combination of two or more kinds thereof.

The ratio between the acid generator (a total amount in a case where a plurality of the acid generators are used) and the basic compound to be used in the composition is preferably acid generator/basic compound (molar ratio)=2.5 to 300. That is, the molar ratio is preferably 2.5 or more in a view of sensitivity and resolution, and is preferably 300 or less in a view of suppressing the reduction in resolution due to thickening of the resist pattern with aging after exposure until the heating treatment. The acid generator/basic compound (molar ratio) is more preferably 5.0 to 200, and still more preferably 7.0 to 150.

The low-molecular-weight compound (hereinafter referred to as a “compound (D-1)”) which has a nitrogen atom and a group capable of leaving by the action of an acid is preferably an amine derivative having a group capable of leaving by the action of an acid on a nitrogen atom.

As the group capable of leaving by the action of an acid, an acetal group, a carbonate group, a carbamate group, a tertiary ester group, a tertiary hydroxyl group, or a hemiaminal ether group are preferable, and a carbamate group or a hemiaminal ether group is more preferable.

The molecular weight of the compound (D-1) is preferably 100 to 1,000, more preferably 100 to 700, and still more preferably 100 to 500.

The compound (D-1) may have a carbamate group having a protecting group on a nitrogen atom. The protecting group constituting the carbamate group can be represented by General Formula (d-1).

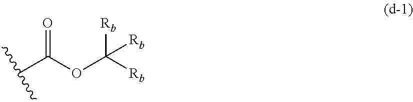

In General Formula (d-1),

R_{b}'s each independently represent a hydrogen atom, an alkyl group (preferably having 1 to 10 carbon atoms), a cycloalkyl group (preferably having 3 to 30 carbon atoms), an aryl group (preferably having 3 to 30 carbon atoms), an aralkyl group (preferably having 1 to 10 carbon atoms), or an alkoxyalkyl group (preferably having 1 to 10 carbon atoms). R_{b}'s may be linked to each other to form a ring.

The alkyl group, the cycloalkyl group, the aryl group, or the aralkyl group represented by R_{b} may be substituted with a hydroxyl group, a cyano group, an amino group, a pyrrolidino group, a piperidino group, a morpholino group, an oxo group, an alkoxy group, or a halogen atom. This shall apply to the alkoxyalkyl group represented by R_{b}.

R_{b} is preferably a linear or branched alkyl group, a cycloalkyl group, or an aryl group, and more preferably a linear or branched alkyl group, or a cycloalkyl group.

Examples of the ring formed by the mutual linking of two R_{b}'s include an alicyclic hydrocarbon group, an aromatic hydrocarbon group, a heterocyclic hydrocarbon group, and derivatives thereof.

Examples of the specific structure of the group represented by General Formula (d-1) include, but are not limited to, the structures disclosed in paragraph <0466> in US2012/0135348A1.

It is particularly preferable that the compound (D-1) has a structure represented by General Formula (6).

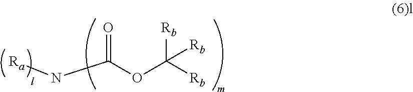

In General Formula (6), Rₐ represents a hydrogen atom, an alkyl group, a cycloalkyl group, an aryl group, or an aralkyl group. In a case where 1 is 2, two Rₐ's may be the same as or different from each other. Two Rₐ's may be linked to each other to form a heterocycle may be bonded to each other to form, together with a carbon atom to which they are bonded with the nitrogen atom in the formula. The heterocycle may contain a heteroatom other than the nitrogen atom in the formula.

R_{b} has the same definition as R_{b} in General Formula (d-1), and preferred examples are also the same.

l represents an integer of 0 to 2, and m represents an integer of 1 to 3, satisfying l+m=3.

In General Formula (6), the alkyl group, the cycloalkyl group, the aryl group, and the aralkyl group as Rₐ may be substituted with the same groups as the group mentioned above as a group which may be substituted in the alkyl group, the cycloalkyl group, the aryl group, and the aralkyl group as R_{b}.

Specific examples of the alkyl group, the cycloalkyl group, the aryl group, and the aralkyl group (such the alkyl group, a cycloalkyl group, an aryl group, and aralkyl group may be substituted with the groups as described above) of Rₐ include the same groups as the specific of examples as described above with respect to R_{b}.

Specific examples of the particularly preferred compound (D-1) in the present invention include, but are not limited to, the compounds disclosed in paragraph <0475> in the specification of US2012/0135348A1.

The compounds represented by General Formula (6) can be synthesized in accordance with JP2007-298569A, JP2009-199021A, and the like.

In the present invention, the compound (D-1) may be used singly or as a mixture of two or more kinds thereof.

The basic compound whose basicity is reduced or lost upon irradiation with actinic rays or radiation (hereinafter also referred to as a “compound (PA)”) is a compound which has a functional group with proton acceptor properties, and decomposes under irradiation with actinic rays or radiation to exhibit deterioration in proton acceptor properties, no proton acceptor properties, or a change from the proton acceptor properties to acid properties.

The functional group with proton acceptor properties refers to a functional group having a group or an electron which is capable of electrostatically interacting with a proton, and for example, means a functional group with a macrocyclic structure, such as a cyclic polyether, or a functional group containing a nitrogen atom having an unshared electron pair not contributing to π-conjugation. The nitrogen atom having an unshared electron pair not contributing to π-conjugation is, for example, a nitrogen atom having a partial structure represented by the following formula.

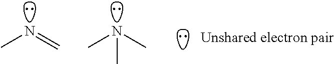

Preferred examples of the partial structure of the functional group with proton acceptor properties include crown ether, azacrown ether, primary to tertiary amines, pyridine, imidazole, and pyrazine structures.

The compound (PA) decomposes upon irradiation with actinic rays or radiation to generate a compound exhibiting deterioration in proton acceptor properties, no proton acceptor properties, or a change from the proton acceptor properties to acid properties. Here, exhibiting deterioration in proton acceptor properties, no proton acceptor properties, or a change from the proton acceptor properties to acid properties means a change of proton acceptor properties due to the proton being added to the functional group with proton acceptor properties, and specifically a decrease in the equilibrium constant at chemical equilibrium in a case where a proton adduct is generated from the compound (PA) having the functional group with proton acceptor properties and the proton.

The proton acceptor properties can be confirmed by carrying out pH measurement.

In the present invention, the acid dissociation constant pKa of the compound generated by the decomposition of the compound (PA) upon irradiation with actinic rays or radiation preferably satisfies pKa <−1, more preferably −13<pKa <−1, and still more preferably −13<pKa <−3.

In the present invention, the acid dissociation constant pKa indicates an acid dissociation constant pKa in an aqueous solution, and is described, for example, in Chemical Handbook (II) (Revised 4^{th} Edition, 1993, compiled by the Chemical Society of Japan, Maruzen Company, Ltd.), and a lower value thereof indicates higher acid strength. Specifically, the acid dissociation constant pKa in an aqueous solution may be measured by using an infinite-dilution aqueous solution and measuring the acid dissociation constant at 25° C., or a value based on the Hammett substituent constants and the database of publicly known literature data can also be obtained by computation using the following software package 1. All the values of pKa described in the present specification indicate values determined by computation using this software package.

Software package 1: Advanced Chemistry Development (ACD/Labs) Software V 8.14 for Solaris (1994-2007 ACD/Labs).

The compound (PA) generates a compound represented by General Formula (PA-1), for example, as the proton adduct generated by decomposition upon irradiation with actinic rays or radiation. The compound represented by General Formula (PA-1) is a compound exhibiting deterioration in proton acceptor properties, no proton acceptor properties, or a change from the proton acceptor properties to acid properties since the compound has a functional group with proton acceptor properties as well as an acidic group, as compared with the compound (PA).

Q-A-(X)ₙ—B—R (PA-1)

In General Formula (PA-1),

Q represents —SO₃H, —CO₂H, or —W₁NHW₂R_{f}, in which R_{f} represents an alkyl group (preferably having 1 to 20 carbon atoms), a cycloalkyl group (preferably having 3 to 20 carbon atoms), or an aryl group (preferably having 6 to 30 carbon atoms), and W₁ and W₂ each independently represent —SO₂— or —CO—.

A represents a single bond or a divalent linking group.

X represents —SO₂— or —CO—.

n is 0 or 1.

B represents a single bond, an oxygen atom, or —N(Rx) Ry-, in which Rx represents a hydrogen atom or a monovalent organic group, and Ry represents a single bond or a divalent organic group, a provided that Rx may be bonded to Ry to form a ring or may be bonded to R to form a ring.

R represents a monovalent organic group having a functional group with proton acceptor properties.

General Formula (PA-1) will be described in more detail.

The divalent linking group in A is preferably a divalent linking group having 2 to 12 carbon atoms, and examples thereof include an alkylene group and a phenylene group. The divalent linking group is more preferably an alkylene group having at least one fluorine atom, and preferably has 2 to 6 carbon atoms, and more preferably has 2 to 4 carbon atoms. The divalent linking group may have a linking group such as an oxygen atom and a sulfur atom in the alkylene chain. The alkylene group preferably an alkylene group, in particular, in which 30% to 100% by number of the hydrogen atoms are substituted with fluorine atoms, more preferably in which a carbon atom bonded to the Q site has a fluorine atom, still more preferably a perfluoroalkylene group, and particularly preferably a perfluoroethylene group, a perfluoropropylene group, or a perfluorobutylene group.

The monovalent organic group in Rx is preferably an organic group having 1 to 30 carbon atoms, and examples thereof include an alkyl group, a cycloalkyl group, an aryl group, an aralkyl group, and an alkenyl group. These groups may further have a substituent.

The alkyl group in Rx may have a substituent, is preferably a linear or branched alkyl group having 1 to 20 carbon atoms, and may have an oxygen atom, a sulfur atom, or a nitrogen atom in the alkyl chain.

The cycloalkyl group in Rx may have a substituent, is preferably a monocyclic or polycyclic cycloalkyl group having 3 to 20 carbon atoms, and may have an oxygen atom, a sulfur atom, or a nitrogen atom in the ring.

The aryl group in Rx may have a substituent, is preferably an aryl group having 6 to 14 carbon atoms, and examples thereof include a phenyl group and a naphthyl group.

The aralkyl group in Rx may have a substituent, is preferably an aralkyl group having 7 to 20 carbon atoms, and examples thereof include a benzyl group and a phenethyl group.

The alkenyl group in Rx may have a substituent, may be linear or branched, is preferably an alkenyl group having 3 to 20 carbon atoms, and examples thereof include a vinyl group, an allyl group, and a styryl group.

In a case where Rx further has a substituent, examples of the substituent include a halogen atom, a linear, branched, or cyclic alkyl group, an alkenyl group, an alkynyl group, an aryl group, an acyl group, an alkoxycarbonyl group, an aryloxycarbonyl group, a carbamoyl group, a cyano group, a carboxyl group, a hydroxyl group, an alkoxy group, an aryloxy group, an alkylthio group, an arylthio group, a heterocyclic oxy group, an acyloxy group, an amino group, a nitro group, a hydrazino group, and a heterocyclic group.

Preferred examples of the divalent organic group in Ry include an alkylene group.

Examples of the ring structure which may be formed by the mutual bonding of Rx and Ry include a 5- to 10-membered ring, and particularly preferably a 6-membered ring, including a nitrogen atom.

The functional group with proton acceptor properties in R is as described above, and examples thereof include nitrogen-including heterocyclic aromatic structures such as azacrown ether, primary to tertiary amines, pyridine, and imidazole.

The organic group having such a structure is preferably an organic group having 4 to 30 carbon atoms, and examples thereof include an alkyl group, a cycloalkyl group, an aryl group, an aralkyl group, and an alkenyl group.

The alkyl group, the cycloalkyl group, the aryl group, the aralkyl group, or the alkenyl group in the alkyl group, the cycloalkyl group, the aryl group, the aralkyl group, or the alkenyl group, each including a functional group with proton acceptor properties or an ammonium group in R, are the same as the alkyl group, the cycloalkyl group, the aryl group, the aralkyl group, or the alkenyl group, mentioned as Rx, respectively.

In a case where B is —N(Rx)Ry-, it is preferable that R and Rx are bonded to each other to form a ring. By forming a ring structure, the stability is improved and the storage stability of the composition using the ring is improved. The number of carbon atoms which form a ring is preferably 4 to 20, the ring may be monocyclic or polycyclic, and an oxygen atom, and a sulfur atom, or a nitrogen atom may be included in the ring.

Examples of the monocyclic structure include 4-, 5-, 6-, 7-, and 8-membered rings, each including a nitrogen atom. Examples of the polycyclic structure include structures formed by a combination of two, or three or more monocyclic structures.

R_{f} in —W₁NHW₂R_{f} represented by Q is preferably an alkyl group having 1 to 6 carbon atoms, which may have a fluorine atom, and more preferably a perfluoroalkyl group having 1 to 6 carbon atoms. Further, it is preferable that at least one of W₁ or W₂ is —SO₂—, and it is more preferable that both of W₁ and W₂ are —SO₂—.

Q is particularly preferably —SO₃H or —CO₂H from the viewpoint of hydrophilicity of acid group.

Among the compounds represented by General Formula (PA-1), the compound in which the Q site is sulfonic acid, can be synthesized by common sulfonamidation reaction. For example, the compound can be obtained by a method of selectively reacting one sulfonyl halide moiety of a bissulfonyl halide compound with an amine compound to form a sulfonamide bond, followed by hydrolysis of another sulfonyl halide moiety thereof, or a method of reacting a cyclic sulfonic acid anhydride with an amine compound to cause ring-opening.

The compound (PA) is preferably an ionic compound. The functional group with proton acceptor properties may be included in an anionic moiety or a cationic moiety, and it is preferable that the functional group is included in an anionic moiety.

Preferred examples of the compound (PA) include compounds represented by General Formulae (4) to (6).

R_{f}—W₂—N⁻—W₁-A-(X)ₙ—B—R[C]⁺ (4)

R—SO₃⁻[C]⁺ (5)

R—CO₂⁻[C]+ (6)

In General Formulae (4) to (6), A, X, n, B, R, R_{f}, W₁, and W₂ each have the same definitions as those, respectively, in General Formula (PA-1).

C⁺ represents a counter cation.

The counter cation is preferably an onium cation. More specifically, with regard to the acid generator, preferred examples thereof include the sulfonium cations described as S⁺(R₂₀₁)(R₂₀₂)(R₂₀₃) in General Formula (ZI) and the iodonium cations described as I⁺(R₂₀₄)(R₂₀₅) in General Formula (ZII).

Specific examples of the compound (PA) include the compounds exemplified in <0280> of US2011/0269072A1.

Furthermore, in the present invention, compounds (PA) other than a compound which generates the compound represented by General Formula (PA-1) can also be appropriately selected. For example, a compound containing a proton acceptor site at its cationic moiety may be used as an ionic compound. More specifically, examples of the compound include a compound represented by General Formula (7).

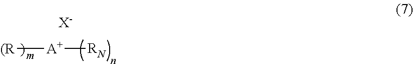

In the formula, A represents a sulfur atom or an iodine atom.

m represents 1 or 2 and n represents 1 or 2, provided that m+n=3 in a case where A is a sulfur atom and that m+n=2 in a case where A is an iodine atom.

R represents an aryl group.

R_{N} represents an aryl group substituted with the functional group with proton acceptor properties, and X⁻ represents a counter anion.

Specific examples of X⁻ include the same anions as those of the acid generators as described above.

Specific preferred examples of the aryl group of R and R_{N} include a phenyl group.

Specific examples of the functional group with proton acceptor properties contained in R_{N} are the same as those of the functional group with proton acceptor properties as described above in Formula (PA-1).

Specific examples of the ionic compounds having a proton acceptor site at a cationic moiety include the compounds exemplified in <0291> of US2011/0269072A1.

Furthermore, such compounds can be synthesized, for example, with reference to the methods described in JP2007-230913A, JP2009-122623A, and the like.

The compound (PA) may be used singly or in combination of two or more kinds thereof.

In the composition of the present invention, an onium salt which becomes a relatively weak acid with respect to the acid generator can be used as an acid diffusion control agent (D).

In a case of mixing the acid generator and the onium salt that generates an acid which is a relatively weak acid (preferably a weak acid having a pKa of more than −1) with respect to an acid generated from the acid generator, and then using the mixture, in a case where the acid generated from the acid generator upon irradiation with actinic rays or radiation collides with an onium salt having an unreacted weak acid anion, a weak acid is discharged by salt exchange, thereby generating an onium salt having a strong acid anion. In this process, the strong acid is exchanged with a weak acid having a lower catalytic ability, and therefore, the acid is deactivated in appearance, and thus, it is possible to carry out the control of acid diffusion.

As the onium salt which becomes a relatively weak acid with respect to the acid generator, compounds represented by General Formulae (d1-1) to (d1-3) are preferable.

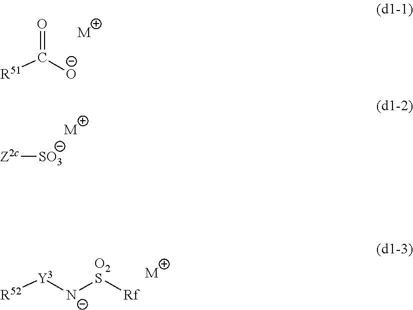

In the formulae, R⁵¹ is a hydrocarbon group which may have a substituent, Z^{2c} is a hydrocarbon group (provided that carbon adjacent to S is not substituted with a fluorine atom) having 1 to 30 carbon atoms, which may have a substituent, R⁵² is an organic group, Y³ is a linear, branched, or cyclic alkylene group or arylene group, R_{f} is a hydrocarbon group including a fluorine atom, and M⁺'s are each independently a sulfonium or iodonium cation.

Preferred examples of the sulfonium cation or the iodonium cation represented by M⁺ include the sulfonium cations exemplified for General Formula (ZI) and the iodonium cations exemplified for General Formula (ZII).

Preferred examples of the anionic moiety of the compound represented by General Formula (d1-1) include the structures exemplified in paragraph [0198] of JP2012-242799A.

Preferred examples of the anionic moiety of the compound represented by General Formula (d1-2) include the structures exemplified in paragraph [0201] of JP2012-242799A.

Preferred examples of the anionic moiety of the compound represented by General Formula (d1-3) include the structures exemplified in paragraphs [0209] and [0210] of JP2012-242799A.

The onium salt which becomes a relatively weak acid with respect to the acid generator may be a compound (hereinafter also referred to as a “compound (D-2)”) having a cationic moiety and an anionic moiety in the same molecule, in which the cationic moiety and the anionic moiety are linked to each other through a covalent bond.

As the compound (D-2), a compound represented by any one of General Formulae (C-1) to (C-3) is preferable.

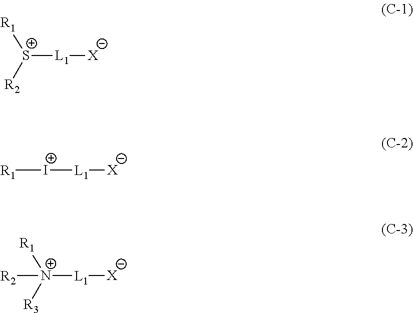

In General Formulae (C-1) to (C-3),

R₁, R₂, and R₃ represent a substituent having 1 or more carbon atoms.

L₁ represents a divalent linking group that links a cationic moiety with an anionic moiety, or a single bond.

—X⁻ represents an anionic moiety selected from —COO⁻, —SO₃⁻, —SO₂⁻, and —N⁻—R₄. R₄ represents a monovalent substituent having a carbonyl group: —C(═O)—, a sulfonyl group: —S(═O)₂—, or a sulfinyl group: —S(═O)— at a site for linking to an adjacent N atom.

R₁, R₂, R₃, R₄, and L₁ may be bonded to one another to form a ring structure. Further, in (C-3), two of R₁ to R₃ may be combined to form a double bond with an N atom.

Examples of the substituent having 1 or more carbon atoms in R₁ to R₃ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, and an arylaminocarbonyl group, and preferably an alkyl group, a cycloalkyl group, and an aryl group.

Examples of L₁ as a divalent linking group include a linear or branched alkylene group, a cycloalkylene group, an arylene group, a carbonyl group, an ether bond, ester bond, amide bond, a urethane bond, a urea bond, and a group formed by a combination of two or more kinds of these groups. L₁ is more preferably alkylene group, an arylene group, an ether bond, ester bond, and a group formed by a combination of two or more kinds of these groups.

Preferred examples of the compound represented by General Formula (C-1) include the compounds exemplified in paragraphs [0037] to [0039] of JP2013-6827A and paragraphs [0027] to [0029] of JP2013-8020A.

Preferred examples of the compound represented by General Formula (C-2) include the compounds exemplified in paragraphs [0012] to [0013] of JP2012-189977A.

Preferred examples of the compound represented by General Formula (C-3) include the compounds exemplified in paragraphs [0029] to [0031] of JP2012-252124A.

<Solvent>

The composition of the present invention usually contains a solvent.

Examples of the solvent which can be used in the preparation of the composition include organic solvents such as alkylene glycol monoalkyl ether carboxylate, alkylene glycol monoalkyl ether, alkyl lactate ester, alkyl alkoxypropionate, a cyclic lactone (preferably having 4 to 10 carbon atoms), a monoketone compound (preferably having 4 to 10 carbon atoms) which may have a ring, alkylene carbonate, alkyl alkoxyacetate, and alkyl pyruvate.

Specific examples of these solvents include those described in [0441] to <0455> of US2008/0187860A, isoamyl acetate, butyl butanoate, and methyl 2-hydroxyisobutyrate.

In the present invention, a mixed solvent obtained by mixing a solvent containing a hydroxyl group and a solvent containing no hydroxyl group in the structure may be used as the organic solvent.

As the solvent containing a hydroxyl group and the solvent containing no hydroxyl group, the aforementioned exemplary compounds can be appropriately selected and used, but as the solvent containing a hydroxyl group, an alkylene glycol monoalkyl ether, alkyl lactate, and the like are preferable, and propylene glycol monomethyl ether (PGME, alternative name: 1-methoxy-2-propanol) and ethyl lactate are more preferable. Further, as the solvent containing no hydroxyl group, an alkylene glycol monoalkyl ether acetate, alkyl alkoxy propionate, a monoketone compound which may contain a ring, cyclic lactone, alkyl acetate, and the like are preferable. Among these, propylene glycol monomethyl ether acetate (PGMEA, alternative name: 1-methoxy-2-acetoxypropane), ethyl ethoxypropionate, 2-heptanone, γ-butyrolactone, cyclohexanone, and butyl acetate are more preferable, and propylene glycol monomethyl ether acetate, ethyl ethoxypropionate, and 2-heptanone are still more preferable.

The mixing ratio (mass) of the solvent containing a hydroxyl group and the solvent containing no hydroxyl group is 1/99 to 99/1, preferably 10/90 to 90/10, and more preferably 20/80 to 60/40. A mixed solvent whose proportion of the solvent containing no hydroxyl group is 50% by mass or more is particularly preferable from the viewpoint of coating evenness.

The solvent preferably includes propylene glycol monomethyl ether acetate, and is preferably a solvent composed of propylene glycol monomethyl ether acetate singly or a mixed solvent of two or more kinds of solvents including propylene glycol monomethyl ether acetate.

<Light Absorbent>

The compositions of the present invention may contain a light absorbent. By incorporating the light absorbent into the composition, the light transmittance of the resist film is reduced, and thus, the decomposition of the acid generator becomes difficult. As a result, even in a case where the exposure dose is more or less deviated from a prescribed value, the sensitivity of the resist film is not greatly changed, and a deviation in the thickness hardly occurs. Incidentally, the light absorbent is a compound different from the resin (A) and the acid generator (B), each mentioned above.

The type of the light absorbent to be used is not particularly limited, and a known light absorbent is used. Further, the light absorbent may be used singly or in combination of two or more kinds thereof.

Among those, a compound X (light absorbent) having a molar light absorption coefficient ε at a wavelength of 243 nm of more than 200 L·mol⁻¹·cm⁻¹ is preferable, in a view that the effect of the present invention is superior. The compound may be either a high-molecular-weight compound (resin) or a low-molecular-weight compound. Further, the high-molecular-weight compound is intended to mean a compound having a molecular weight of more than 2,000 compounds, and the low-molecular-weight compound is intended to mean a compound having a molecular weight of 2,000 or less.

That is, examples of the compound X include a resin having a molar light absorption coefficient ε at a wavelength of 243 nm of more than 200 L·mol⁻¹·cm⁻¹, and a compound having a molar light absorption coefficient ε at a wavelength of 243 nm of more than 200 L·mol⁻¹·cm⁻¹ and having a molecular weight of 2,000 or less. Furthermore, in a case where the high-molecular-weight compound is a resin having a predetermined repeating unit and has a molecular weight distribution, the molecular weight is replaced with a weight-average molecular weight.

The molar light absorption coefficient ε of the compound X is more than 200 L·mol⁻¹·cm⁻¹, and in a view that the effect of the present invention is superior, the molar light absorption coefficient ε is preferably 5,000 L·mol⁻¹·cm⁻¹ or more, and more preferably 10,000 L·mol⁻¹·cm⁻¹ or more. The upper limit is not particularly limited, but is preferably 150,000 L·mol⁻¹·cm⁻¹ or less, and more preferably 100,000 L·mol⁻¹·cm⁻¹ or less.

As for a method for measuring the molar light absorption coefficient ε, 0.1 g of a compound X is weighed, and completely dissolved in 1,000 mL of acetonitrile, the absorbance of the solution is measured by a spectrophotometer (UV-2500PC, manufactured by Shimadzu Corp.), and a molar light absorption coefficient ε is calculated by the following equation. Further, the optical path length of a cell used in this measurement is 1 cm.

A=ε·C·l Equation:

(A: absorbance, C: concentration (mol/L), l: optical path length (cm))

Furthermore, in a view that the effect of the present invention is superior, one of suitable aspects of the light absorbent may include a compound represented by General Formula (I) (hereinafter also referred to as a “compound (A)”).

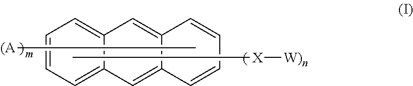

In General Formula (I),

A represents a monovalent substituent.

X represents a single bond or a divalent linking group.

W represents a group having a lactone ring, or a group represented by any one of Formulae (V1) to (V4).

m represents an integer of 0 or more.

n represents an integer of 1 or more.

In a case where a plurality of each of A's, X's, and W's are present, they may be the same as or different from each other, respectively.

Furthermore, a plurality of the compounds represented by General Formula (I) may be bonded via a single bond or at least one of A or W. That is, the plurality of the compounds represented by General Formula (I) may be bonded in a manner of sharing a group represented by A or W.

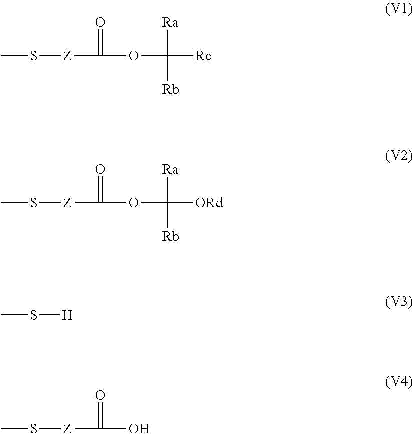

In Formulae (V1) to (V4),

Z represents a single bond or a divalent linking group, and the divalent linking group of Z has the same definition as X in General Formula (I). Z is preferably a single bond or an alkylene group. Ra, Rb, and Rc independently represent a hydrogen atom, an alkyl group, a cycloalkyl group, or an alkenyl group.

Rd represents an alkyl group, a cycloalkyl group, or an alkenyl group.

Furthermore, two groups out of Ra, Rb, and Rc, or two groups out of Ra, Rb, and Rd may be bonded to each other to form a ring structure including 3 to 8 carbon atoms, or may form a ring structure including carbon atoms and further including heteroatoms.

In General Formula (I), A represents a monovalent substituent. Examples of the monovalent substituent of A include a halogen atom such as a fluorine atom, a chlorine atom, a bromine atom, and an iodine atom; an alkoxy group such as a methoxy group, an ethoxy group, and a tert-butoxy group; an aryloxy group such as a phenoxy group and a p-tolyloxy group; an alkoxycarbonyl group such as a methoxycarbonyl group, a butoxycarbonyl group, and a phenoxycarbonyl group; an acyloxy group such as an acetoxy group, a propionyloxy group, and a benzoyloxy group; an acyl group such as an acetyl group, a benzoyl group, an isobutyryl group, an acryloyl group, a methacryloyl group, and a methoxalyl group; an alkylsulfanyl group such as a methylsulfanyl group and a tert-butylsulfanyl group; an arylsulfanyl group such as a phenylsulfanyl group and a p-tolylsulfanyl group; an alkylamino group such as a methylamino group and a cyclohexylamino group; a dialkylamino group such as a dimethylamino group, a diethylamino group, a morpholino group, and a piperidino group; an arylamino group such as a phenylamino group and a p-tolylamino group; an alkyl group such as a methyl group, an ethyl group, a tert-butyl group, and a dodecyl group; a cycloalkyl group such as a cyclopentyl group and a cyclohexyl group; an aryl group such as a phenyl group, a p-tolyl group, a xylyl group, a cumenyl group, a naphthyl group, an anthryl group, and a phenanthryl group; an alkynyl group such as an ethynyl group and a propargyl group; a hydroxy group; a carboxyl group; a formyl group; a mercapto group; a sulfo group; a mesyl group; a p-toluenesulfonyl group; an amino group; a nitro group; a cyano group; a trifluoromethyl group; a trichloromethyl group; a trimethylsilyl group; a phosphinico group; a phosphono group; a trimethylammoniumyl group; a dimethylsulfoniumyl group; and a triphenylphenacylphosphoniumyl group.

X is preferably a single bond, an alkylene group, an arylene group, a carbonyl group, a sulfide group, —O—, sulfonyl group, —C(═O)O—, —CONH—, —SO₂NH—, —SS—, —COCO—, —OCOO—, —SO₂O—, or a divalent linking group formed by combining these groups. More preferred examples thereof include a single bond, an alkylene group, an arylene group, a carbonyl group, a sulfonyl group, —COO—, —CONH—, —SO₂NH—, a sulfide group, and —O—.

Preferred examples of the combination include a combination of an alkylene group and a carbonyl group, a sulfonyl group —COO—, —CONH—, —SO₂NH—, a sulfide group, or —O—.

The number of atoms in the linking group as X is preferably from 1 to 10.

Specific examples of X are set forth below, but the present invention is not limited thereto.

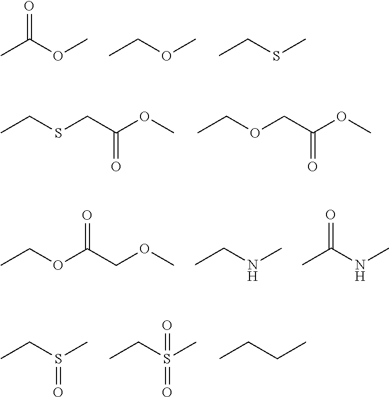

W represents a group having a lactone ring, or a group represented by any one of Formulae (V1) to (V4).

In a case where W is the group having a lactone ring, the compound is hydrolyzed during the development to generate a carboxyl group (alkali-soluble group), and therefore, the compound contributes to reduction particularly in the development defect.

In the case of a group represented by Formula (V1) where Ra, Rb, and Rc each represents an alkyl group, a cycloalkyl group, or an alkenyl group or in the case of a group represented by Formula (V2), W is a group having an acid-decomposable group, and since a deprotection reaction proceeds by the action of an acid generated from an acid generator upon exposure and an alkali-soluble group is produced, the compound contributes to reduction particularly in the development defect.

The group represented by Formula (V3) or (V4) is a group having an acid group such as a thiol group and a carboxyl group and is an alkali-soluble group, and therefore, the compound contributes to enhancement particularly of the performance of reducing the development defect.

The group represented by —X—W is preferably bonded to the benzene ring in the center of the anthracene ring.

m represents an integer of 0 or more, and is preferably an integer of 0 to 3, and particularly preferably 0.

n represents an integer of 1 or more, and is preferably an integer of 1 to 3, and particularly preferably 1.

First, a case where W is a group having a lactone ring will be described.

The lactone ring contained in the group having a lactone ring as W is preferably a 4- to 8-membered ring, and more preferably a 5- to 7-membered ring. The lactone ring may have a double bond therein.

Examples of the substituent which may be contained in the lactone ring include an alkyl group, an alkoxy group, an acyl group, an oxy group (>C═O), a hydroxyl group, and those described for the substituent as A, and the substituent may be a group substituted with another substituent.

Specific examples of the lactone ring include, but are not limited to, structures of General Formulae (LC1-1) to (LC1-17).

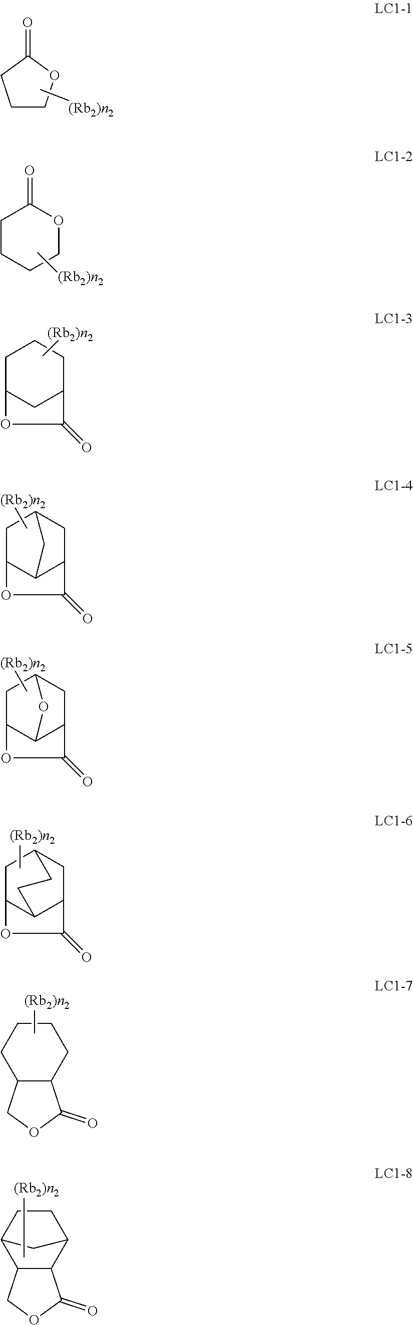

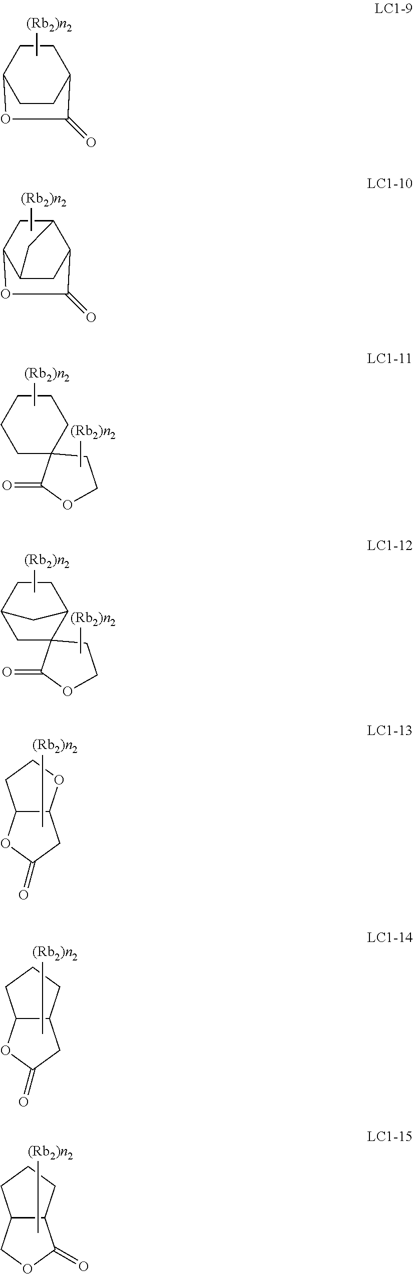

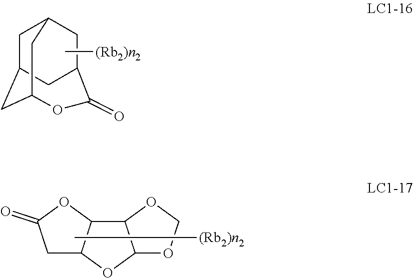

The lactone structure moiety may or may not have a substituent (Rb₂). Preferred examples of the substituent (Rb₂) include an alkyl group having 1 to 8 carbon atoms, a cycloalkyl group having 3 to 7 carbon atoms, an alkoxy group having 1 to 8 carbon atoms, an alkoxycarbonyl group having 1 to 8 carbon atoms, a carboxyl group, a halogen atom, a hydroxyl group, a cyano group, and an acid-decomposable group.

n₂ represents an integer of 0 to 4. In a case where n₂ is an integer of 2 or more, the substituents (Rb₂) which are present in plural numbers may be the same as or different from each other, and further, the substituents (Rb₂) which are present in plural numbers may be bonded to each other to form a ring.

More specific examples, the following lactone structures may be mentioned.

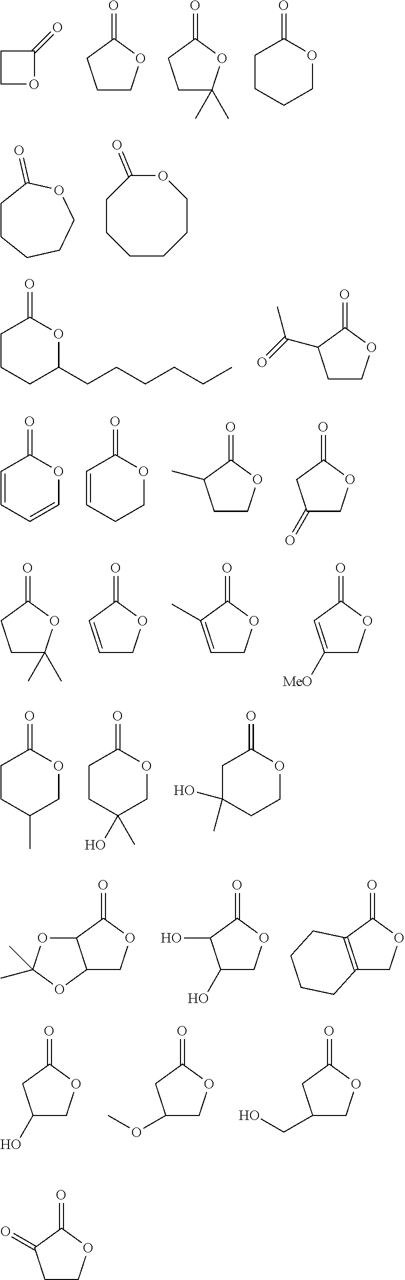

Examples of the compound represented by General Formula (I) in a case where W is a group having a lactone ring include, but are not limited to, the following compounds.

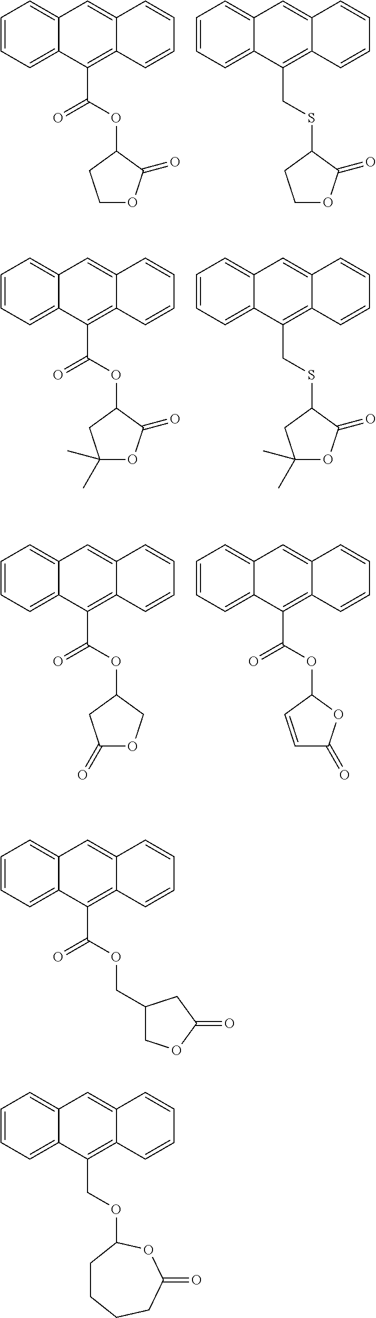

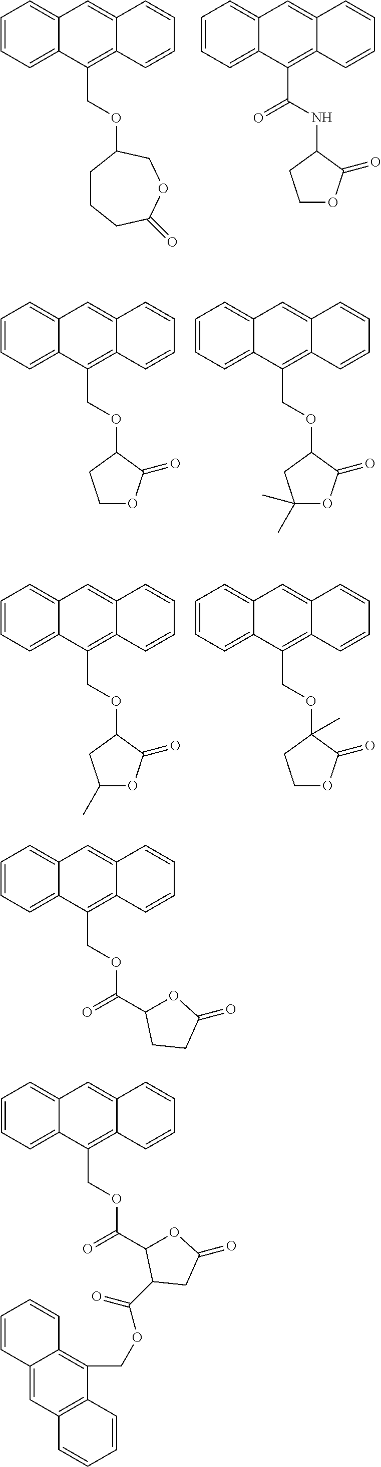

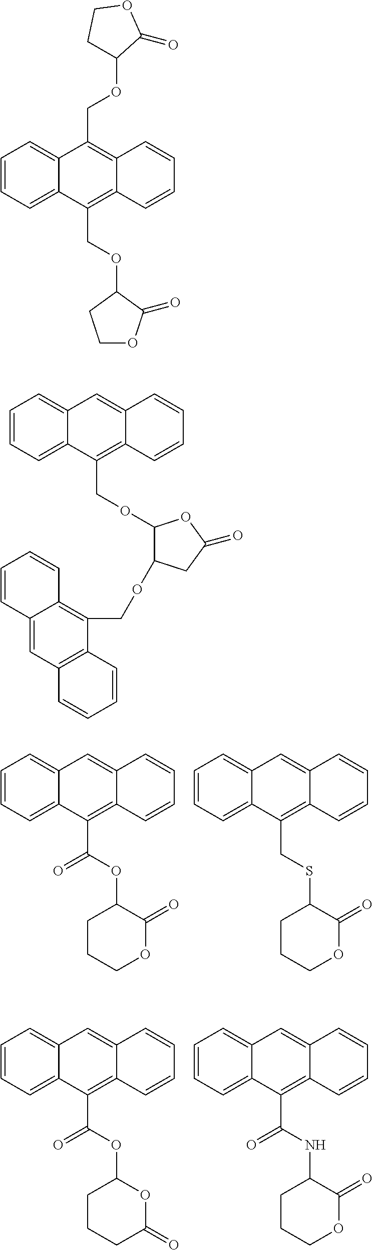

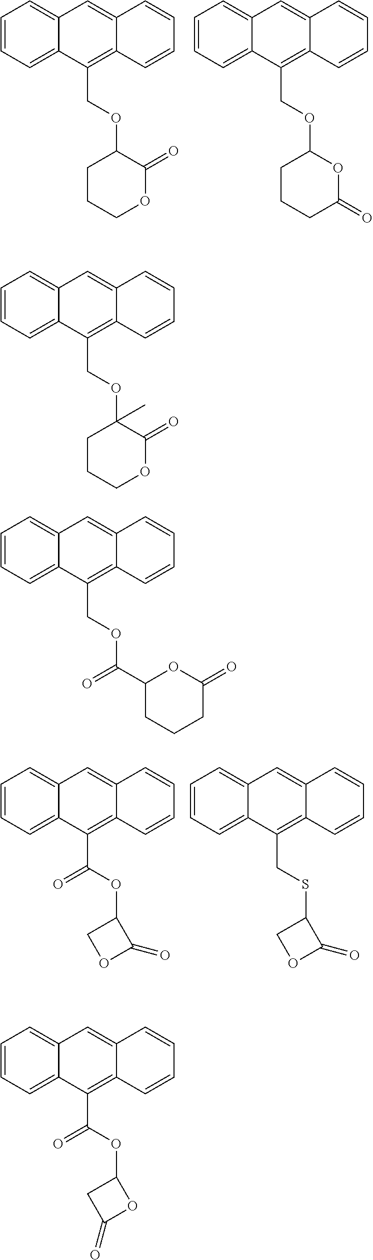

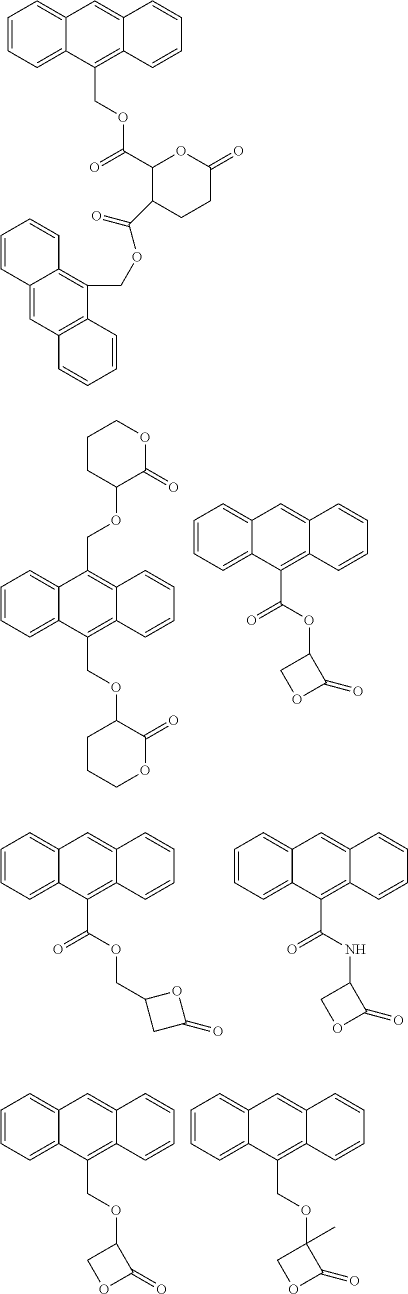

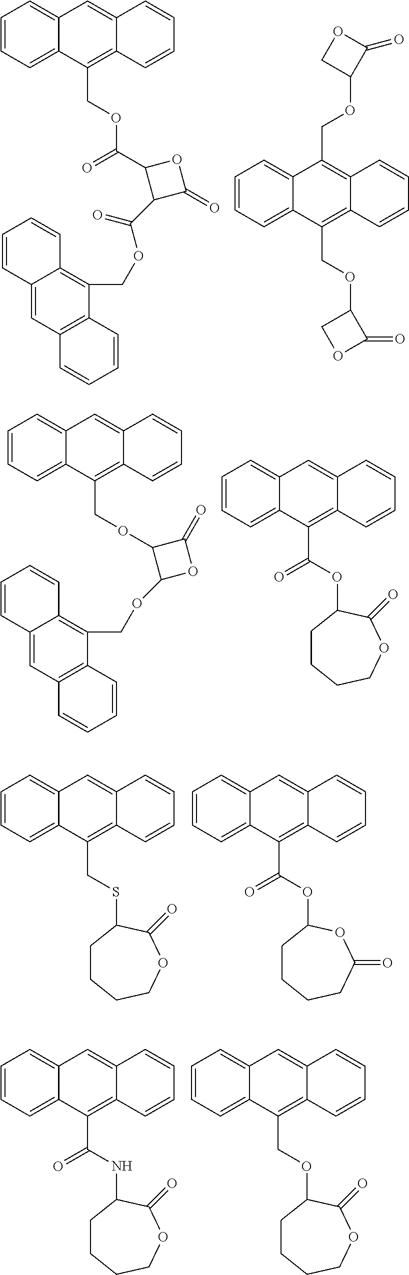

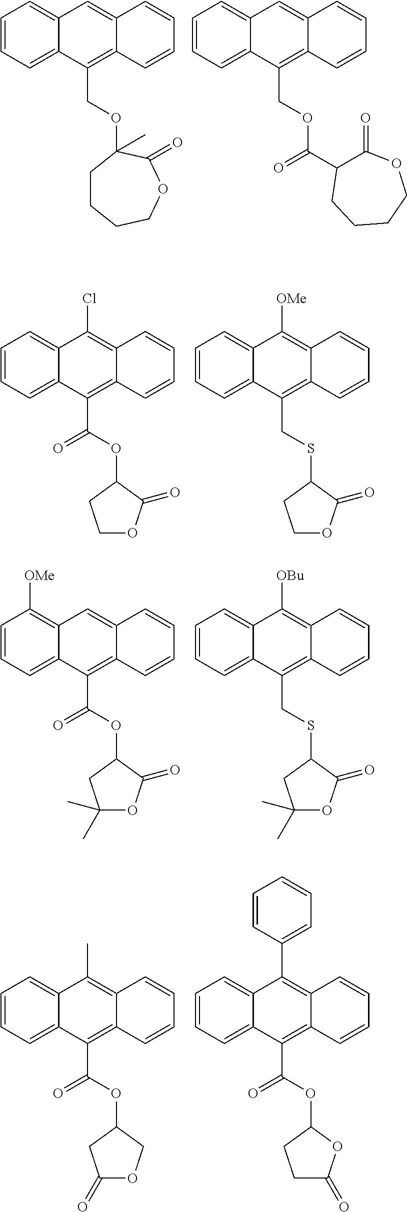

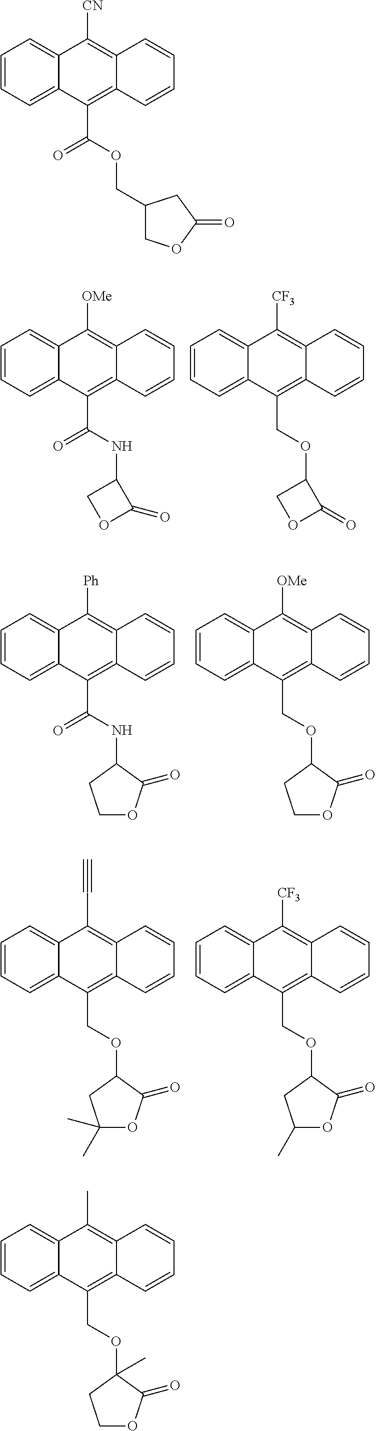

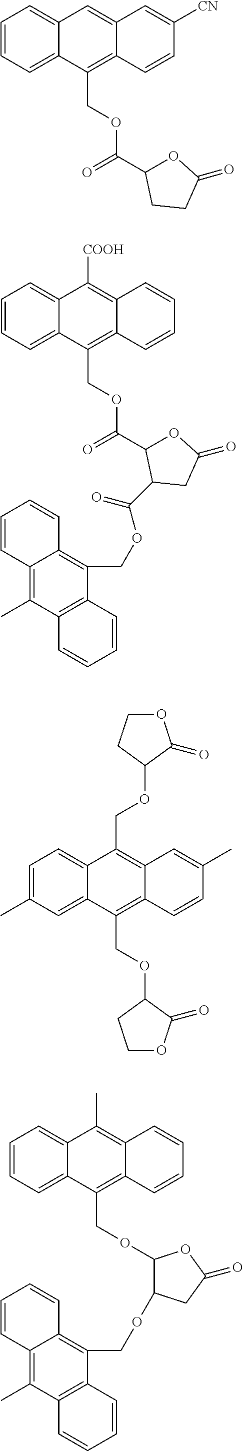

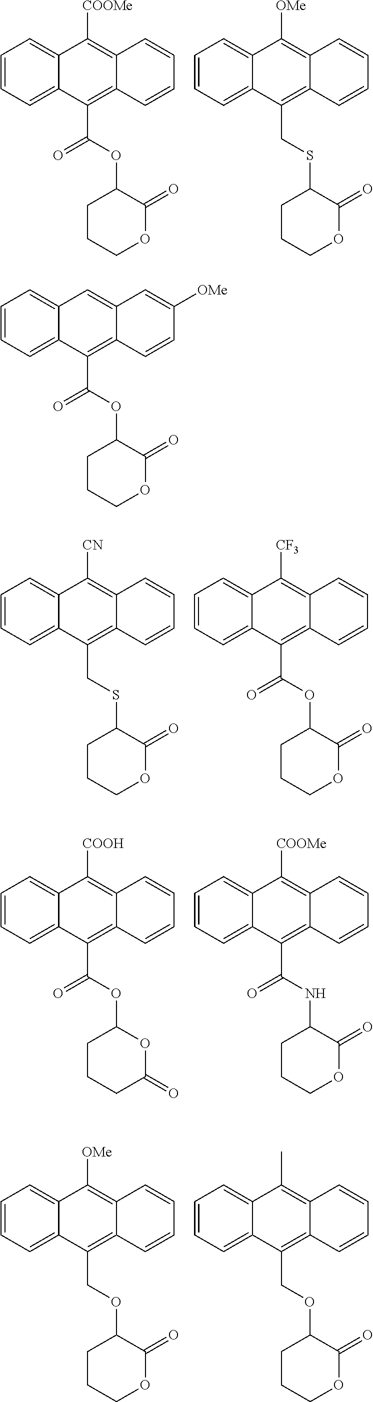

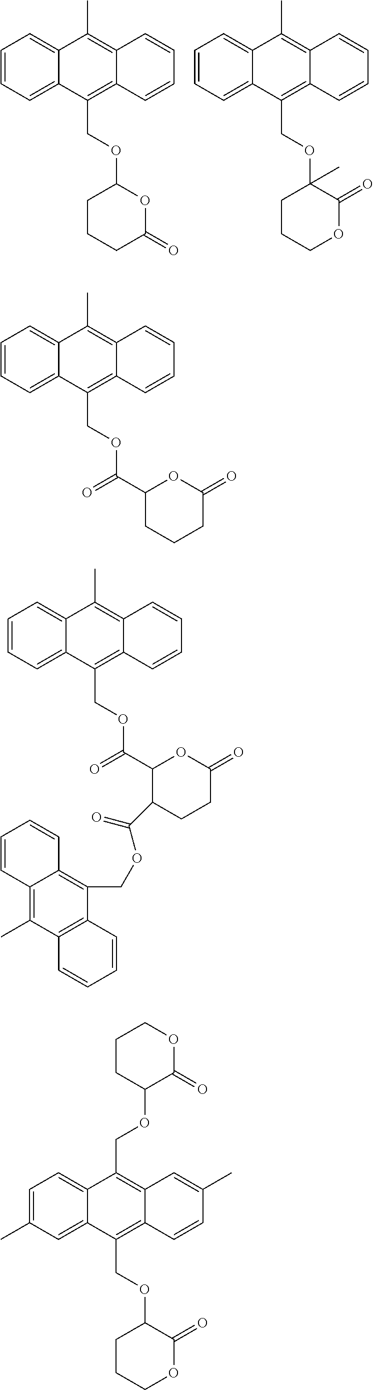

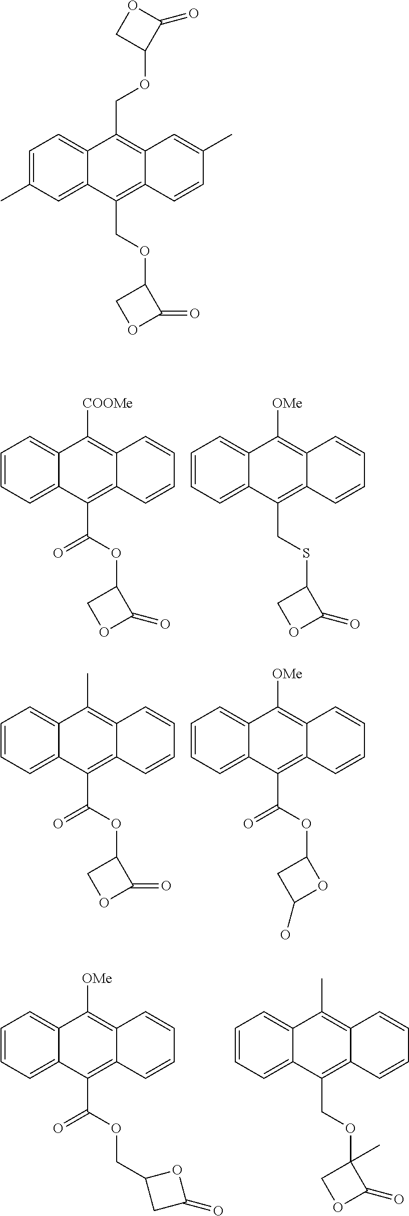

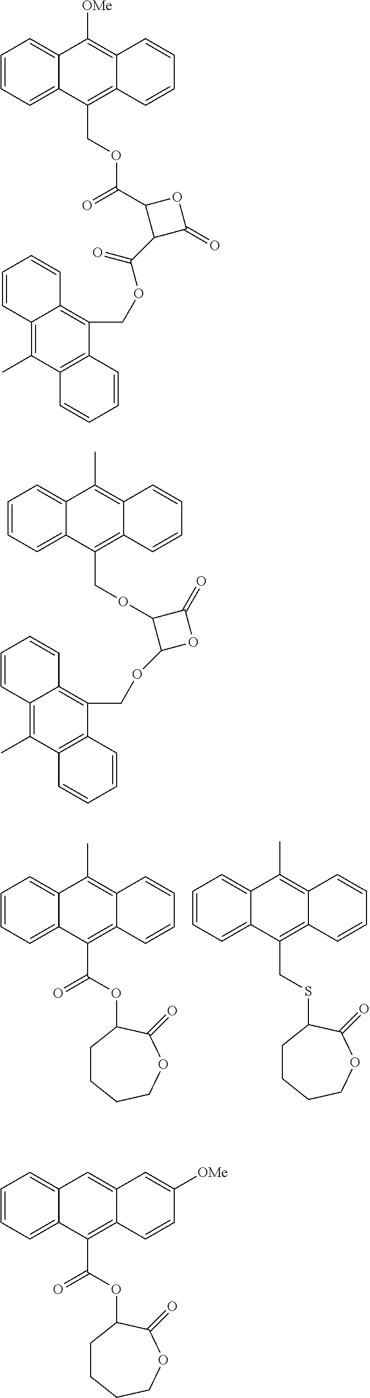

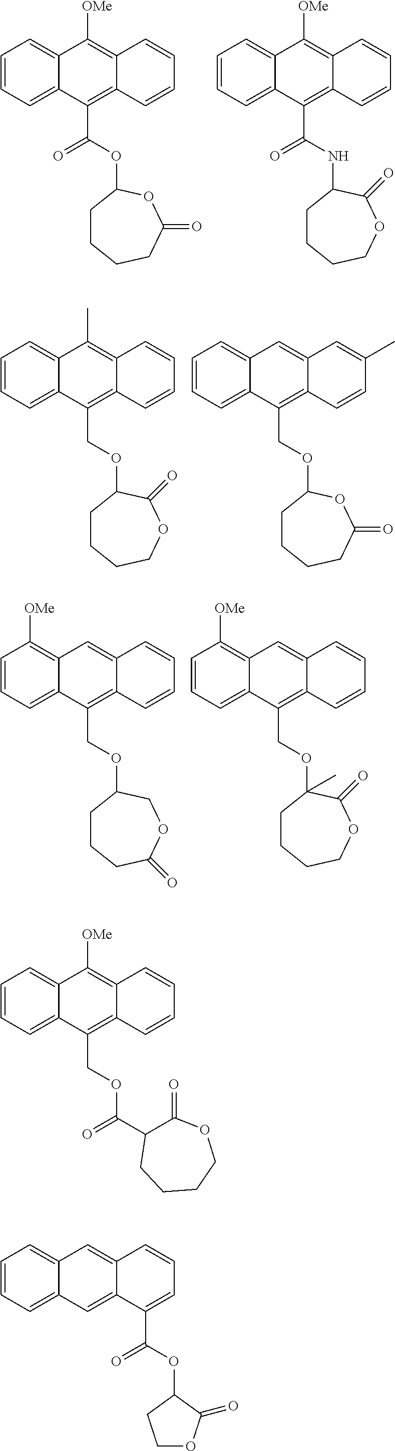

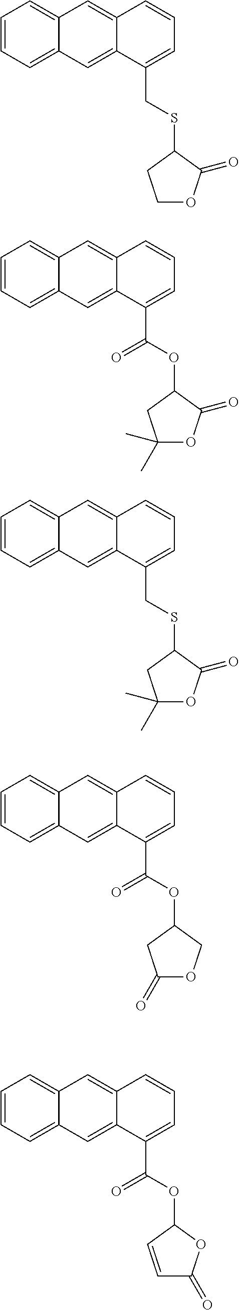

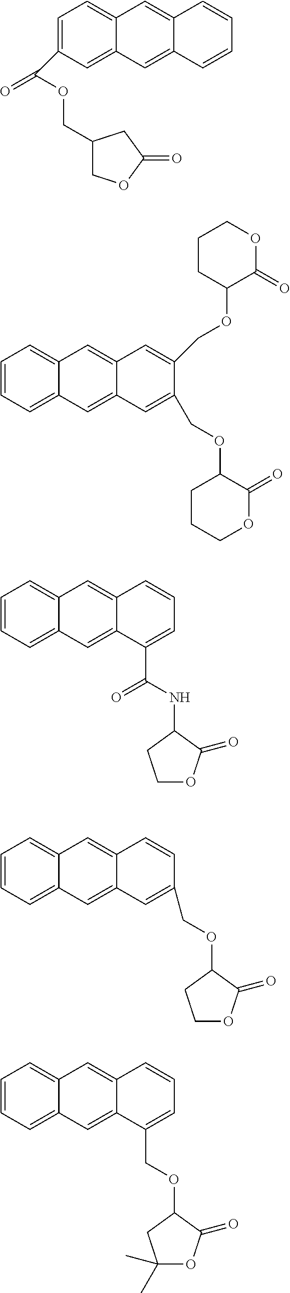

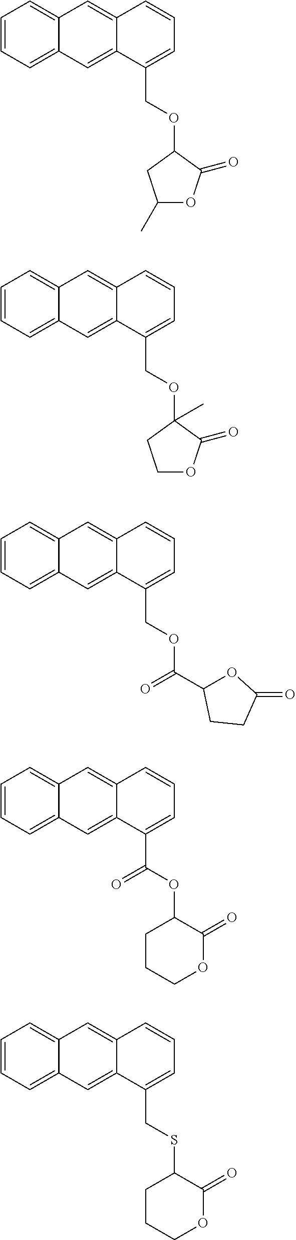

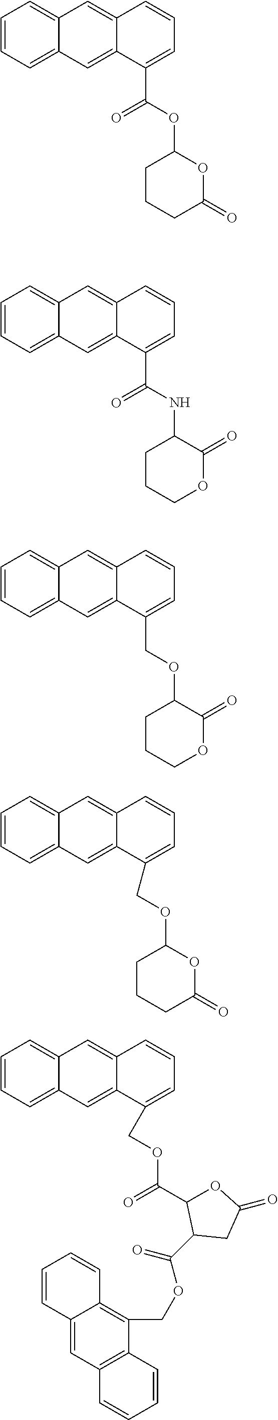

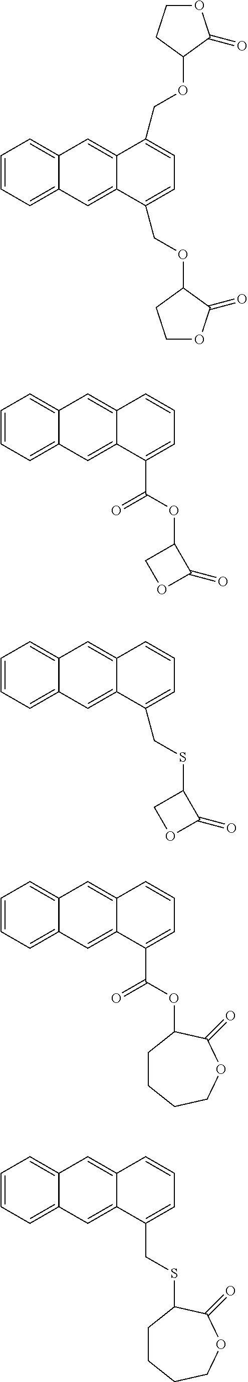

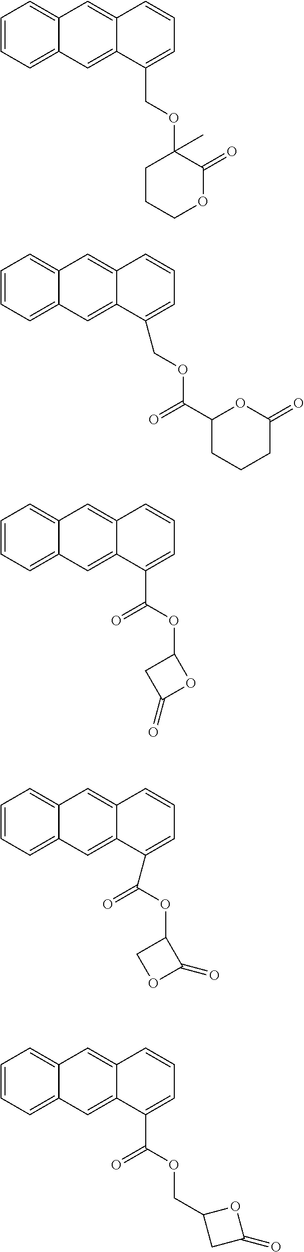

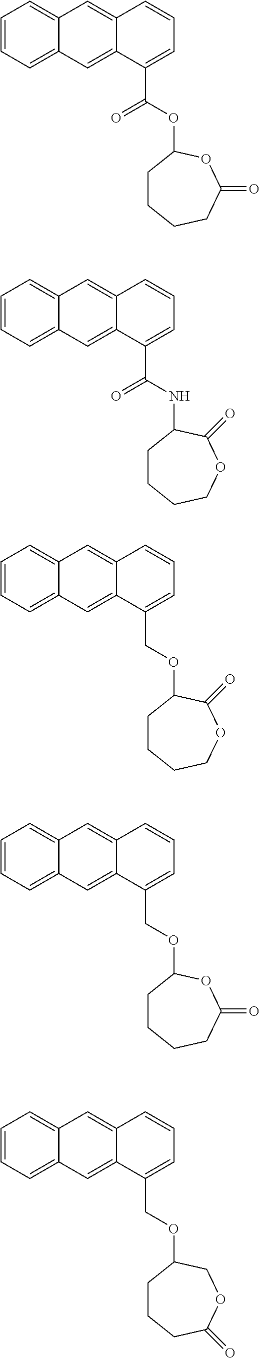

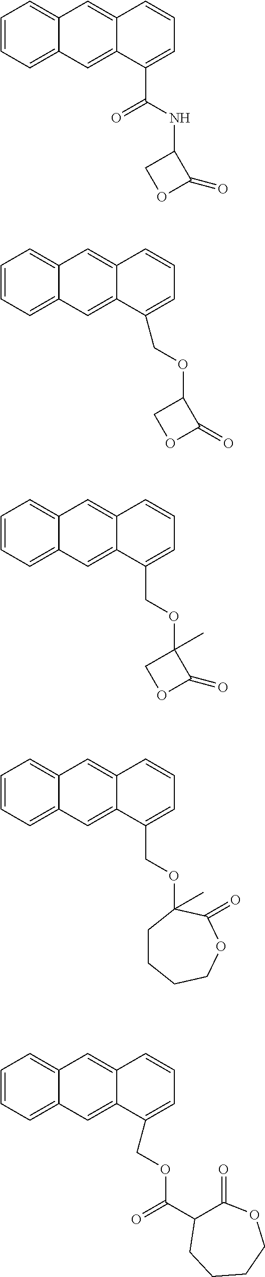

Next, a case where W is a group represented by any one of Formulae (V1) to (V4) will be described.

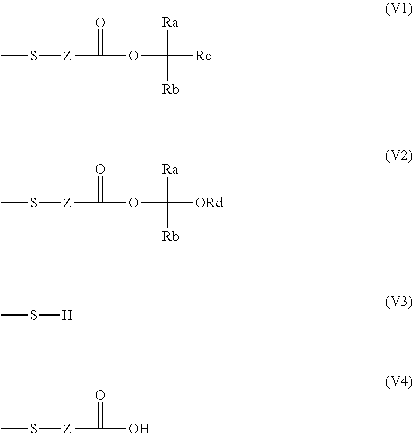

In Formulae (V1) to (V4),

Z represents a single bond or a divalent linking group, and the divalent linking group of Z is the same as X in General Formula (I). Z is preferably a single bond or an alkylene group (for example, a methylene group, an ethylene group, a propylene group, a butylene group, and a hexylene group). In Formulae (V1) and (V2), Z is preferably a single bond or a methylene group, and in Formula (V4), Z is preferably a methylene group.

Ra, Rb, and Rc each independently represent a hydrogen atom, an alkyl group, a cycloalkyl group, or an alkenyl group.

Rd represents an alkyl group, a cycloalkyl group, or an alkenyl group.

Incidentally, with respect to the group represented by Formula (V1), a case where Ra, Rb, and Rc each preferably represent an alkyl group, a cycloalkyl group, or an alkenyl group, that is, a case where Ra, Rb, and Rc are each a group having an acid-decomposable group capable of generating a carboxyl group by allowing a group represented by —C(Ra)(Rb)(Rc) to leave by the action of an acid.

Moreover, two groups out of Ra, Rb, and Rc or two groups out of Ra, Rb, and Rd may be bonded to each other to form a ring structure including carbon atoms, or may form a ring structure including carbon atoms and further including heteroatoms.

The ring structure formed preferably has 3 to 15 carbon atoms, and more preferably has 3 to 8 carbon atoms, and examples thereof include a cyclopropyl group, a cyclopentyl group, a cyclohexyl group, a cycloheptyl group, a 1-cyclohexenyl group, an adamantyl group, a 2-tetrahydrofuranyl group and a 2-tetrahydropyranyl group.

The alkyl group of each of Ra to Rd is preferably an alkyl group having 1 to 8 carbon atoms, which may have a substituent, such as a methyl group, an ethyl group, a propyl group, an n-butyl group, a sec-butyl group, a hexyl group, a 2-ethylhexyl group, and an octyl group.

The cycloalkyl group is preferably a cycloalkyl group having 3 to 8 carbon atoms, which may have a substituent, such as a cyclopropyl group, a cyclopentyl group, and a cyclohexyl group.

The alkenyl group is preferably an alkenyl group having 2 to 6 carbon atoms, which may have a substituent, such as a vinyl group, a propenyl group, an allyl group, a butenyl group, a pentenyl group, a hexenyl group, and a cyclohexenyl group.

Moreover, preferred examples of the additional substituent on each of the groups described above in detail include a hydroxyl group, a halogen atom (a fluorine atom, a chlorine atom, a bromine atom, and an iodine atom), a nitro group, a cyano group, an amido group, a sulfonamido group, an alkyl group such as a methyl group, an ethyl group, a propyl group, an n-butyl group, a sec-butyl group, a hexyl group, an 2-ethylhexyl group, and an octyl group, an alkoxy group such as a methoxy group, an ethoxy group, a hydroxyethoxy group, a propoxy group, a hydroxypropoxy group, and a butoxy group, an alkoxycarbonyl group such as a methoxycarbonyl group and an ethoxycarbonyl group, an acyl group such as a formyl group, an acetyl group, and a benzoyl group, an acyloxy group such as an acetoxy group and a butyryloxy group, and a carboxyl group.

Specific examples of the compound represented by General Formula (I) in a case where W is a group represented by any one of Formulae (V1) to (V4) are set forth below, but the present invention is not limited thereto.

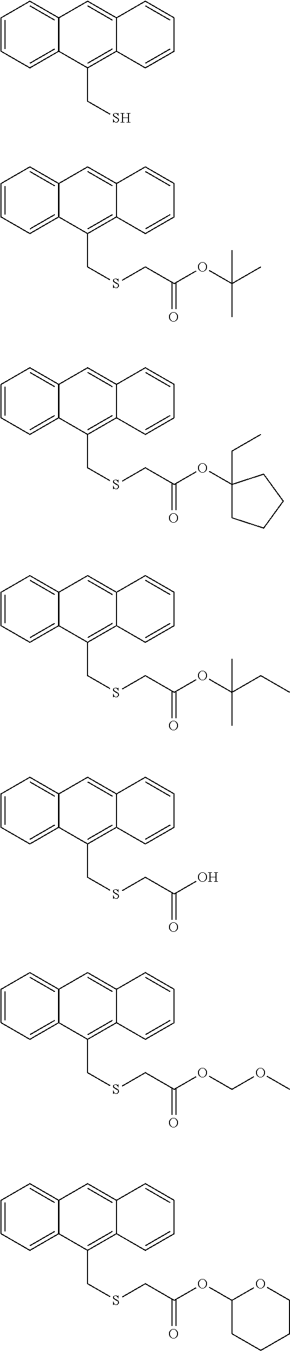

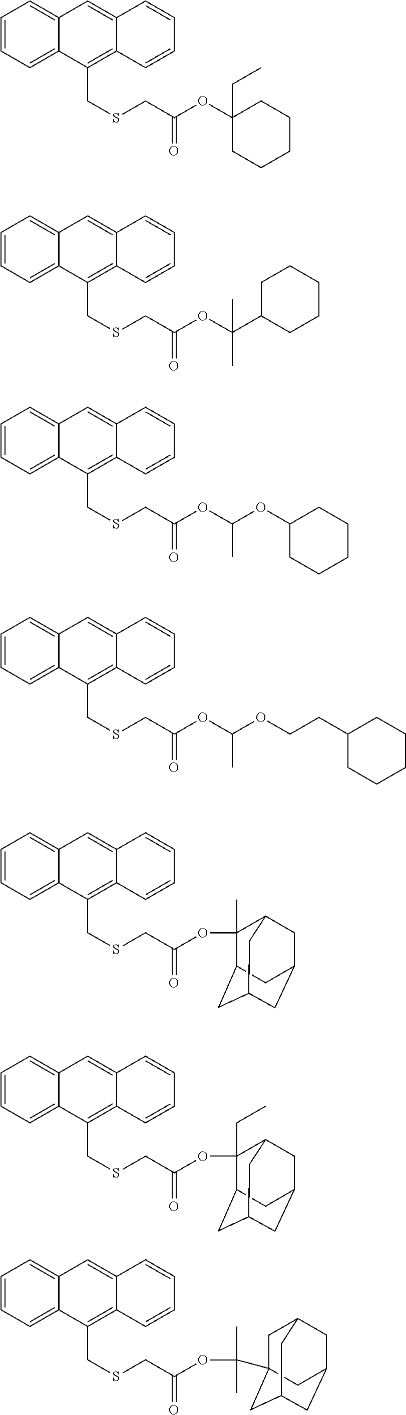

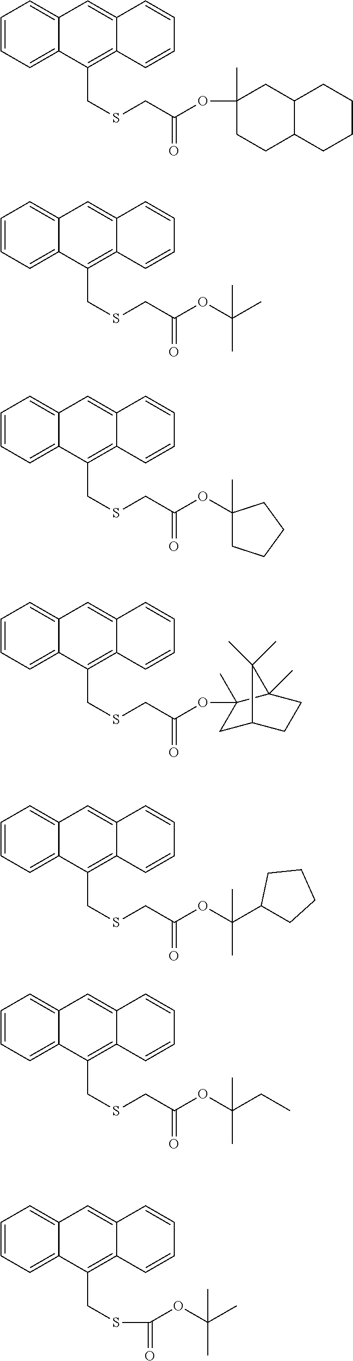

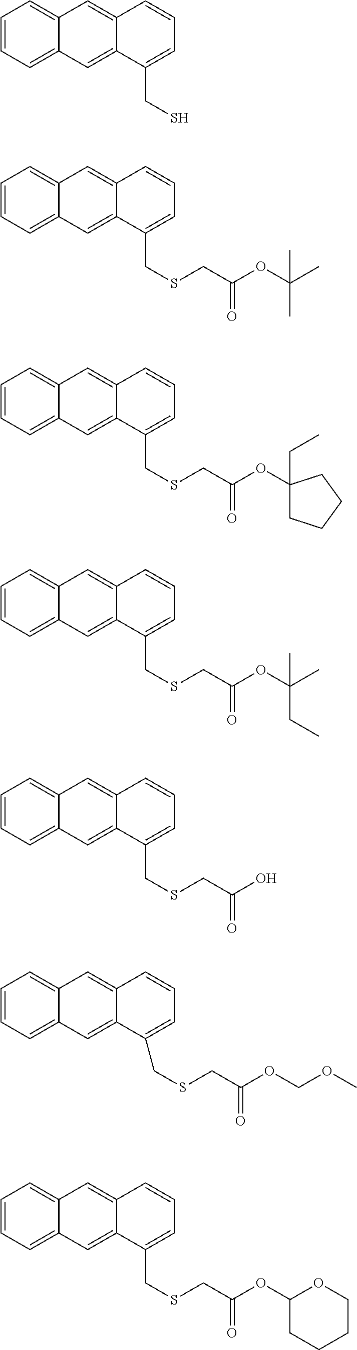

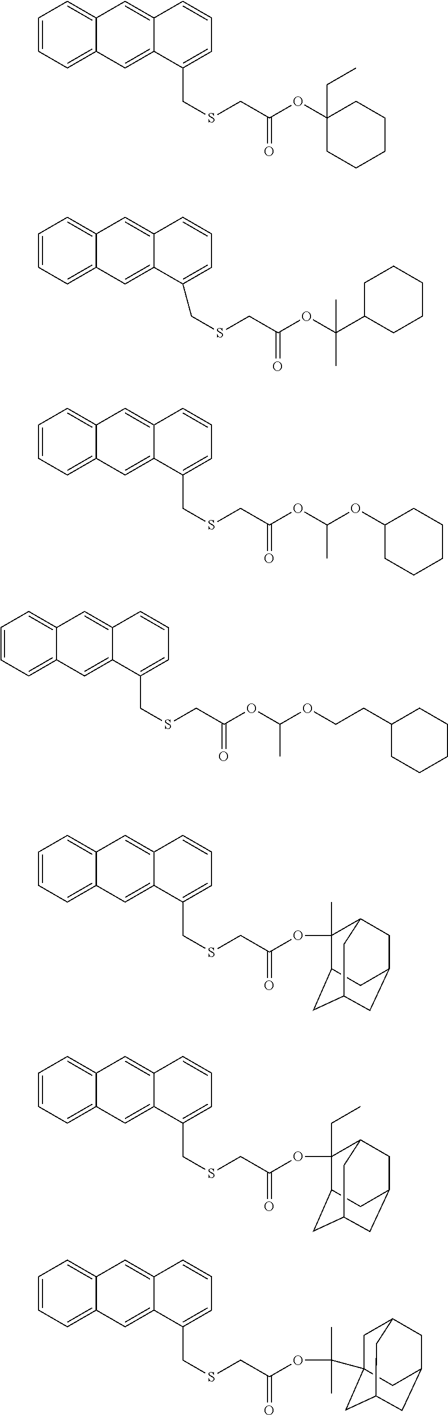

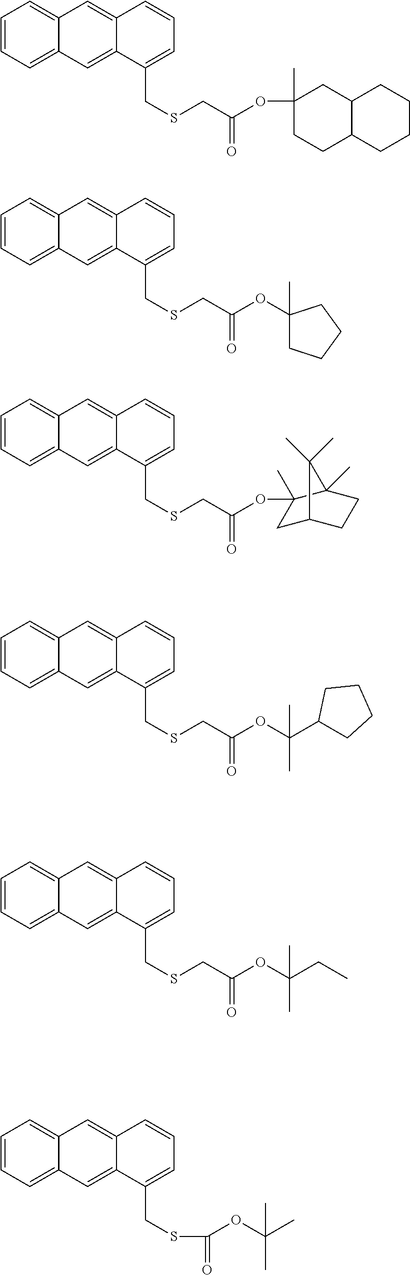

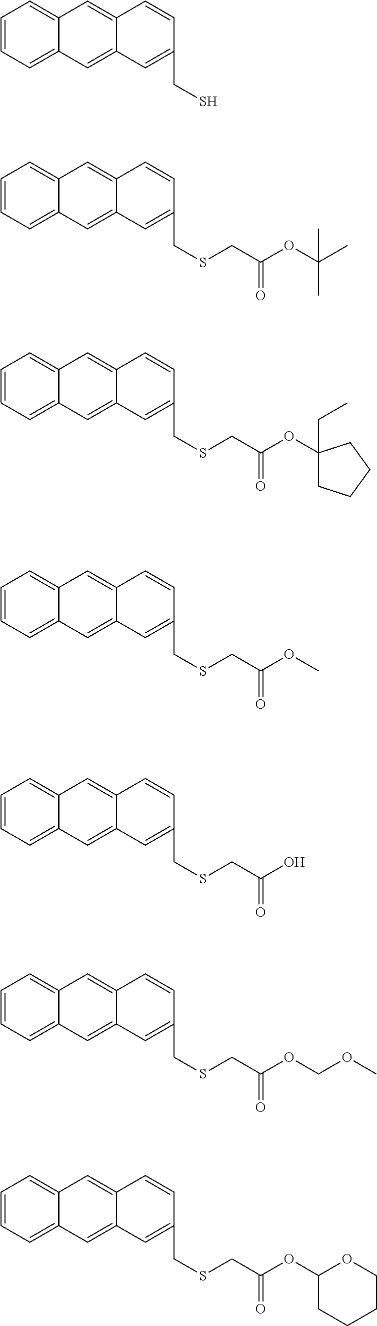

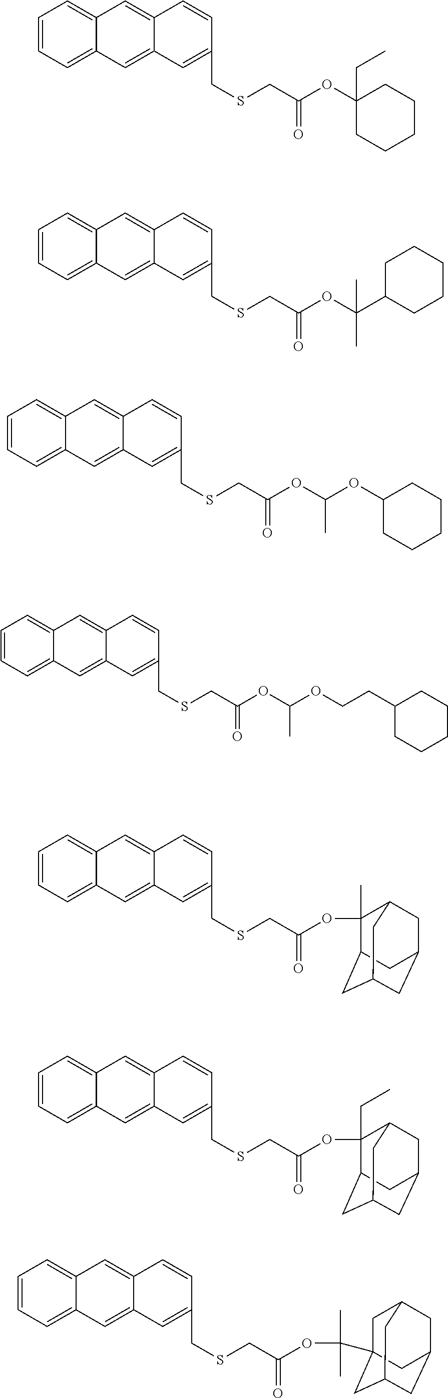

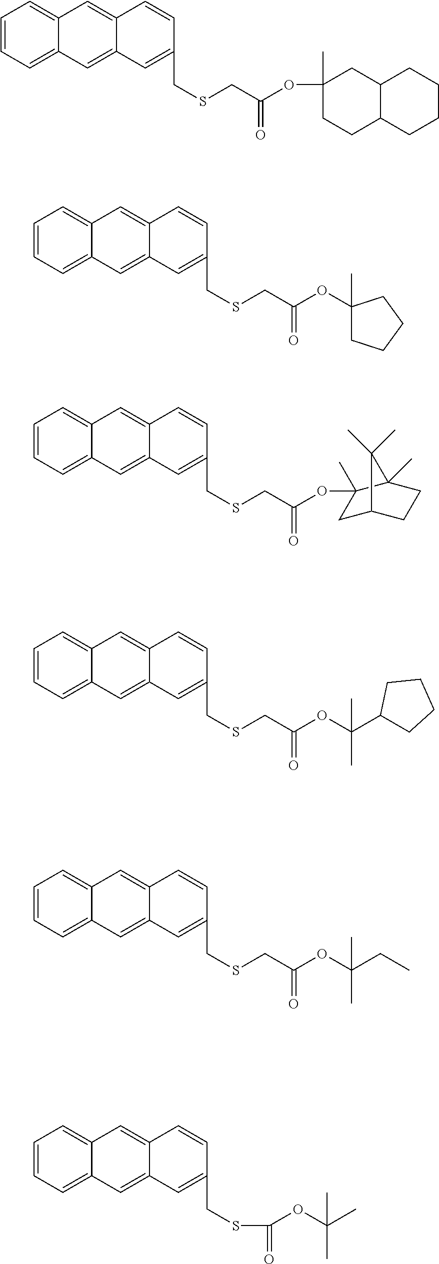

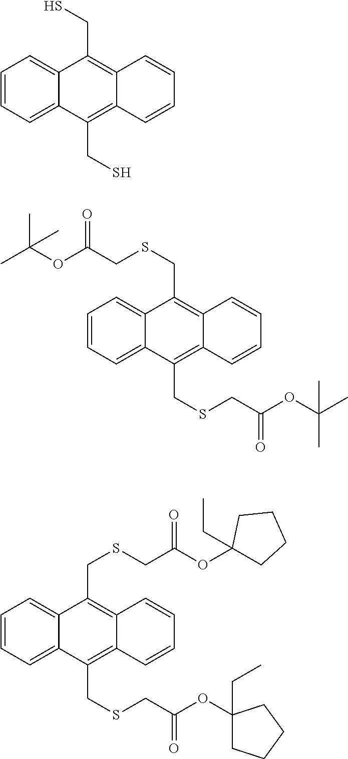

The molecular weight of the compound (A) is generally 100 to 1,000, and preferably 200 to 500.

The compound (A) may be synthesized by a known method, or a commercially available product may be used. For example, the compound can be synthesized as follows. In the following, X has the same definition as that in General Formula (I).

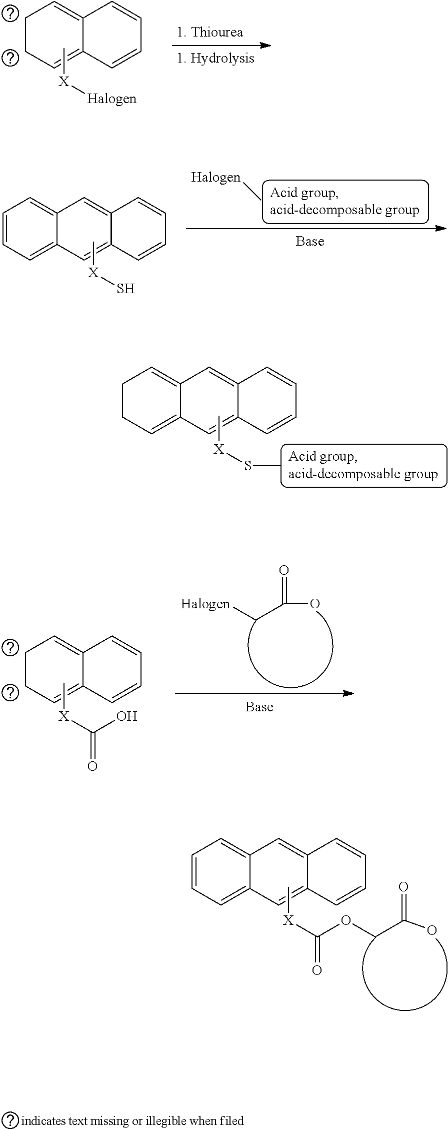

The amount of the compound (A) to be added is preferably 0.1% to 10% by mass, and more preferably 0.2% to 5% by mass, with respect to the total solid content of the actinic ray-sensitive or radiation-sensitive resin composition.

<Other Additives>

The composition of the present invention may or may not contain an onium carboxylate salt. Examples of such an onium carboxylate salt include those described in <0605> to <0606> in the specification of US2008/0187860A.

The onium carboxylate salt can be synthesized by reacting sulfonium hydroxide, iodonium hydroxide, ammonium hydroxide and carboxylic acid with silver oxide in a suitable solvent.

In a case where the composition of the present invention contains the onium carboxylate salt, the content of the onium carboxylate salt is generally 0.1% to 20% by mass, preferably 0.5% to 10% by mass, and more preferably 1% to 7% by mass, with respect to the total solid contents of the composition.

The composition of the present invention may further contain an acid proliferation agent, a dye, a plasticizer, a light sensitizer, a light absorbent, an alkali-soluble resin, a dissolution inhibitor, a compound promoting solubility in a developer (for example, a phenol compound having a molecular weight of 1,000 or less, and an alicyclic or aliphatic compound having a carboxyl group), and the like, as desired.

Such a phenol compound having a molecular weight of 1,000 or less can be easily synthesized by those skilled in the art with reference to the method described in, for example, JP1992-122938A (JP-H04-122938A), JP1990-28531A (JP-H02-28531A), U.S. Pat. No. 4,916,210A, EP219294B, or the like.

Specific examples of the alicyclic or aliphatic compound having a carboxyl group include, but not limited to, a carboxylic acid derivative having a steroid structure such as a cholic acid, deoxycholic acid or lithocholic acid, an adamantane carboxylic acid derivative, adamantane dicarboxylic acid, cyclohexane carboxylic acid, and cyclohexane dicarboxylic acid.

The concentration of the solid content of the composition according to the present invention is usually 1.0% to 30% by mass, preferably 2.0% to 25% by mass, and more preferably 2.0% to 20% by mass. By setting the concentration of the solid content to these ranges, it is possible to uniformly coat the resist solution on a substrate, and additionally, it is possible to form a resist pattern having excellent line width roughness (LWR). The reason is not clear; however, it is considered that, by setting the concentration of the solid content to 10% by mass or less, and preferably 5.7% by mass or less, the aggregation of materials, particularly the acid generator, in the resist solution is suppressed and, as the result, it is possible to form a uniform resist film.

The concentration of the solid content is the mass percentage of the mass of other resist components excluding the solvent with respect to the total mass of the composition.

The composition of the present invention is used by dissolving the components in a predetermined organic solvent, and preferably in the mixed solvent, filtering the solution through a filter, and then applying the filtered solution on a predetermined substrate. The filter for use in filtration is preferably a polytetrafluoroethylene-, polyethylene- or nylon-made filter having a pore size of 0.1 μm or less, more preferably 0.05 μm or less, and still more preferably 0.03 μm or less. In the filtration through a filter, as described in, for example, JP2002-62667A, circulating filtration may be carried out, or the filtration may be carried out by connecting plural kinds of filters in series or in parallel. In addition, the composition may be filtered in plural times. Furthermore, the composition may be subjected to a deaeration treatment or the like before or after filtration through a filter.

It is preferable that various materials (for example, a resist solution, a developer, a rinsing liquid, a composition for forming an antireflection film, and a composition for forming a topcoat) used in the actinic ray-sensitive or radiation-sensitive resin composition of the present invention and the pattern forming method of the present invention do not include impurities such as metals. The content of the impurities included in these materials is preferably 1 ppm or less, more preferably 10 ppb or less, still more preferably 100 ppt or less, and particularly preferably 10 ppt or less, but the material not having substantially metal components (within a detection limit of a determination device, or less) is particularly preferable.

Examples of a method for removing impurities such as metals from the various materials include filtration using a filter. As for the filter pore diameter, the pore size is preferably 10 nm or less, more preferably 5 nm or less, and still more preferably 3 nm or less. As for the materials of a filter, a polytetrafluoroethylene-made filter, a polyethylene-made filter, and a nylon-made filter are preferable. The filter may be formed of a composite material formed by combining this material with an ion exchange medium. As the filter, a filter which had been washed with an organic solvent in advance may be used. In the step of filtration using a filter, plural kinds of filters may be connected in series or in parallel, and used. In a case of using plural kinds of filters, a combination of filters having different pore diameters and/or materials may be used. In addition, various materials may be filtered plural times, and a step of filtering plural times may be a circulatory filtration step.

Moreover, examples of the method for reducing the impurities such as metals included in the various materials include a method involving selecting raw materials having a small content of metals as raw materials constituting various materials, a method involving subjecting raw materials constituting various materials to filtration using a filter, and a method involving performing distillation under the condition with contamination being suppressed to the largest degree by, for example, lining the inside of a device with TEFLON (registered trademark). The preferred conditions for filtration using a filter, which is carried out for raw materials constituting various materials, are the same as described above.

In addition to filtration using a filter, removal of impurities by an adsorbing material may be carried out, or a combination of filtration using a filter and an adsorbing material may be used. As the adsorbing material, known adsorbing materials may be used, and for example, inorganic adsorbing materials such as silica gel and zeolite, and organic adsorbing materials such as activated carbon can be used.

A method for improving the surface roughness of a pattern may be applied to the pattern formed by the pattern forming method of the present invention. Examples of the method for improving the surface roughness of a pattern include the method of treating a resist pattern by a plasma of a hydrogen-containing gas disclosed in WO2014/002808. In addition, known methods as described in JP2004-235468A, US2010/0020297A, JP2009-19969A, and Proc. of SPIE Vol. 8328 83280N-1 “EUV Resist Curing Technique for LWR Reduction and Etch Selectivity Enhancement” may be applied.

The pattern forming method of the present invention can be used for a guide pattern formation in a directed self-assembly (DSA) (see, for example, ACS Nano Vol. 4 No. 8 Pages 4815-4823).

In addition, a resist pattern formed by the method can be used as a core material (core) of the spacer process disclosed in JP1991-270227A (JP-H03-270227A) and JP2013-164509A.

An electrically conductive compound may be added to the organic treatment liquid (a developer, a rinsing liquid, or the like) used in the pattern forming method in order to prevent failure of chemical liquid pipe and various parts (a filter, an O-ring, a tube, or the like) due to electrostatic charge, and subsequently generated electrostatic discharge. The electrically conductive compound is not particularly limited and examples thereof include methanol. The addition amount is not particularly limited, but from the viewpoint of maintaining preferred developing characteristics, it is preferably 10% by mass or less, and more preferably 5% by mass or less. For members of the chemical liquid pipe, various pipes coated with stainless steel (SUS), or a polyethylene, polypropylene, or fluorine resin (a polytetrafluoroethylene or perfluoroalkoxy resin, or the like) that has been subjected to an antistatic treatment can be used. In the same manner, for the filter or the O-ring, polyethylene, polypropylene, or fluorine resin (a polytetrafluoroethylene or perfluoroalkoxy resin, or the like) that has been subjected to an antistatic treatment can be used.

Moreover, generally, the developer and the rinsing liquid are stored in a waste liquid tank through a pipe after use. At that time, there is a method of passing a solvent in which a resist is dissolved again through a pipe in order to prevent the resist dissolved in a developer from being precipitated and adhering to the rear surface of a wafer, the side surface of the pipe, or the like, in a case where a hydrocarbon-based solvent is used as the rinsing liquid. Examples of the method of passing the solvent through the pipe include a method in which the rear surface, the side surface, and the like of a substrate are washed with a solvent in which the resist is dissolved and then the solvent is allowed to flow after washing with a rinsing liquid, and a method of flowing a solvent in which a resist is dissolved without being in contact with the resist so as to pass through a pipe.

The solvent to be passed through the pipe is not particularly limited as long as it can dissolve the resist, and examples thereof include the above-mentioned organic solvents. Propylene glycol monomethyl ether acetate (PGMEA), propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate, ethylene glycol monoethyl ether acetate, propylene glycol monomethyl ether (PGME), propylene glycol monoethyl ether, propylene glycol monopropyl ether, propylene glycol monobutyl ether, ethylene glycol monomethyl ether, ethylene glycol monoethyl ether, 2-heptanone, ethyl lactate, 1-propanol, acetone, or the like can be used. Among those, PGMEA, PGME, or cyclohexanone can be preferably used.

In a case where the topcoat composition includes a plurality of the resins (X), it preferably includes at least one kind of the resin (XA) having fluorine atoms and/or silicon atoms. The topcoat composition more preferably includes at least one kind of the resin (XA) having fluorine atoms and/or silicon atoms, and a resin (XB) having a smaller content of the fluorine atoms and/or the silicon atoms than that of the resin (XA) topcoat composition more preferable. Thus, in a case where the topcoat composition includes a plurality of the resins (X), it is possible to improve performance such as developing characteristics and immersion liquid tracking properties so as to make the resin (XA) unevenly distributed on the surface of a topcoat during the formation of the topcoat.

The content of the resin (XA) is preferably 0.01% to 30% by mass, more preferably 0.1% to 10% by mass, still more preferably 0.1% to 8% by mass, and particularly preferably 0.1% to 5% by mass, with respect to the total solid content included in the topcoat composition. The content of the resin (XB) is preferably 50.0% to 99.9% by mass, more preferably 60% to 99.9% by mass, still more preferably 70% to 99.9% by mass, particularly preferably 80% to 99.9% by mass, with respect to the total solid content included in the topcoat composition.

A preferred range of the content of the fluorine atoms and the silicon atoms contained in the resin (XA) is the same as the preferred range of a case where the resin (X) has fluorine atoms and a case where the resin (X) contains silicon atoms.

An aspect in which the resin (XB) does not substantially contain fluorine atoms and silicon atoms is preferable, and in this case, specifically, the total content of the repeating units having fluorine atoms and the repeating units having silicon atoms is preferably 0% to 20% by mole, more preferably 0% to 10% by mole, still more preferably 0% to 5% by mole, particularly preferably 0% to 3% by mole, and ideally 0% by mole, that is, containing neither a fluorine atom nor a silicon atom, with respect to all the repeating units in the resin (XB).

### Examples

Hereinafter, the present invention will be described with reference to Examples, but the present invention is not limited thereto.

<Preparation of Actinic Ray-Sensitive or Radiation-Sensitive Resin Composition>

The components shown in Table 1 were dissolved in a solvent at a ratio (unit: parts by mass in the total mass of the composition) shown in the same table. For each, a resist solution was prepared and filtered through an ultrahigh-molecular-weight polyethylene (UPE) filter having a pore size of 1.0 m, thereby preparing an actinic ray-sensitive or radiation-sensitive resin composition (resist composition) having a concentration of the solid content of 14.2% by mass.

Furthermore, in Table 1, the section of “PEB (° C.)” represents a temperature for (Post Exposure Bake; PEB) carried out in (Evaluation of Deviation of Film Thickness) which will be described later.

Furthermore, in Table 1, the section of “Condition 1 or condition 2” indicates which one of the above-mentioned condition 1 or condition 2 is satisfied. Cases where the both are not satisfied are denoted with “-”

TABLE 1

| | | | Acid | | Acid | | | | | | | |
|---|---|---|---|---|---|---|---|---|---|---|---|---|
| | Resin | | generator | | diffusion | | | | Light | | | |
| | Type | | Type | | control agent | | Surfactant | | absorbent | | Solvent | |
| | (mass | Content | (mass | Content | | Content | | Content | | Content | | Content |
| | ratio) | (wt %) | ratio) | (wt %) | Type | (wt %) | Type | (wt %) | Type | (wt %) | Type | (wt %) |
| Example 1 | A-1 | 18.31 | B-1 | 0.18 | C-1 | 0.01 | D-1 | 0.02 | E-1 | 0.48 | F-1 | 81 |
| Example 2 | A-1 | 18.31 | B-1 | 0.18 | C-1 | 0.01 | D-1 | 0.02 | E-1 | 0.48 | F-1 | 81 |
| Example 3 | A-1 | 18.31 | B-1 | 0.18 | C-1 | 0.01 | D-1 | 0.02 | E-1 | 0.48 | F-1 | 81 |
| Example 4 | A-1 | 18.31 | B-1 | 0.18 | C-1 | 0.01 | D-1 | 0.02 | E-1 | 0.48 | F-1 | 81 |
| Example 5 | A-1 | 18.31 | B-1 | 0.18 | C-1 | 0.01 | D-1 | 0.02 | E-1 | 0.48 | F-1 | 81 |
| Example 6 | A-1 | 18.12 | B-1 | 0.18 | C-1 | 0.01 | D-1 | 0.02 | E-1 | 0.67 | F-1 | 81 |
| Example 7 | A-1 | 18.45 | B-1 | 0.18 | C-1 | 0.01 | D-1 | 0.02 | E-1 | 0.34 | F-1 | 81 |
| Example 8 | A-2 | 18.31 | B-1 | 0.18 | C-1 | 0.01 | D-1 | 0.02 | E-1 | 0.48 | F-1 | 81 |
| Example 9 | A-3 | 18.31 | B-1 | 0.18 | C-1 | 0.01 | D-1 | 0.02 | E-1 | 0.48 | F-1 | 81 |
| Example 10 | A-4 | 18.31 | B-1 | 0.18 | C-1 | 0.01 | D-1 | 0.02 | E-1 | 0.48 | F-1 | 81 |
| Example 11 | A-1/A-2 | 18.31 | B-1 | 0.18 | C-1 | 0.01 | D-1 | 0.02 | E-1 | 0.48 | F-1 | 81 |
| | (50/50) | | | | | | | | | | | |
| Example 12 | A-1/A-3 | 18.31 | B-1 | 0.18 | C-1 | 0.01 | D-1 | 0.02 | E-1 | 0.48 | F-1 | 81 |
| | (50/50) | | | | | | | | | | | |
| Example 13 | A-1 | 18.31 | B-2 | 0.18 | C-1 | 0.01 | D-1 | 0.02 | E-1 | 0.48 | F-1 | 81 |
| Example 14 | A-1 | 18.31 | B-3 | 0.18 | C-1 | 0.01 | D-1 | 0.02 | E-1 | 0.48 | F-1 | 81 |
| Example 15 | A-1 | 18.31 | B-2/B-3 | 0.18 | C-1 | 0.01 | D-1 | 0.02 | E-1 | 0.48 | F-1 | 81 |
| | | | (50/50) | | | | | | | | | |
| Example 16 | A-1 | 18.31 | B-1 | 0.18 | C-2 | 0.01 | D-1 | 0.02 | E-1 | 0.48 | F-1 | 81 |
| Example 17 | A-5 | 18.31 | B-4 | 0.18 | C-1 | 0.01 | D-1 | 0.02 | E-1 | 0.48 | F-1 | 81 |
| Example 18 | A-5 | 18.12 | B-4 | 0.18 | C-1 | 0.01 | D-1 | 0.02 | E-1 | 0.67 | F-1 | 81 |
| Example 19 | A-1 | 18.72 | B-1 | 0.18 | C-1 | 0.08 | D-1 | 0.02 | None | — | F-1 | 81 |
| Example 20 | A-1 | 18.59 | B-1 | 0.18 | C-1 | 0.21 | D-1 | 0.02 | None | — | F-1 | 81 |
| Example 21 | A-1 | 18.62 | B-1 | 0.18 | C-1 | 0.18 | D-1 | 0.02 | None | — | F-1 | 81 |
| Example 22 | A-1 | 18.72 | B-2 | 0.18 | C-1 | 0.08 | D-1 | 0.02 | None | — | F-1 | 81 |
| Example 23 | A-1 | 18.59 | B-1 | 0.18 | C-1 | 0.08 | D-1 | 0.02 | E-1 | 0.13 | F-1 | 81 |
| Comparative | A-1 | 18.79 | B-1 | 0.18 | C-1 | 0.01 | D-1 | 0.02 | None | — | F-1 | 81 |
| Example 1 | | | | | | | | | | | | |
| Comparative | A-5 | 18.79 | B-4 | 0.18 | C-1 | 0.01 | D-1 | 0.02 | None | — | F-1 | 81 |
| Example 2 | | | | | | | | | | | | |
| Comparative | A-1 | 18.72 | B-1 | 0.18 | C-1 | 0.08 | D-1 | 0.02 | None | — | F-1 | 81 |
| Example 3 | | | | | | | | | | | | |
| Comparative | A-1 | 18.72 | B-2 | 0.18 | C-1 | 0.08 | D-1 | 0.02 | None | — | F-1 | 81 |
| Example 4 | | | | | | | | | | | | |
| Comparative | A-1 | 18.69 | B-1 | 0.18 | C-1 | 0.01 | D-1 | 0.02 | E-1 | 0.10 | F-1 | 81 |
| Example 5 | | | | | | | | | | | | |

| | | Evaluation | | | | | |
|---|---|---|---|---|---|---|---|
| | | | film | | | | |
| | PEB | | thickness | | Condition 1 | Deviation | Deviation |
| | (° C.) | Transmittance | (nm) | γ | or condition 2 | (nm) | rate |
| Example 1 | 120 | 8% | 2,000 | 4,300 | Condition 1 | 36 | 1.80 |
| Example 2 | 120 | 5% | 3,000 | 2,300 | Condition 1 | 43 | 1.43 |
| Example 3 | 120 | 11% | 1,000 | 9,600 | Condition 1 | 38 | 3.80 |
| Example 4 | 105 | 8% | 2,000 | 3,600 | Condition 1 | 34 | 1.70 |
| Example 5 | 110 | 8% | 2,000 | 3,800 | Condition 1 | 35 | 1.75 |
| Example 6 | 120 | 5% | 2,000 | 2,100 | Condition 1 | 28 | 1.40 |
| Example 7 | 120 | 11% | 2,000 | 9,800 | Condition 1 | 84 | 4.20 |
| Example 8 | 120 | 7% | 2,000 | 3,700 | Condition 1 | 30 | 1.50 |
| Example 9 | 120 | 7% | 2,000 | 3,700 | Condition 1 | 30 | 1.50 |
| Example 10 | 120 | 8% | 2,000 | 4,200 | Condition 1 | 38 | 1.90 |
| Example 11 | 120 | 7% | 2,000 | 3,700 | Condition 1 | 32 | 1.60 |
| Example 12 | 120 | 7% | 2,000 | 3,700 | Condition 1 | 33 | 1.65 |
| Example 13 | 120 | 8% | 2,000 | 3,400 | Condition 1 | 33 | 1.65 |
| Example 14 | 120 | 8% | 2,000 | 3,900 | Condition 1 | 34 | 1.70 |
| Example 15 | 120 | 8% | 2,000 | 3,500 | Condition 1 | 33 | 1.65 |
| Example 16 | 120 | 8% | 2,000 | 4,100 | Condition 1 | 37 | 1.85 |
| Example 17 | 80 | 8% | 2,000 | 5,900 | Condition 1 | 74 | 3.70 |
| Example 18 | 80 | 5% | 2,000 | 3,700 | Condition 1 | 36 | 1.80 |
| Example 19 | 105 | 56% | 80 | 3,300 | Condition 2 | 4.1 | 5.13 |
| Example 20 | 105 | 56% | 80 | 2,700 | Condition 2 | 3.2 | 4.00 |
| Example 21 | 105 | 56% | 80 | 3,000 | Condition 2 | 3.7 | 4.63 |
| Example 22 | 105 | 56% | 80 | 2,200 | Condition 2 | 3 | 3.75 |
| Example 23 | 105 | 42% | 400 | 4,600 | Condition 2 | 20 | 5.00 |
| Comparative | 120 | 28% | 2,000 | 24,100 | — | 243 | 12.15 |
| Example 1 | | | | | | | |
| Comparative | 80 | 28% | 2,000 | 29,200 | — | 287 | 14.35 |
| Example 2 | | | | | | | |
| Comparative | 115 | 56% | 80 | 9,600 | — | 12 | 15.00 |
| Example 3 | | | | | | | |
| Comparative | 115 | 56% | 80 | 7,100 | — | 9 | 11.25 |
| Example 4 | | | | | | | |
| Comparative | 120 | 13% | 2,000 | 13,500 | — | 186 | 9.30 |
| Example 5 | | | | | | | |

In Table 1, the structures of the resins (resins whose solubility in a developer changes by the action of an acid) are as follows. Here, the compositional ratios of the repeating units are molar ratios.

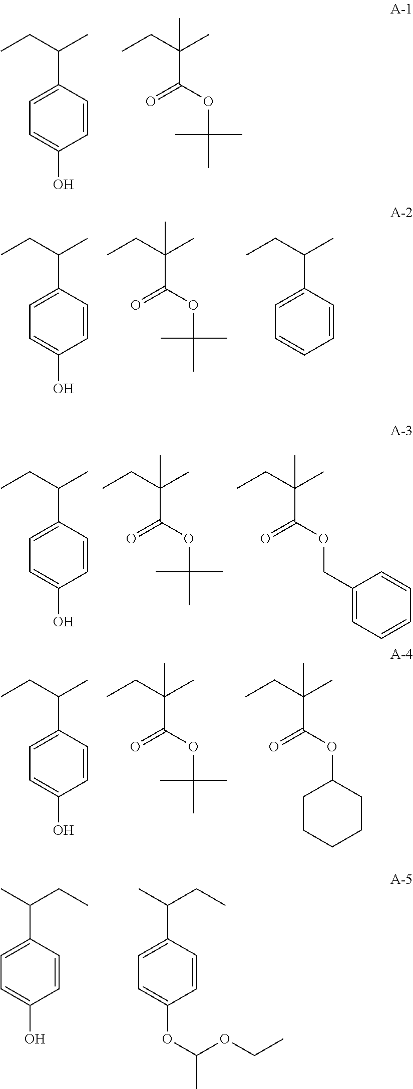

The molar ratios, the weight-average molecular weight (Mw), and the molecular weight distribution (Pd) of the respective repeating units of A-1 to A-5 are shown in Table 2. Further, each of the numerical values in the section of “Composition” represents the molar ratio of the repeating units in each of the resins, and for example, in A-1, the repeating units on the left side:the repeating units on the right side=70:30 is shown.

Furthermore, a method for measuring the molar light absorption coefficients of A-1 to A-5 is as described above.

In addition, the following A-2 and A-3 correspond to resins having a molar light absorption coefficient ε of more than 200, in acetonitrile at a wavelength of 243 nm.

TABLE 2

| | Composition | Mw | Pd |
|---|---|---|---|
| A-1 | 70/30 | 15,000 | 1.32 |
| A-2 | 60/30/10 | 13,000 | 1.28 |
| A-3 | 60/30/10 | 16,000 | 1.29 |
| A-4 | 60/30/10 | 16,000 | 1.32 |
| A-5 | 60/40 | 18,000 | 1.34 |

In Table 1, the structures of the acid generators are as follows.

Furthermore, the pKa of the acid (generated acid) generated from the following B-1 is −6, the pKa of the acid (generated acid) generated from the following B-2 is −1, the pKa of the acid (generated acid) generated from the following B-3 is −2, and the pKa of the acid (generated acid) generated from the following B-4 is 1.

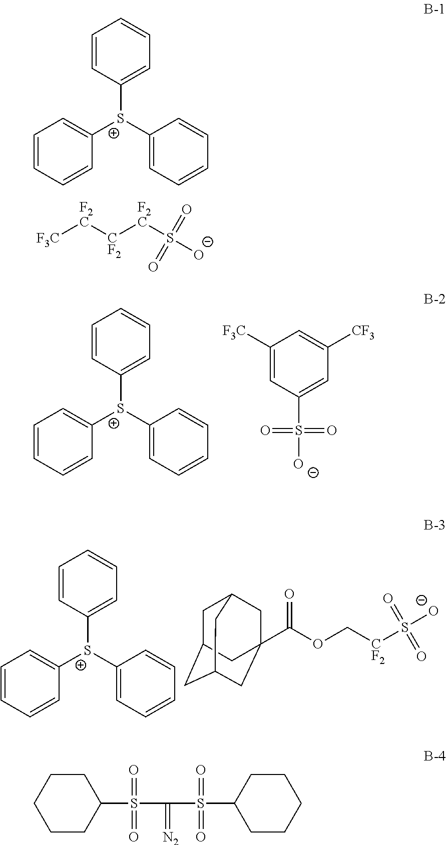

In Table 1, the structures of the acid diffusion control agents are as follows.

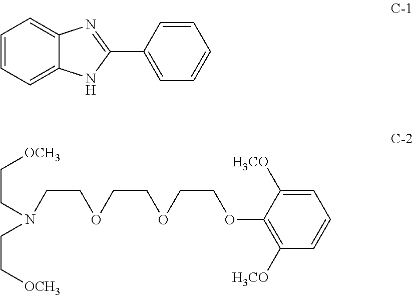 [SMILES: c1ccc(-c2nc3ccccc3[nH]2)cc1 ; COCCN(CCOC)CCOCCOCCOc1c(OC)cccc1OC]

In Table 1, the structures of the surfactants are as follows.

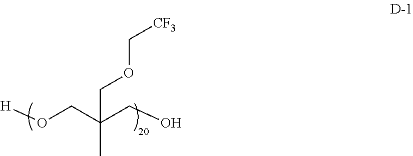

In Table 1, the structure of the light absorbent is as follows. The molar light absorption coefficient ε and the molecular weight of the following light absorbent are 9×10⁴ and 306.31, respectively.

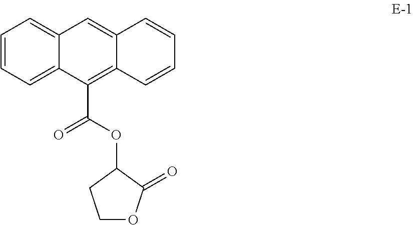 [SMILES: O=C(OC1CCOC1=O)c1c2ccccc2cc2ccccc12]

In Table 1, the solvents are as follows.

F-1: PGMEA/PGME=80/20

<Various Evaluations>

(Evaluation of γ)

The resist composition prepared above was applied onto an Si substrate (manufactured by Advanced Materials Technology Inc.) which had been subjected to a hexamethyldisilazane treatment, and baked (Pre Bake) at 140° C. for 60 seconds to form resist films having a thickness T described in Table 1, in each of Examples and Comparative Examples. Next, the wafer having the resist film formed thereon was exposed at 99 positions, not through an exposure mask, while an exposure dose was increased from 1 mJ/cm² at an interval of 0.8 mJ/cm², using a KrF excimer laser scanner (NA0.80). Thereafter, the wafer was baked (Post Exposure Bake; PEB) at 120° C. for 60 seconds, then developed with an aqueous tetramethylammonium hydroxide solution (2.38% by mass) for 60 seconds, rinsed with pure water for 30 seconds, and then spin-dried. The film thickness was measured at 99 positions in the exposed areas, the points corresponding to the film thickness and the common logarithm values of the exposure doses in each of the exposed positions are plotted in Cartesian coordinates with the film thickness (nm) displayed along the vertical axis and the common logarithm value of the exposure doses (mJ/cm²) displayed along the horizontal axis are plotted, thereby creating a plot diagram (see FIG. 2).

In the obtained plot diagram, a line obtained by connecting the plotted points was created, and an absolute value of the slope of a straight line connecting a point with the thickness T×0.8 of the vertical axis and a point with the thickness T×0.4 of the vertical axis on the line was calculated as γ. The values of γ of each of Examples and Comparative Examples are summarized in Table 1.

(Evaluation of Deviation of Film Thickness)

The resist composition prepared above was applied onto an Si substrate (manufactured by Advanced Materials Technology Inc.) which had been subjected to a hexamethyldisilazane treatment, and baked (Pre Bake) at 140° C. for 60 seconds to form resist films having a thickness T described in Table 1, in each of Examples and Comparative Examples. Next, the wafer having the resist film formed thereon was exposed at 99 positions, not through an exposure mask, using a KrF excimer laser scanner (NA0.80), at the same exposure dose. As the exposure dose at this time, an exposure dose corresponding to 0.5 T (T×0.5) nm on the line in the plot diagram obtained in (Evaluation of γ) was used.

Thereafter, the wafer was baked (Post Exposure Bake; PEB) at a temperature described in Table 1 in each of Examples and Comparative Examples for 60 seconds, then developed with an aqueous tetramethylammonium hydroxide solution (2.38% by mass) for 60 seconds, rinsed with pure water for 30 seconds, and then spin-dried. The film thickness was measured at 99 positions in the exposed areas, and 30 was calculated. The value of 3a was taken as a deviation of the film thickness (corresponding to “Deviation” in Table 1).

In addition, a value of the deviation (nm) of the film thickness obtained in each of Examples and Comparative Examples was divided by the thickness T of the resist film of each of Examples and Comparative Examples, and then multiplied by 100 to calculate a deviation rate (%). The results are summarized in Table 1. As the deviation rate is smaller, the uniformity in the film thickness is superior.

(Transmittance)

The prepared resist composition was applied onto a quartz glass substrate by rotation application, and subjected to pre-baking at 140° C. for 60 seconds to form a resist film having the thickness T described in Table 1 in each of Examples and Comparative Examples, and the transmittance of the film at a wavelength of 248 nm was measured. For the measurement of the transmittance, a light absorption photometer (manufactured by Shimadzu Corp.) was used.

As shown in Table 1 above, it was confirmed that the deviation of the thickness of the treated film obtained by a plurality of times of exposing treatments was small according to the pattern forming method of the present invention. That is, these results are intended to indicate that even in a case where a plurality of patterns are formed under the same condition, the deviation of the thickness among production lots is small.

Furthermore, from these results, it can be recognized that even in a case where there is a deviation in the exposure dose among production lots in the grayscale exposure or the like, it is difficult to generate a deviation of the thickness of the treated film which has been formed. Accordingly, for example, in a case where a pattern having a stepped structure is formed by grayscale exposure even in a case where there is a deviation of the exposure doses among production lots, it can be seen that a difference in the height of the respective steps in the pattern among production lots is hardly generated, and thus, the production yield is excellent.

Among those, from the comparison of Examples 1 to 3, it was confirmed that in a case where the film thickness is 2,000 nm or more, the effects are superior.

Furthermore, from the comparison of Examples 1, 4, and 5, it was confirmed that in a case where the temperature of PEB is 115° C. or lower, the effects are superior.

Moreover, from the comparison of Examples 1, 6, and 7, it was confirmed that in a case where the absorbance is 8% or less, the effects are superior.

In addition, from the comparison of Examples 1, 8, and 12, it was confirmed that in a case where the molar light absorption coefficient ε at a wavelength of 243 nm of the resin is more than 200 L·mol⁻¹·cm⁻¹, the effects are superior.

Furthermore, from the comparison of Examples 1, 13, and 14, it was confirmed that in a case where an acid generator having a pKa of a generated acid of −2 or more is used, the effects are superior.

Moreover, in Comparative Examples 1 to 5 in which the condition 1 or condition 2 was not satisfied, the deviation of the film thickness was large, and thus, desired effects were not obtained.

A resist film was formed by the same procedure as (Evaluation of γ) above, using the above-mentioned resist composition prepared in each of Examples. Thereafter, exposure was carried out using a grayscale exposure mask for forming a three-dimensional pattern, and the next treatment (developing treatment) was carried out by the same procedure as (Evaluation of γ) above. As a result, it was confirmed that a desired three-dimensional pattern was formed. Further, even in a case where 100 samples above were produced, there was almost no deviation of the shapes of the respective three-dimensional patterns.

### EXPLANATION OF REFERENCES

10 substrate
12 film (resist film)

What is claimed is:

1. A pattern forming method comprising:
a step A of forming a film having a thickness T on a substrate, using an actinic ray-sensitive or radiation-sensitive resin composition including a resin whose solubility in a developer changes by the action of an acid and an acid generator;
a step B of exposing the film; and
a step C of developing the exposed film using a developer to form a pattern,
wherein the film formed in the step A satisfies at least one of the following condition 1 or 2:
Condition 1: In a case where the thickness T of the film is 800 nm or more, the value of γ is less than 10,000, and
Condition 2: In a case where the thickness T of the film is less than 800 nm, the value of γ is less than 5,000, and
γ is obtained by the following method for calculating γ:
Method for calculating γ: The film having the thickness T formed on the substrate is exposed at 99 positions, while an exposure dose is increased from 1 mJ/cm² at an interval of 0.8 mJ/cm², using a KrF excimer laser; the exposed film is subjected to a baking treatment at 120° C. for 60 seconds, and then subjected to a developing treatment with an aqueous tetramethylammonium hydroxide solution; the film thickness is calculated at each of the exposed positions of the development-treated film; the points corresponding to the film thickness and the common logarithm values of the exposure doses in each of the exposed positions are plotted in Cartesian coordinates with the film thickness displayed along the vertical axis and the common logarithm value of the exposure doses displayed along the horizontal axis are plotted, thereby creating a line obtained by connecting the plotted points; and an absolute value of the slope of a straight line connecting a point with the thickness T×0.8 of the vertical axis and a point with the thickness T×0.4 of the vertical axis on the line is defined as γ.

2. The pattern forming method according to claim 1,
wherein the film formed in the step A satisfies the condition 1, and
the transmittance of the film formed in the step A at a wavelength of 248 nm is 12% or less.

3. The pattern forming method according to claim 1,
wherein the resin has a molar light absorption coefficient ε at a wavelength of 243 nm of more than 200 L·mol⁻¹·cm⁻¹, or
the actinic ray-sensitive or radiation-sensitive resin composition further includes a resin having a molar light absorption coefficient ε at a wavelength of 243 nm of more than 200 L·mol⁻¹·cm⁻¹, which is other than the resin whose solubility in a developer changes by the action of an acid.

4. The pattern forming method according to claim 1,
wherein the actinic ray-sensitive or radiation-sensitive resin composition further includes a compound having a molar light absorption coefficient ε at a wavelength of 243 nm of more than 200 L·mol⁻¹·cm⁻¹ and a molecular weight of 2,000 or less, which is other than the acid generator.

5. The pattern forming method according to claim 1,
wherein the resin includes a tertiary alkyl ester group as an acid-decomposable group.

6. The pattern forming method according to claim 1,
wherein the acid generator includes an acid generator having a pKa of a generated acid of −2 or more.

7. The pattern forming method according to claim 1,
wherein the actinic ray-sensitive or radiation-sensitive resin composition further includes an acid diffusion control agent, and
the content of the acid diffusion control agent is 0.2% by mass or more with respect to the total solid content in the actinic ray-sensitive or radiation-sensitive resin composition.

8. The pattern forming method according to claim 1,
wherein the exposure in the step B is grayscale exposure.

9. The pattern forming method according to claim 1, further comprising:
a step D of subjecting the film to a heating treatment after the step B and before the step C,
wherein the temperature in the heating treatment is 115° C. or lower.

10. The pattern forming method according to claim 1,
wherein the exposure in the step B is carried out with KrF light.

11. An actinic ray-sensitive or radiation-sensitive resin composition used in the pattern forming method according to claim 1.

12. The pattern forming method according to claim 2,
wherein the resin has a molar light absorption coefficient ε at a wavelength of 243 nm of more than 200 L·mol⁻¹·cm⁻¹, or
the actinic ray-sensitive or radiation-sensitive resin composition further includes a resin having a molar light absorption coefficient ε at a wavelength of 243 nm of more than 200 L·mol⁻¹·cm⁻¹, which is other than the resin whose solubility in a developer changes by the action of an acid.

13. The pattern forming method according to claim 2,
wherein the actinic ray-sensitive or radiation-sensitive resin composition further includes a compound having a molar light absorption coefficient ε at a wavelength of 243 nm of more than 200 L·mol⁻¹·cm⁻¹ and a molecular weight of 2,000 or less, which is other than the acid generator.

14. The pattern forming method according to claim 3,
wherein the actinic ray-sensitive or radiation-sensitive resin composition further includes a compound having a molar light absorption coefficient ε at a wavelength of 243 nm of more than 200 L·mol⁻¹·cm⁻¹ and a molecular weight of 2,000 or less, which is other than the acid generator.

15. The pattern forming method according to claim 2,
wherein the resin includes a tertiary alkyl ester group as an acid-decomposable group.

16. The pattern forming method according to claim 3,
wherein the resin includes a tertiary alkyl ester group as an acid-decomposable group.

17. The pattern forming method according to claim 4,
wherein the resin includes a tertiary alkyl ester group as an acid-decomposable group.

18. The pattern forming method according to claim 2,
wherein the acid generator includes an acid generator having a pKa of a generated acid of −2 or more.

19. The pattern forming method according to claim 3,
wherein the acid generator includes an acid generator having a pKa of a generated acid of −2 or more.

20. The pattern forming method according to claim 4,
wherein the acid generator includes an acid generator having a pKa of a generated acid of −2 or more.
